(19) United States
(12) Patent Application Publication
(10) Pub. No.: US 2026/0022294 A1
(43) Pub. Date: Jan. 22, 2026

(54) ORGANOMETALLIC COMPOUND, LIGHT-EMITTING DEVICE AND ELECTRONIC DEVICE

(71) Applicant: Samsung Display Co., LTD., Yongin-si (KR)

(72) Inventors: Soo Inn LEE, Yongin-si (KR); Il Joon KANG, Yongin-si (KR); Soo Byung KO, Yongin-si (KR); Chan Seok OH, Yongin-si (KR); Ji Hyung LEE, Yongin-si (KR); Jin Hee JU, Yongin-si (KR)

(73) Assignee: Samsung Display Co., LTD., Yongin-si (KR)

(21) Appl. No.: 19/041,370

(22) Filed: Jan. 30, 2025

(30) Foreign Application Priority Data
Jul. 18, 2024 (KR) 10-2024-0095198

(51) Int. Cl. C09K 11/06; H10K 50/115; H10K 50/12; H10K 50/15; H10K 50/16; H10K 85/30; H10K 85/60; H10K 101/20

(52) U.S. Cl. CPC C09K 11/06; H10K 50/115; H10K 50/12; H10K 50/15; H10K 50/16; H10K 85/346; H10K 85/631; H10K 85/654; C09K 2211/185; H10K 2101/20

(57) ABSTRACT

Embodiments provide an organometallic compound, a light-emitting device that includes the organometallic compound, and an electronic device that includes the light-emitting device. The light-emitting device includes a first electrode, a second electrode, and an intermediate layer between the first electrode and the second electrode, wherein the intermediate layer includes an emission layer, and the emission layer includes the organometallic compound. The organometallic compound is represented by Chemical Formula 1, which is explained in the specification.

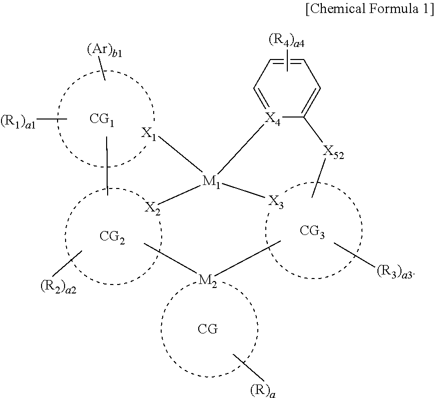

### CROSS-REFERENCE TO RELATED APPLICATION(S)

This application claims priority to and benefits of Korean Patent Application No. 10-2024-0095198 under 35 U.S.C. § 119, filed on Jul. 18, 2024 in the Korean Intellectual Property Office (KIPO), the entire contents of which are incorporated herein by reference.

### BACKGROUND

### 1. Technical Field

The disclosure relates to an organometallic compound, a light-emitting device including the organometallic compound, and an electronic device including the light-emitting device.

### 2. Description of the Related Art

An organic light-emitting device is a self-emissive device that has improved viewing angle and contrast properties, along with a high response speed and high luminance.

An organic light-emitting device may include an emission layer disposed between a first electrode and a second electrode. A hole transferred from the first electrode and an electron transferred from the second electrode may recombine in the emission layer to generate an exciton. As the exciton transitions from an excited state to a ground state, light is emitted.

An emission layer may include a host material and a dopant material for implementing the light-emitting mechanism described above.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

An embodiment provides an organometallic compound having improved spectroscopic and light-emitting properties.

An embodiment provides a light-emitting device having improved light-emitting properties and reliability.

Another embodiment provides an electronic device that includes the light-emitting device.

According to an embodiment, an organometallic compound may be represented by Chemical Formula 1:

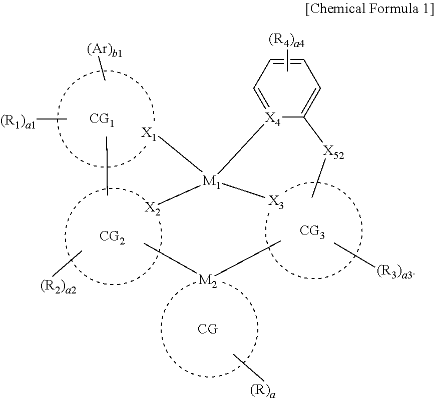

In Chemical Formula 1, M₁ may be platinum (Pt), palladium (Pd), gold (Au), nickel (Ni), silver (Ag), or copper (Cu); M₂ may be carbon (C) or silicon (Si); X₁ to X₄ may each independently be C or nitrogen (N); CG, CG₁, CG₂, and CG₃ may each independently be a C₃-C₆₀ carbocyclic group or a C₁-C₆₀ heterocyclic group, provided that a ring formed by X₁ and CG₁ is not a benzene group or a pyridine group; X₅ may be a direct linkage, *—N(R₅)—*′, *—B(R₅)—*′, *—P(R₅)—*′, *—C(R₅ₐ)(R_{5b})—*′, *—Si(R₅ₐ)(R_{5b})—*′, *—Ge(R₅ₐ)(R_{5b})—*′, *—S—*′, *—Se—*′, *—O—*, *—C(═O)—*′, *—S(═O)—*′, *—S(═O)₂—*′, *—C(R₅)═*′, *═C(R₅)—*′, *—C(R₅ₐ)═C(R_{5b})—*′, *—C(═S) or *—C≡C—*′; Ar may be a substituted or unsubstituted C₆-C₆₀ aryl group, or a substituted or unsubstituted C₅-C₆₀ heteroaryl group; R, R₂ to R₄, R₅, R₅ₐ, and R_{5b} may each independently be hydrogen, deuterium, a halogen, a substituted or unsubstituted C₁-C₁₀ alkyl group, a substituted or unsubstituted C₂-C₁₀ alkenyl group, a substituted or unsubstituted C₂-C₁₀ alkynyl group, a substituted or unsubstituted C₆-C₃₀ aryl group, or a substituted or unsubstituted C₅-C₃₀ heteroaryl group; R₁ may be: hydrogen, deuterium, a halogen, a substituted or unsubstituted C₁-C₁₀ alkyl group, a substituted or unsubstituted C₂-C₁₀ alkenyl group, a substituted or unsubstituted C₂-C₁₀ alkynyl group, a substituted or unsubstituted C₆-C₃₀ aryl group, a substituted or unsubstituted C₅-C₃₀ heteroaryl group; a direct linkage bonded to Ar; or a substituted or unsubstituted C₁-C₁₀ alkylene group bonded to Ar; a, a1, a2, a3, and a4 may each independently be an integer from 0 to 20; and b1 may be 1 or 2.

In embodiments, in Chemical Formula 1, M₁ may be Pt, and M₂ may be Si.

In embodiments, in Chemical Formula 1, CG may form a bridge of a silafluorene moiety.

In embodiments, in Chemical Formula 1, CG₂ and CG₃ may be different from each other, and the number of carbon atoms in CG₂ may be less than the number of carbon atoms in CG₃.

In embodiments, CG₂ may form a benzene group with X₂, and CG₃ may form a carbazole group with X₃.

In embodiments, in Chemical Formula 1, the number of carbon atoms in Ar may be greater than the number of carbon atoms in (R₄)ₐ₄.

In embodiments, the organometallic compound may be represented by Chemical Formula 1-1:

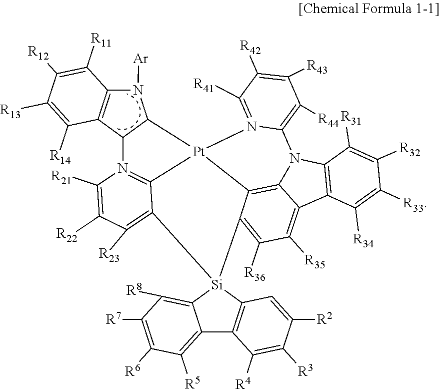

In Chemical Formula 1-1, R¹ to R⁸, R₁₁ to R₁₄, R₂₁ to R₂₃, R₃₁ to R₃₆, and R₄₁ to R₄₄ may each independently be hydrogen, deuterium, a halogen, a substituted or unsubstituted C₁-C₁₀ alkyl group, a substituted or unsubstituted C₂-C₁₀ alkenyl group, a substituted or unsubstituted C₂-C₁₀ alkynyl group, a substituted or unsubstituted C₆-C₃₀ aryl group, or a substituted or unsubstituted C₅-C₃₀ heteroaryl group; and Ar may be the same as defined in Chemical Formula 1.

In embodiments, in Chemical Formula 1-1, at least one of R₄₁ to R₄₄ may each independently include a substituted or unsubstituted aryl group, or a substituted or unsubstituted heteroaryl group; and the number of carbon atoms in the aryl group or in the heteroaryl group included in R₄₁ to R₄₄ may be less than the number of carbon atoms in Ar.

In embodiments, Ar may include three or more benzene rings.

In embodiments, the organometallic compound may be represented by Chemical Formula 1-2:

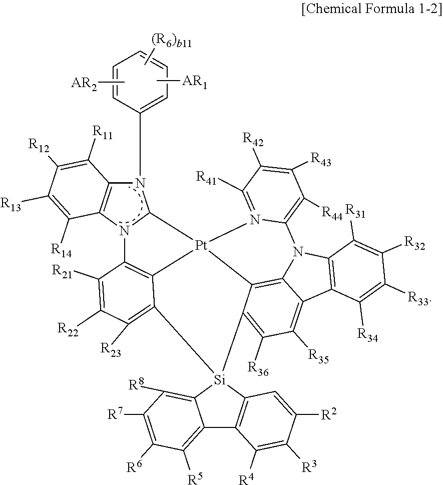

In Chemical Formula 1-2, Ar₁ and Ar₂ may each independently be a substituted or unsubstituted C₆-C₃₀ aryl group, or a substituted or unsubstituted C₅-C₃₀ heteroaryl group; R₆ may each independently be hydrogen, deuterium, a halogen, a substituted or unsubstituted C₁-C₁₀ alkyl group, a substituted or unsubstituted C₂-C₁₀ alkenyl group, or a substituted or unsubstituted C₂-C₁₀ alkynyl group; b₁₁ may be an integer from 0 to 3; and R¹ to R⁸, R₁₁ to R₁₄, R₂₁ to R₂₃, R₃₁ to R₃₆, and R₄₁ to R₄₄ may each be the same as defined in Chemical Formula 1-1.

In embodiments, in Chemical Formula 1-2, at least one of Ar₁ and Ar₂ may each independently be a substituted or unsubstituted C₆-C₃₀ aryl group condensed with a cycloalkyl group, or a substituted or unsubstituted C₅-C₃₀ heteroaryl group condensed with a cycloalkyl group.

In embodiments, in Chemical Formula 1-2, at least one of Ar₁ and Ar₂ may each independently be represented by

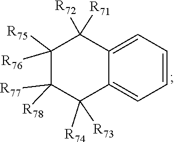

and R₇₁ to R₇₈ may each independently be hydrogen, deuterium, a halogen, a substituted or unsubstituted C₁-C₁₀ alkyl group, a substituted or unsubstituted C₂-C₁₀ alkenyl group, or a substituted or unsubstituted C₂-C₁₀ alkynyl group.

In embodiments, the organometallic compound may be represented by Chemical Formula 1-3:

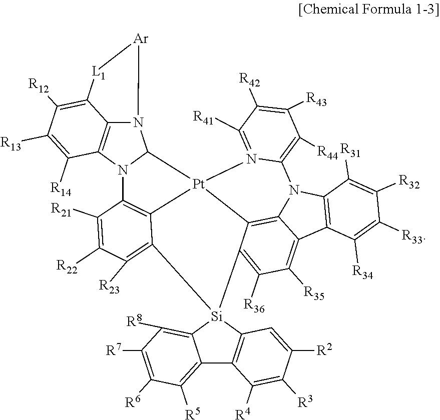

In Chemical Formula 1-3, L₁ may be a direct linkage or a substituted or unsubstituted C₁-C₁₀ alkylene group; R¹ to R⁸, R₁₂ to R₁₄, R₂₁ to R₂₃, R₃₁ to R₃₆, and R₄₁ to R₄₄ may each independently be hydrogen, deuterium, a halogen, a substituted or unsubstituted C₁-C₁₀ alkyl group, a substituted or unsubstituted C₂-C₁₀ alkenyl group, a substituted or unsubstituted C₂-C₁₀ alkynyl group, a substituted or unsubstituted C₆-C₃₀ aryl group, or a substituted or unsubstituted C₅-C₃₀ heteroaryl group; and Ar may be the same as defined in Chemical Formula 1.

In embodiments, the organometallic compound may be represented by Chemical Formula 1-4:

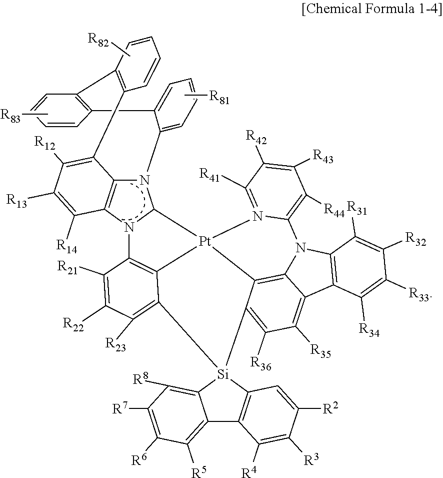

In Chemical Formula 1-4, R₈₁ to R₈₃ may each independently be hydrogen, deuterium, a halogen, a substituted or unsubstituted C₁-C₁₀ alkyl group, a substituted or unsubstituted C₂-C₁₀ alkenyl group, a substituted or unsubstituted C₂-C₁₀ alkynyl group, a substituted or unsubstituted C₆-C₃₀ aryl group, or a substituted or unsubstituted C₅-C₃₀ heteroaryl group; and R¹ to R⁸, R₁₂ to R₁₄, R₂₁ to R₂₃, R₃₁ to R₃₆, and R₄₁ to R₄₄ may each be the same as defined in Chemical Formula 1-3.

In embodiments, the organometallic compound may be one of Compounds DP-1 to DP-150, which are explained below.

According to an embodiment, a light-emitting device may include a first electrode, a second electrode, and an intermediate layer between the first electrode and the second electrode, wherein the intermediate layer may include an emission layer, and the emission layer may include an organometallic compound represented by Chemical Formula 1, which is explained herein.

In embodiments, the emission layer may include a host and a dopant, and the organometallic compound may serve as a phosphorescent dopant or as a thermally activated delayed fluorescence (TADF) dopant.

In embodiments, the dopant may include a thermally activated delayed fluorescence material.

In embodiments, the host may include a hole transporting host represented by Chemical Formula HT, and an electron transporting host represented by Chemical Formula ET:

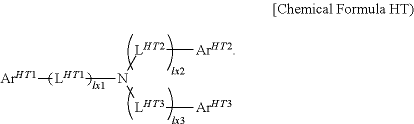

In Chemical Formula HT, L^{HT1}, L^{HT2}, and L^{HT3} may each independently be a direct linkage, a substituted or unsubstituted C₆-C₃₀ arylene group, or a substituted or unsubstituted C₂-C₃₀ heteroarylene group; lx1 to lx3 may each independently be an integer from 0 to 10; Ar^{HT1} and Ar^{HT2} may each independently be a substituted or unsubstituted C₆-C₃₀ aryl group, or a substituted or unsubstituted C₂-C₃₀ heteroaryl group; and Ar^{HT3} may be a substituted or unsubstituted C₆-C₃₀ aryl group.

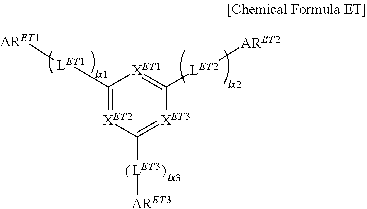

In Chemical Formula ET, at least one of X^{ET1} to X^{ET3} may be N; the remainder of X^{ET1} to X^{ET3} may each independently be C(R^{ET}); R^{ET} may be a hydrogen atom, a deuterium atom, a substituted or unsubstituted C₁-C₂₀ alkyl group, a substituted or unsubstituted C₆-C₆₀ aryl group, or a substituted or unsubstituted C₂-C₆₀ heteroaryl group; lx1 to lx3 may each independently be an integer from 0 to 10; L^{ET1} to L^{ET3} may each independently be a direct linkage, a substituted or unsubstituted C₆-C₃₀ arylene group, or a substituted or unsubstituted C₂-C₃₀ heteroarylene group; and Ar^{ET1} to Ar^{ET3} may each independently be a hydrogen atom, a deuterium atom, a substituted or unsubstituted C₁-C₂₀ alkyl group, a substituted or unsubstituted C₆-C₃₀ aryl group, or a substituted or unsubstituted C₂-C₃₀ heteroaryl group.

In embodiments, the emission layer may emit blue light; and the blue light may have a maximum emission wavelength in a range of about 440 nm to about 460 nm.

In embodiments, the organometallic compound may be represented by Chemical Formula 1-2 or Chemical Formula 1-3, which are explained herein.

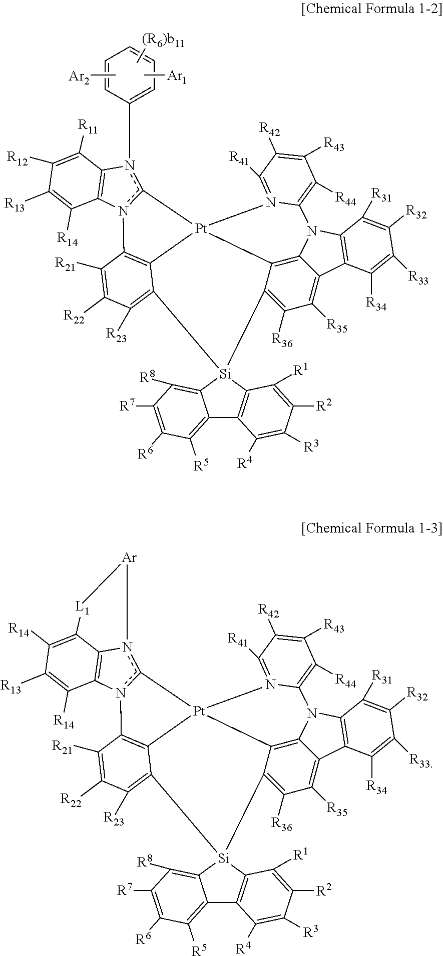

According to an embodiment, an electronic device may include the light-emitting device.

In embodiments, the electronic device may further include a functional layer disposed on the light-emitting device, wherein the functional layer may include a sensor layer, a polarizing layer, a color conversion layer, a color filter layer, a window film, or a combination thereof.

In embodiments, the functional layer may include the color conversion layer, and the color conversion layer may include quantum dots.

An organometallic compound according to embodiments may include a bridge group connecting neighboring carbocyclic or heterocyclic groups that are connected to a central metal. In embodiments, the bridge group may include a silafluorene moiety. Bulkiness of the organometallic compound may be increased by partial intramolecular tilting by the bridge group. Thus, intermolecular aggregation may be prevented and a depth of a highest occupied molecular orbital (HOMO) energy level may be increased. The organometallic compound may be applied as a phosphorescent dopant so that driving properties in an emission layer may be enhanced by an increase in a host-dopant energy gap.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIGS. 1 to 5 are each a schematic cross-sectional view of a light-emitting device according to an embodiment;

FIG. 6 is a schematic cross-sectional view of a display device according to an embodiment;

FIG. 7 is a schematic cross-sectional view of a display device according to an embodiment; and

FIG. 8 is a schematic perspective view of an electronic device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

According to embodiments, an organometallic compound may include a central metal and multiple carbocyclic and/or heterocyclic groups bonded to the central metal. Embodiments also provide a light-emitting device, a display device, and an electronic device, each including the organometallic compound.

### Definitions of Terms

In the specification, the term “substituted or unsubstituted” may describe a group that is substituted or unsubstituted with at least one substituent selected from the group consisting of, e.g., a deuterium atom, a halogen atom, a cyano group, a nitro group, an amino group, a silyl group, an oxy group, a thio group, a sulfinyl group, a sulfonyl group, a carbonyl group, an ester group, a boron group, a phosphine oxide group, a phosphine sulfide group, an alkyl group (e.g., a C₁-C₆₀, C₁-C₁₀ alkyl group), an alkenyl group (e.g., a C₂-C₆₀, C₂-C₁₀ alkenyl group), an alkynyl group (e.g., a C₂-C₆₀, C₂-C₁₀ alkynyl group), an alkoxy group (e.g., a C₁-C₆₀, C₁-C₁₀ alkoxy group), a hydrocarbon ring group, an aryl group (e.g., a C₆-C₆₀ aryl group), and a heterocyclic group (e.g., a C₁-C₆₀ heterocyclic group). For example, the term “substituted alkyl group” may describe a group in which at least one hydrogen atom in an alkyl group is substituted with at least one substituent as described above, such that the substituent is bonded to a carbon atom of the alkyl group.

In embodiments, the substituent may include a combination of substituents selected from the groups described above. For example, at least one hydrogen atom in the alkyl group, the aryl group, etc., included as a substituent may itself be substituted with a deuterium atom, a halogen atom, a cyano group, a nitro group, an amino group, a silyl group, an oxy group, a thio group, a sulfinyl group, a sulfonyl group, a carbonyl group, an ester group, boron, a phosphine oxide group, a phosphine sulfide group, an alkyl group, an alkenyl group, an alkynyl group, a hydrocarbon ring group, an aryl group, a heterocyclic group, or a combination thereof.

In the substituents described above, a multivalent substituent such as an amino group, a phosphine sulfide group, a phosphine oxide group, a sulfinyl group, a sulfonyl group, an oxy group, a carbonyl group, an ester group, etc., may each independently be substituted with a C₁-C₁₀ alkyl group, a C₁-C₁o alkenyl group, a C₁-C₁₀ alkynyl group, or a C₆-C₁₀ aryl group.

In the specification, the term “substituted or unsubstituted Cₐ-C_{b} Y group” the range of a to b refers to the number of carbon atoms in an unsubstituted Y group, and may not include the number of carbon atoms of a substituent.

In the specification, an alkyl group may be a monovalent hydrocarbon group in which one hydrogen atom is removed from a linear or branched hydrocarbon group. Examples of an alkyl group may include a methyl group, an ethyl group, a propyl group, a sec-butyl group, a tert-butyl group, an iso-butyl group, a pentyl group, a neopentyl group, a 2-ethyl butyl group, a 3,3-dimethyl butyl group, a hexyl group, a heptyl group, an octyl group, etc.

In the specification, an alkylene group may be a divalent hydrocarbon group in which two hydrogen atoms are removed from a linear or branched hydrocarbon group.

In the specification, an alkenyl group may have a same skeleton as that of an alkyl group, and may be a monovalent hydrocarbon group that includes at least one carbon-carbon double bond. In the specification, an alkenylene group may be a divalent hydrocarbon group in which one hydrogen atom is further removed from an alkenyl group.

In the specification, an alkynyl group may have a same skeleton as that of an alkyl group, and may be a monovalent hydrocarbon group that includes at least one carbon-carbon a triple bond. In the specification, an alkynylene group may be a divalent hydrocarbon group in which one hydrogen atom is further removed from an alkynyl group.

In the specification, an aryl group may be a monovalent hydrocarbon group in which one hydrogen atom is removed from a hydrocarbon group having an aromatic structure. The definition of an aryl group may also encompass a group in which multiple aromatic rings are directly connected, such as a biphenyl group. Examples of an aryl group may include, e.g., a phenyl group, a naphthyl group, an anthracenyl group, a phenanthrenyl group, a pyrenyl group, a fluorenyl group, a tetracenyl group, a biphenyl group, a terphenyl group, a quaterphenyl group, a chrysenyl group, etc.

In the specification, a group in which two or more aryl rings are condensed to each other or linked to each other by an alicyclic hydrocarbon ring, such as a fluorenyl group, can be encompassed in the definition of an aryl group.

For example, a biphenyl group may be interpreted as an aryl group or it may be interpreted as a phenyl group that is substituted with a phenyl group.

In the specification, an arylene group may be a divalent hydrocarbon group in which two hydrogen atoms are removed from an aryl group.

In the specification, a heteroaryl group may be a monovalent group having an aromatic structure that includes at least one heteroatom such as B, O, P, S, and Si as a ring-forming atom.

In the specification, a heteroarylene group may be a divalent group having an aromatic structure that includes at least one heteroatom such as B, O, P, S, and Si as a ring-forming atom. When a heteroaryl group or a heteroarylene group includes two or more heteroatoms, the two or more heteroatoms may be the same as or different from each other.

In the specification, a group in which two or more aryl rings are condensed or linked to a non-aromatic heterocyclic ring, such as a carbazole group, can also encompassed in the definition of a heteroaryl group.

In the specification, the term “cyclic group” may encompass a monocyclic group or a polycyclic group, and may also encompass an alicyclic ring or an aromatic ring.

In the specification, the term “polycyclic group” may be a group in which two or more rings are connected to each other or condensed to each other through one or more atoms. For example, a polycyclic structure may include a bicyclic structure through a bridge carbon, a spiro structure, a fused structure, etc.

In the specification, the term “condensed group” or “condensed ring structure” may each be a group in which two or more adjacent rings share two or more atoms among the above-described polycyclic structures. Examples of a condensed ring structure may include naphthalene, anthracene, phenanthrene, fluorene, pyrene, benzopyrene, pentacene, polyacene, helicene, etc.

In the specification, the term “carbocyclic group (e.g., C₃-C₆₀ carbocyclic group)” may be a cyclic group in which carbon atoms are the only ring-forming atoms. In the specification, a heterocyclic group (e.g., a C₁-C₆₀ heterocyclic group) may be a cyclic group that includes at least one heteroatom as a ring-forming atom, in addition to carbon atoms.

In the specification, a carbocyclic group and a heterocyclic group may each independently be a monocyclic group that consists of one ring or a polycyclic group in which two or more rings are condensed with each other.

### <Organometallic Compound>

According to embodiments, an organometallic compound may include a central metal (e.g., Pt) and a bridge element (e.g., Si), wherein the organometallic compound may have an asymmetric structure with respect to a virtual straight line that connects the central metal and the bridge element.

In embodiments, the organometallic compound may be represented by Chemical Formula 1:

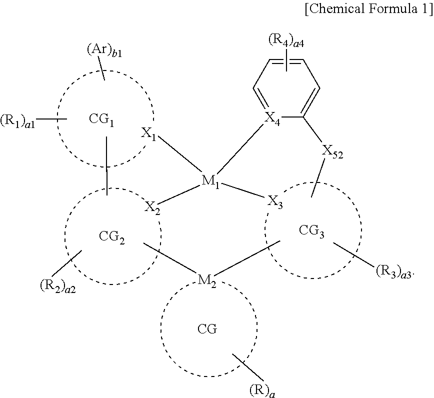

In Chemical Formula 1, M₁ may be platinum (Pt), palladium (Pd), gold (Au), nickel (Ni), silver (Ag), or copper (Cu); and M₂ may be carbon (C) or silicon (Si).

In an embodiment, in Chemical Formula 1, M₁ may be Pt, and M₂ may be Si.

In Chemical Formula 1, X₁ to X₄ may each independently be C or nitrogen (N).

In an embodiment, X₁ may be C, e.g., a carbon atom of a carbene moiety. In an embodiment, X₁ may be N.

In an embodiment, X₂ and X₃ may each be C, and X₄ may be N.

In an embodiment, a bond between X₁ and M₁ may be a coordination bond. In an embodiment, one among a bond between X₂ and M₁, a bond between X₃ and M₁, and a bond between X₄ and M may be a coordination bond; and the remaining two bonds may each be a covalent bond.

In an embodiment, a bond between X₂ and M₁ and a bond between X₃ and M₁ may each be a covalent bond; and a bond between X₄ and M may be a coordination bond.

In Chemical Formula 1, CG, CG₁, CG₂, and CG₃ may each independently be a C₃-C₆₀ carbocyclic group or a C₁-C₆₀ heterocyclic group.

In an embodiment, CG may be a C₃-C₆₀ carbocyclic group. In embodiments, CG may be an M₂-containing 5-membered ring to which at least one 6-membered ring is fused. In an embodiment, CG may be a M₂-containing 5-membered ring to which two 6-membered rings are fused. In an embodiment, CG may be a fluorenyl group. In an embodiment, a bridge between CG₂ and CG₃ may be formed by a silafluorenyl group. For example, in an embodiment, in Chemical Formula 1, CG may for a bridge of a silafluorene moiety.

In an embodiment, CG₁ may be an X₁-containing 5-membered ring, an X₁-containing 5-membered ring to which at least one 6-membered ring is fused, or an X₁-containing 6-membered ring. In an embodiment, CG₁ may be an X₁-containing 5-membered ring, or an X₁-containing 5-membered ring to which at least one 6-membered ring is fused.

In an embodiment, the X₁-containing 5-membered ring may be a pyrrole group, a pyrazole group, an imidazole group, a triazole group, an oxazole group, an isoxazole group, a thiazole group, an isothiazole group, an oxadiazole group, or a thiadiazole group.

In an embodiment, the X₁-containing 6-membered ring or the 6-membered ring that is optionally fused to the X₁-containing 5-membered ring may each independently be a benzene group, a pyridine group, or a pyrimidine group.

In embodiments, CG₁ may not be a benzene group or a pyridine group. For example, a ring formed by X₁ and CG₁ may not be a benzene group or a pyridine group.

In an embodiment, CG₁ may be an imidazole group or a triazole group. In an embodiment, CG₁ may be an X₁-containing 5-membered ring to which at least one 6-membered ring is fused, and CG₁ may be a benzimidazole group or an imidazopyridine group.

In an embodiment, CG₂ and CG₃ may each independently be a benzene group, a pyridine group, a pyrimidine group, a naphthalene group, a dibenzofuran group, a dibenzothiophene group, a carbazole group, a fluorene group, a dibenzosilole group, a naphthobenzofuran group, a naphthobenzothiophene group, a benzocarbazole group, a benzofluorene group, a naphthobenzosilole group, a dinaphthofuran group, a dinaphthothiophene group, a dibenzocarbazole group, a dibenzofluorene group, a dinaphthosilole group, an azadibenzofuran group, an azadibenzothiophene group, an azacarbazole group, an azafluorene group, an azadibenzosilole group, an azanaphthobenzofuran group, an azanaphthobenzothiophene group, an azabenzocarbazole group, an azabenzofluorene group, an azanaphthobenzosilole group, an azadinapthofuran group, an azadinapthothiophene group, an azadibenzocarbazole group, an azadibenzofluorene group, or an azadinapthosilole group.

In an embodiment, CG₂ and CG₃ may each independently be a benzene group, a pyridine group, a pyrimidine group, a naphthalene group, a dibenzofuran group, a dibenzothiophene group, a carbazole group, a fluorene group or a dibenzosilole group.

In embodiments, in Chemical Formula 1, CG₂ and CG₃ may be different from each other. In embodiments, in Chemical Formula 1, the number of carbon atoms in CG₂ may be less than the number of carbon atoms in CG₃. In an embodiment, CG₂ may be a benzene group and CG₃ may be a carbazole group

In Chemical Formula 1, X₅ may be a direct linkage (or a direct bond), *—N(R₅)—*′, *—B(R₅)—*′, *—P(R₅)—*′, *—C(R₅ₐ)(R_{5b})—*′, *—Si(R₅ₐ)(R_{5b})—*′, *—Ge(R₅ₐ)(R_{5b})—*′, *—S—*′, *—Se—*′, *—O—*, *—C(═O)—*′, *—S(═O)—*′, *—S(═O)₂—*′, *—C(R₅)═*′, *═C(R₅)—*′, *—C(R₅ₐ)═C(R_{5b})—*′, *—C(═S)—*′ or *—C≡C—*′.

In an embodiment, X₅ may be a direct linkage, CG₃ may be an N-containing heterocyclic ring, and X₅ may be bonded to an N atom of CG₃.

In Chemical Formula 1, Ar may be a substituted or unsubstituted C₆-C₆₀ aryl group, or a substituted or unsubstituted C₅-C₆₀ heteroaryl group. In an embodiment, Ar may be a substituted or unsubstituted C₆-C₃₀ aryl group.

In embodiments, Ar may include at least three aryl rings. For example, in an embodiment, Ar may include three or more benzene rings. For example, Ar may be a substituted or unsubstituted C₁₈-C₆₀ aryl group, or a substituted or unsubstituted C₁₅-C₆₀ heteroaryl group.

In embodiments, the number of carbon atoms in Ar may be greater than the number of carbon atoms in R₄. In an embodiment, in Chemical Formula 1, the number of carbon atoms in Ar may be greater than the number of carbon atoms in (R₄)ₐ₄.

In Chemical Formula 1, R, R₂ to R₄, R₅, R₅ₐ, and R_{5b} may each independently be hydrogen, deuterium, a halogen, a substituted or unsubstituted C₁-C₁₀ alkyl group, a substituted or unsubstituted C₂-C₁₀ alkenyl group, a substituted or unsubstituted C₂-C₁₀ alkynyl group, a substituted or unsubstituted C₆-C₃₀ aryl group, or a substituted or unsubstituted C₅-C₃₀ heteroaryl group.

In Chemical Formula 1, R₁ may be: hydrogen, deuterium, a halogen, a substituted or unsubstituted C₁-C₁₀ alkyl group, a substituted or unsubstituted C₂-C₁₀ alkenyl group, a substituted or unsubstituted C₂-C₁₀ alkynyl group, a substituted or unsubstituted C₆-C₃₀ aryl group, a substituted or unsubstituted C₅-C₃₀ heteroaryl group; a direct linkage bonded to Ar; or a substituted or unsubstituted C₁-C₁₀ alkylene group bonded to Ar.

In Chemical Formula 1, a, a1, a2, a3, and a4 may respectively represent the number of R, R₁, R₂, R₃, and R₄; and a, a1, a2, a3, and a4 may each independently be an integer from 0 to 20.

In an embodiment, a, a1, a2, a3, and a4 may each independently be an integer from 0 to 10. For example, a, a1, a2, a3, and a4 may each independently be an integer from 0 to 5.

In Chemical Formula 1, b1 may be 1 or 2. In an embodiment, b1 may be 1.

In embodiments, the organometallic compound may be represented by Chemical Formula 1-1:

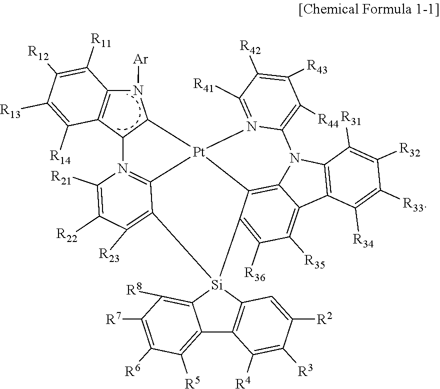

In Chemical Formula 1-1, R¹ to R⁸, R₁₁ to R₁₄, R₂₁ to R₂₃, R₃₁ to R₃₆, and R₄₁ to R₄₄ may each independently be hydrogen, deuterium, a halogen, a substituted or unsubstituted C₁-C₁₀ alkyl group, a substituted or unsubstituted C₂-C₁₀ alkenyl group, a substituted or unsubstituted C₂-C₁₀ alkynyl group, a substituted or unsubstituted C₆-C₃₀ aryl group, or a substituted or unsubstituted C₅-C₃₀ heteroaryl group; and Ar may be the same as defined in Chemical Formula 1.

In embodiments, in Chemical Formula 1-1, at least one of R₄₁ to R₄₄ may each independently include a substituted or unsubstituted aryl group, or a substituted or unsubstituted heteroaryl group; and the number of carbon atoms in the aryl group or the heteroaryl group included in R₄₁ to R₄₄ may be less than the number of carbon atoms in Ar.

Accordingly, a degree of asymmetry of the organometallic compound may be increased. Thus, molecular aggregation may be prevented more effectively, and an energy gap reduction effect between a host and a dopant may be implemented more efficiently.

As described above, Ar may include three or more benzene rings. Accordingly, rotational characteristics between a benzene ring in Ar and a benzene ring of the organometallic compound may be implemented at either side of a central benzene ring, and molecular bulkiness may be further increased. Therefore, the effects of preventing molecular aggregation and a reduction of an energy gap between the host and the dopant may be more efficiently implemented.

In embodiments, the organometallic compound may be represented by Chemical Formula 1-2:

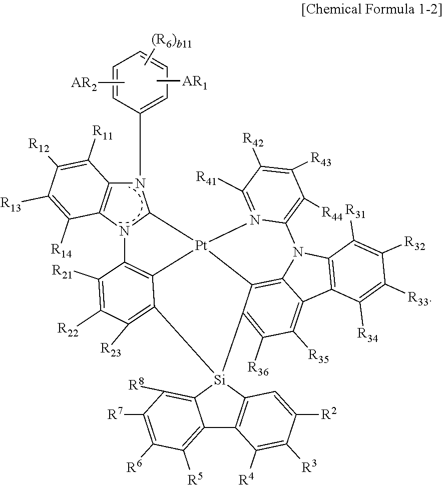

In Chemical Formula 1-2, Ar₁ and Ar₂ may each independently be a substituted or unsubstituted C₆-C₃₀ aryl group, a substituted or unsubstituted C₅-C₃₀ heteroaryl group. In Chemical Formula 1-2, R₆ may each independently be hydrogen, deuterium, a halogen, a substituted or unsubstituted C₁-C₁₀ alkyl group, a substituted or unsubstituted C₂-C₁₀ alkenyl group, or a substituted or unsubstituted C₂-C₁₀ alkynyl group. In Chemical Formula 1-2, R¹ to R⁸, R₁₁ to R₁₄, R₂₁ to R₂₃, R₃₁ to R₃₆, and R₄₁ to R₄₄ may each be the same as described above.

In Chemical Formula 1-2, b₁₁ may be an integer from 0 to 3.

In embodiments, at least one of Ar₁ and Ar₂ may include a substituent, and at least one among the substituent and R₆ may include a tertiary alkyl group. Accordingly, Ar may further increase bulkiness of the organometallic compound.

In embodiments, at least one of Ar₁ and Ar₂ may have a structure fused to or condensed with a cycloalkyl group. For example, at least one of Ar₁ and Ar₂ may include alkyl substituents bonded to different carbon atoms, and the alkyl substituents may be bonded to each other to form a ring.

In an embodiment, in Chemical Formula 1-2, at least one of Ar₁ and Ar₂ may each independently be a substituted or unsubstituted C₆-C₃₀ aryl group condensed with a cycloalkyl group, or a substituted or unsubstituted C₅-C₃₀ heteroaryl group condensed with a cycloalkyl group.

In an embodiment, in Chemical Formula 1-2, at least one of Ar₁ and Ar₂ may each independently be represented by

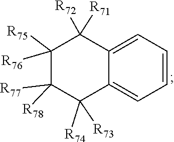

and R₇₁ to R₇₈ may each independently be hydrogen, deuterium, a halogen, a substituted or unsubstituted C₁-C₁₀ alkyl group, a substituted or unsubstituted C₂-C₁₀ alkenyl group, or a substituted or unsubstituted C₂-C₁₀ alkynyl group.

In an embodiment, R₇₁ to R₇₄ may each independently be a substituted or unsubstituted C₁-C₁₀ alkyl group; and R₇₅ to R₇₈ may each independently be hydrogen or deuterium.

In embodiments, in Chemical Formula 1 as described above, R₁ may be bonded to Ar. In an embodiment, the organometallic compound may be represented by Chemical Formula 1-3:

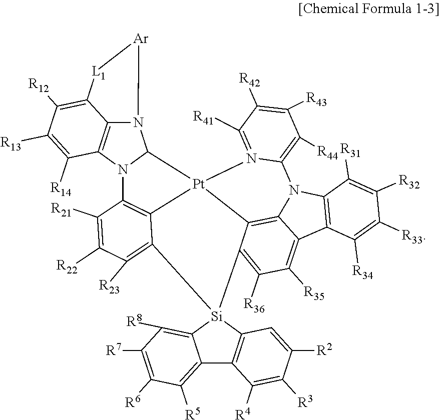

In Chemical Formula 1-3, L₁ may be a direct linkage or a substituted or unsubstituted C₁-C₁₀ alkylene group. In an embodiment, L₁ may be a direct linkage. In Chemical Formula 1-3, R¹ to R⁸, R₁₂ to R₁₄, R₂₁ to R₂₃, R₃₁ to R₃₆, and R₄₁ to R₄₄ may each be the same as described above.

According to Chemical Formula 1-3, Ar may form a bridge structure to a benzimidazole group. Accordingly, bulkiness and structural complexity of a moiety bonded to the benzimidazole group may be further increased, thereby adding distortion to the molecule.

Thus, a highest occupied molecular orbital (HOMO) energy level of the organometallic compound may have a deeper value (for example, a greater absolute value), while further contributing to the prevention of molecular aggregation.

In embodiments, at least one benzene ring may be included between a benzene ring bonded to the N atom of the benzimidazole group and a benzene ring in L₁ bonded to Ar. Accordingly, rotation and a twist between the benzene rings may be readily induced.

In an embodiment, the organometallic compound may be represented by Chemical Formula 1-4:

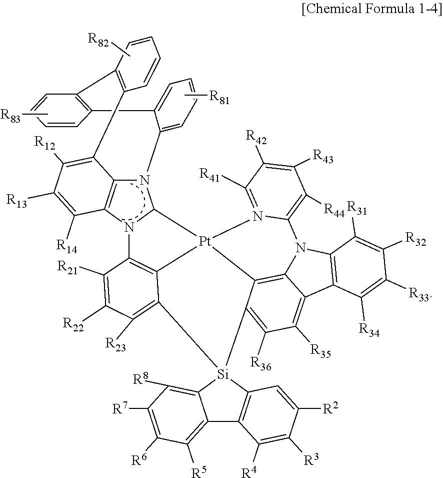

In Chemical Formula 1-4, R₈₁ to R₈₃ may each independently be hydrogen, deuterium, a halogen, a substituted or unsubstituted C₁-C₁₀ alkyl group, a substituted or unsubstituted C₂-C₁₀ alkenyl group, a substituted or unsubstituted C₂-C₁₀ alkynyl group, a substituted or unsubstituted C₆-C₃₀ aryl group, or a substituted or unsubstituted C₅-C₃₀ heteroaryl group. In Chemical Formula 1-4, R¹ to R⁸, R₁₁ to R₁₄, R₂₁ to R₂₃, R₃₁ to R₃₆, and R₄₁ to R₄₄ may each be the same as described above.

In an embodiment, at least one of R₈₁ to R₈₃ may each independently be a substituted or unsubstituted C₆-C₃₀ aryl group, or a substituted or unsubstituted C₅-C₃₀ heteroaryl group.

In an embodiment, the organometallic compound represented by Formula 1 may be one of Compounds DP-1 to DP-150. In an embodiment, an emission layer of a light-emitting device may include at least one compound selected from Compounds DP-1 to DP-150.

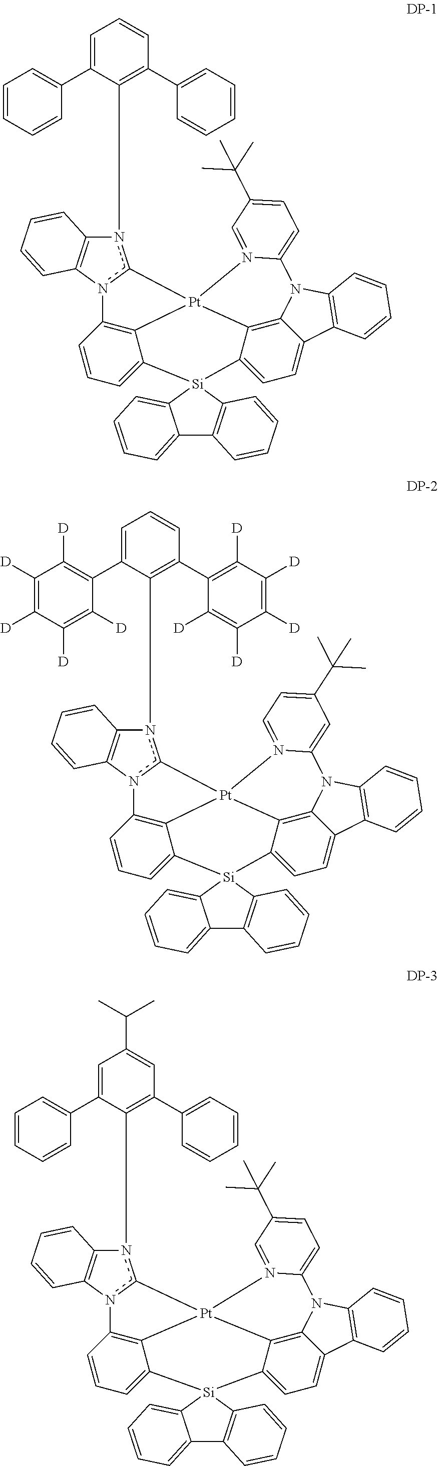

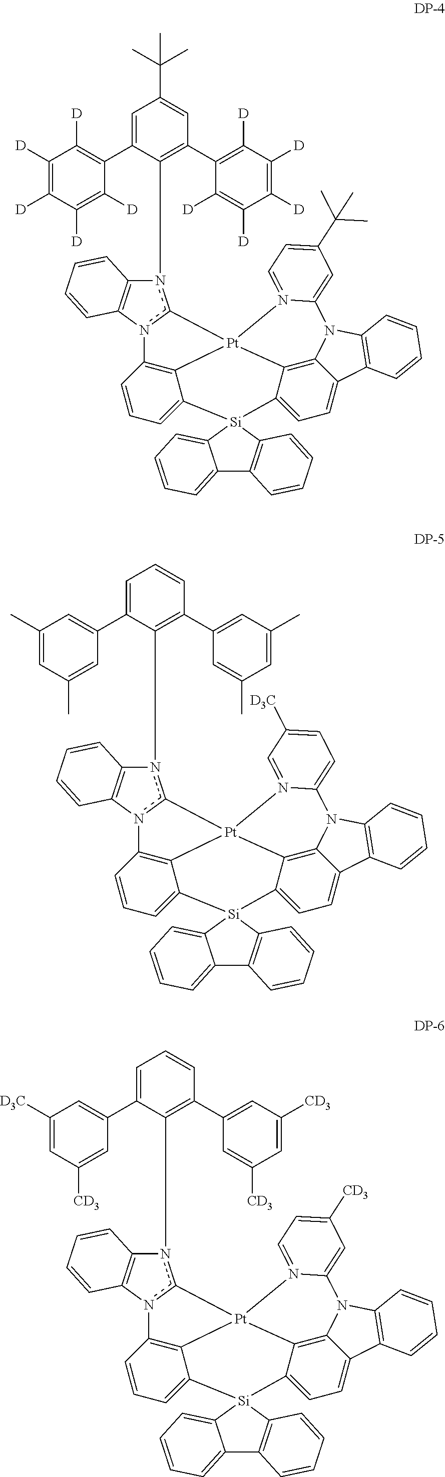

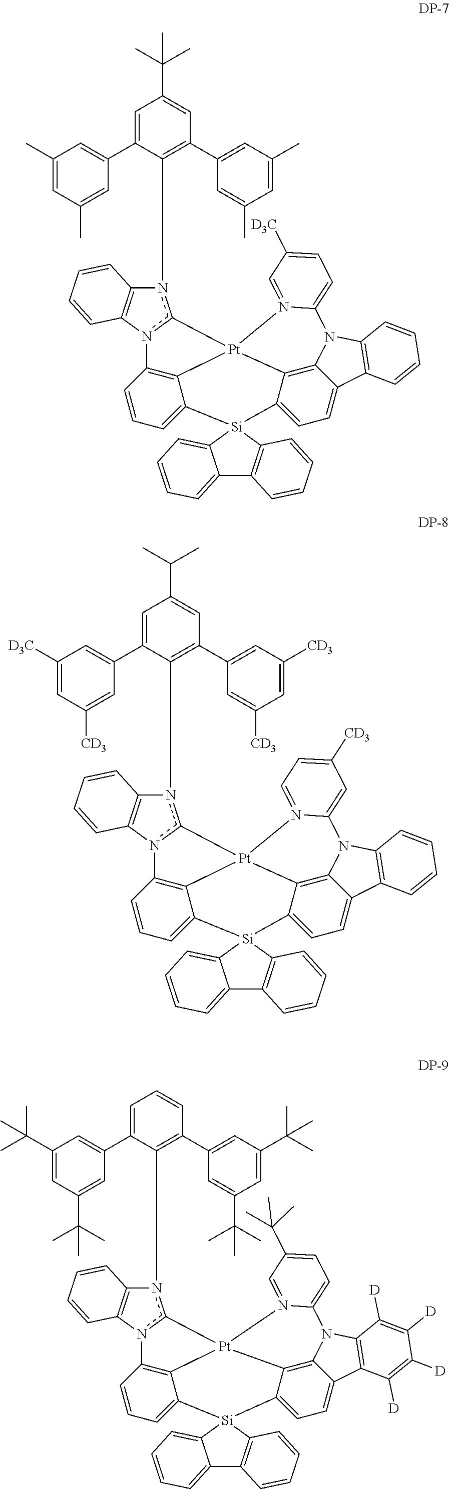

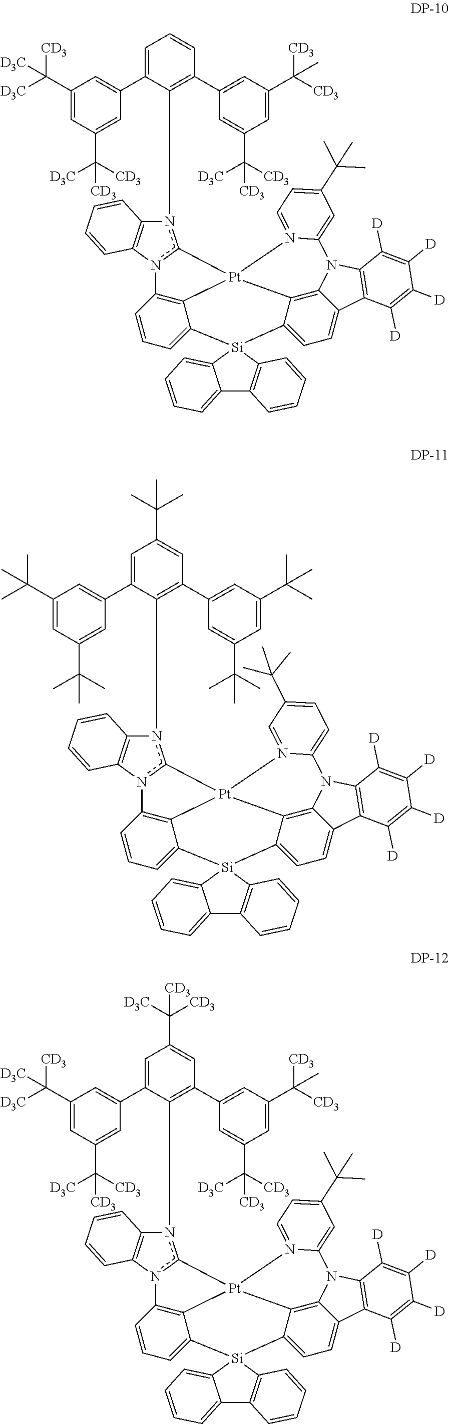

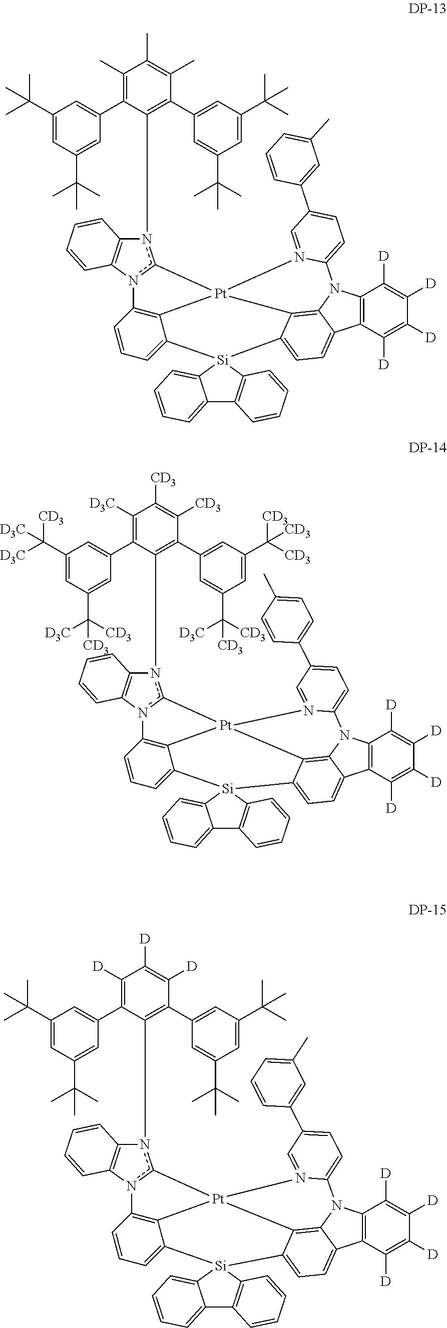

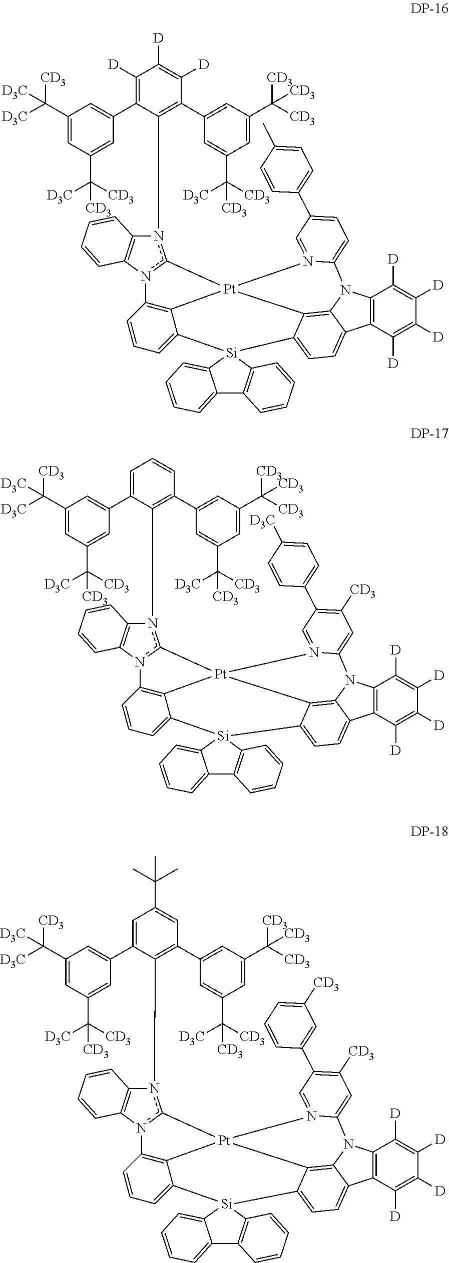

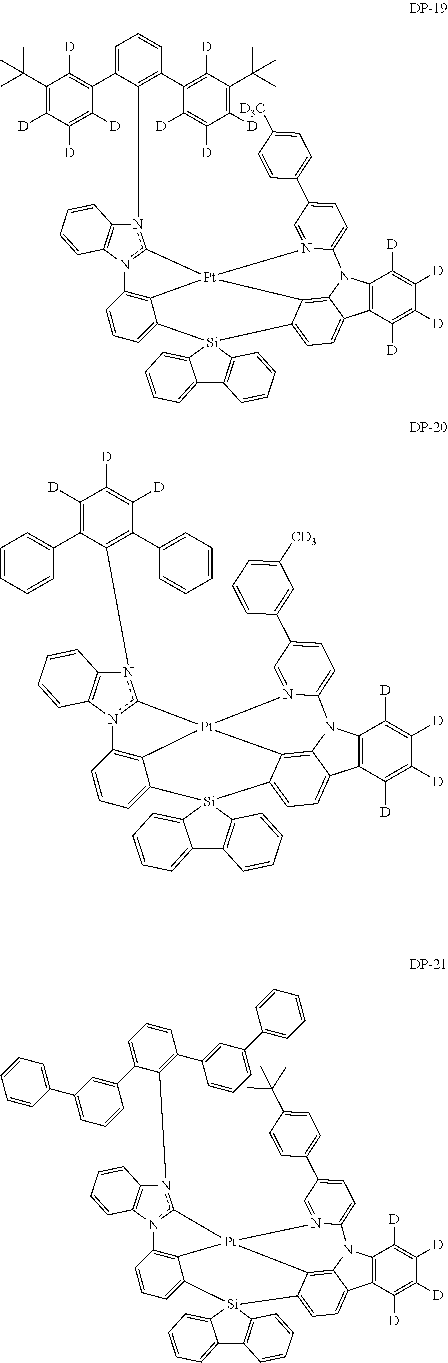

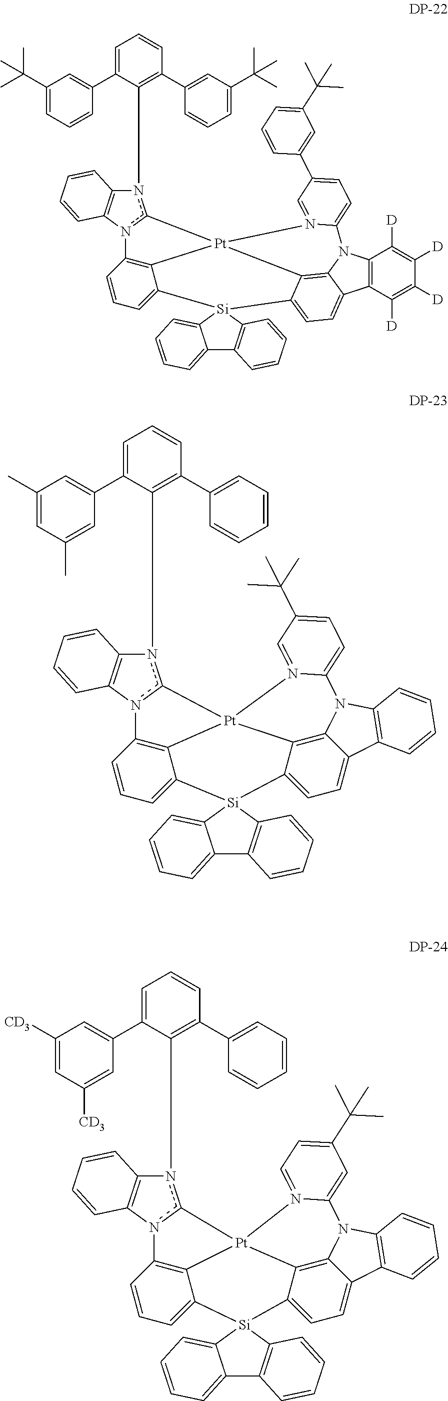

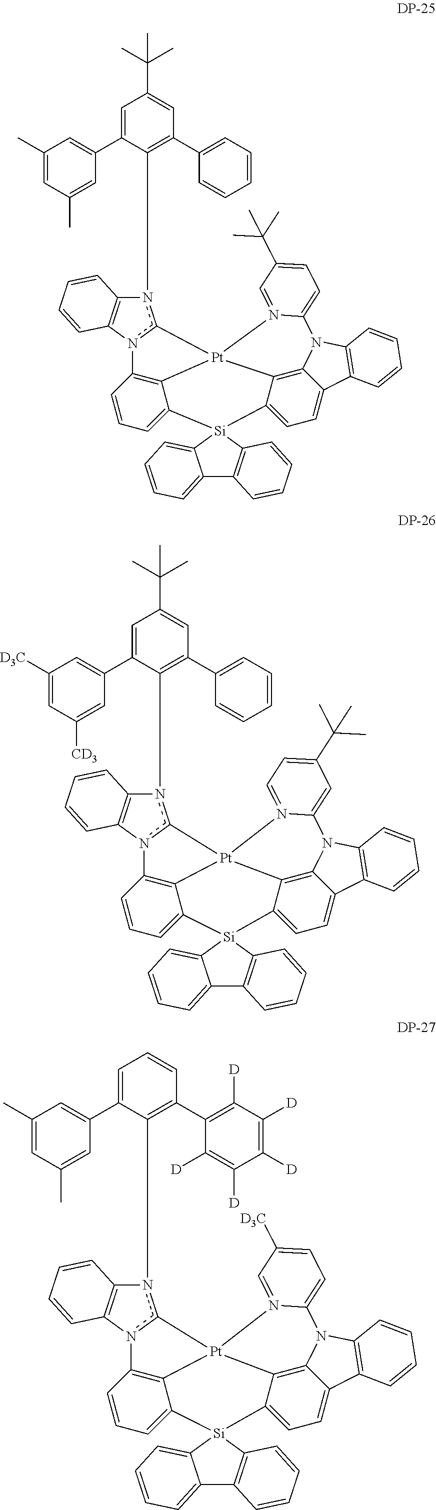

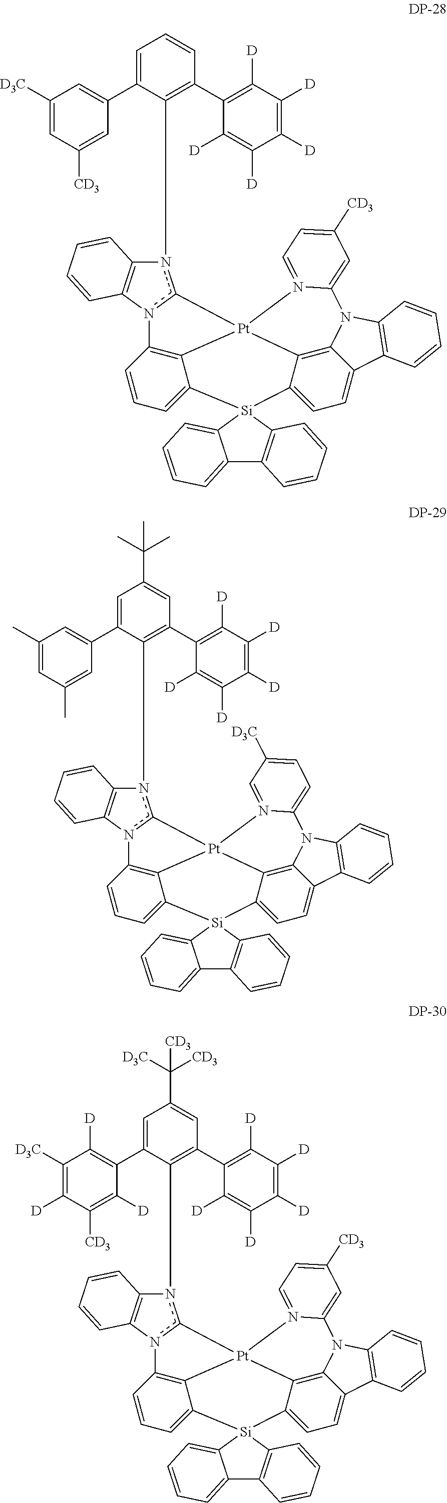

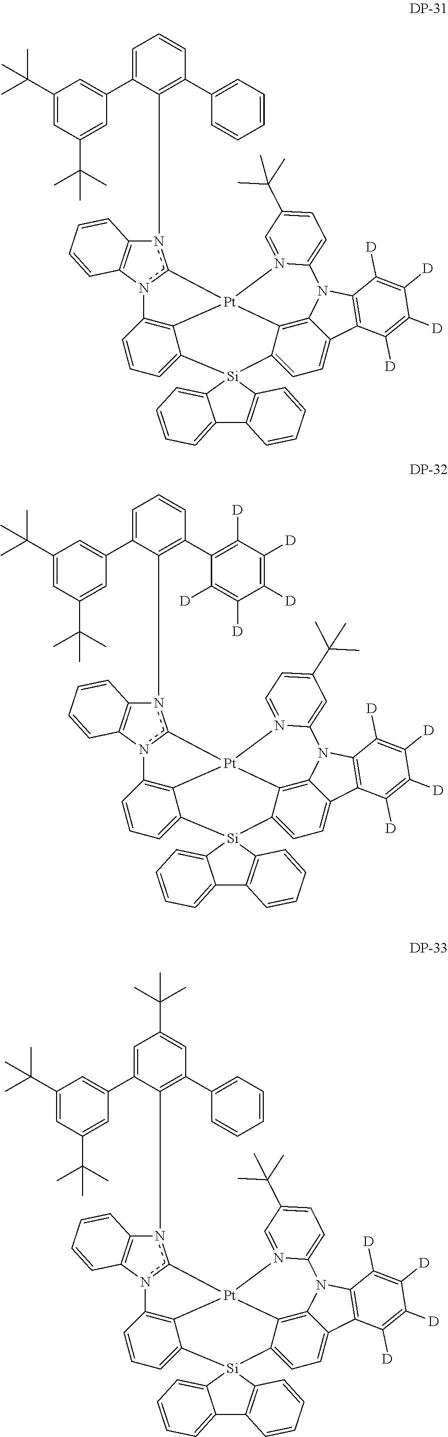

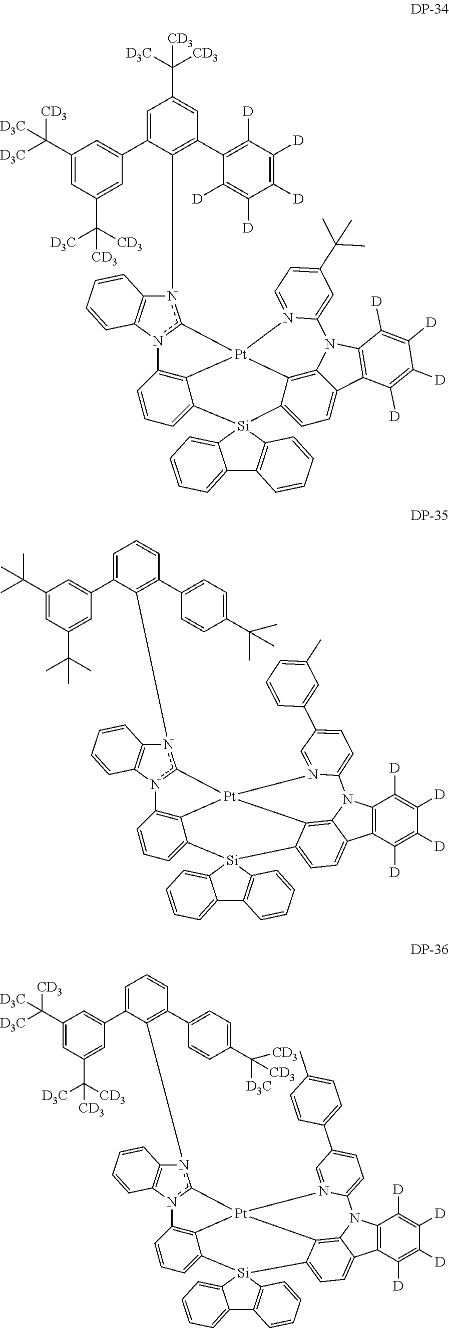

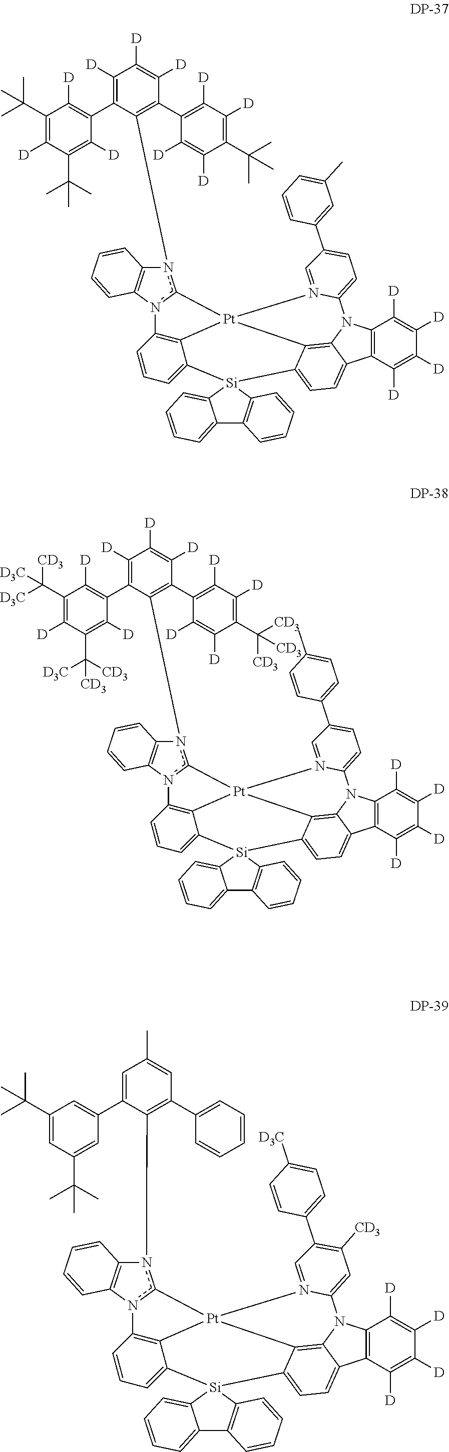

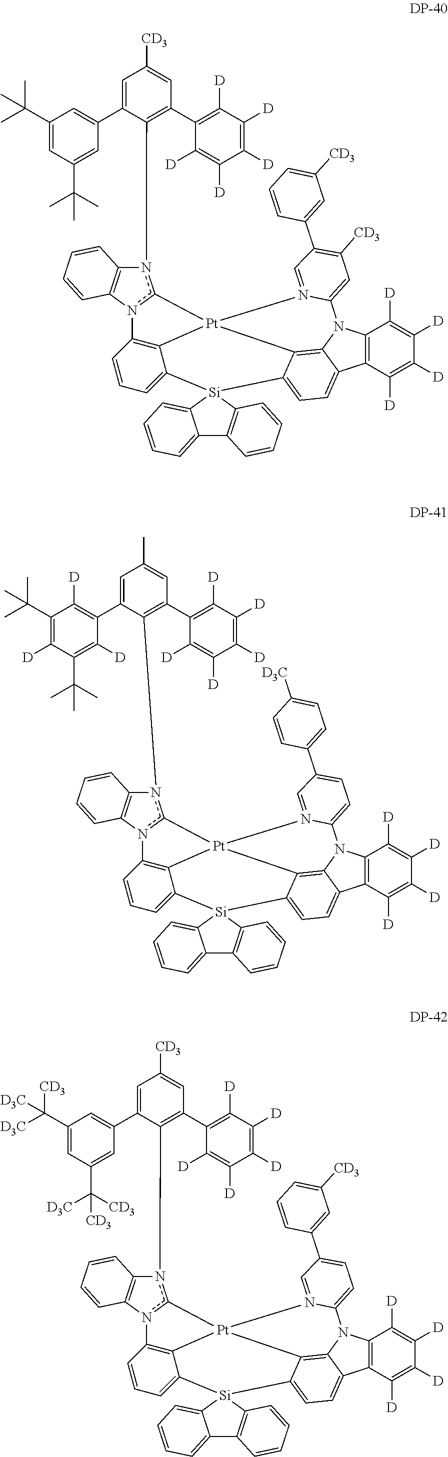

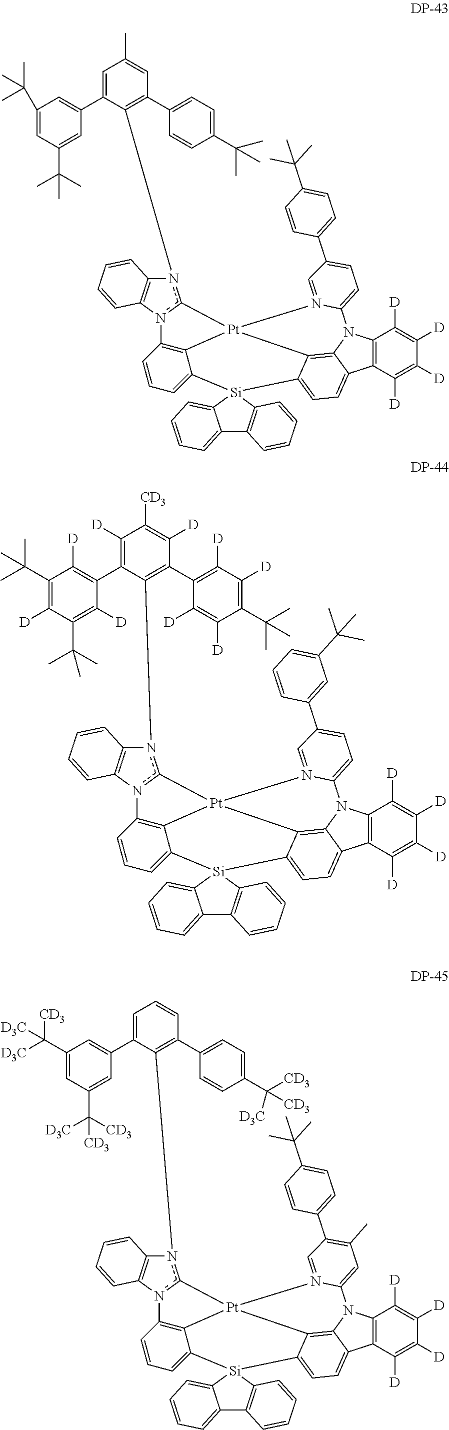

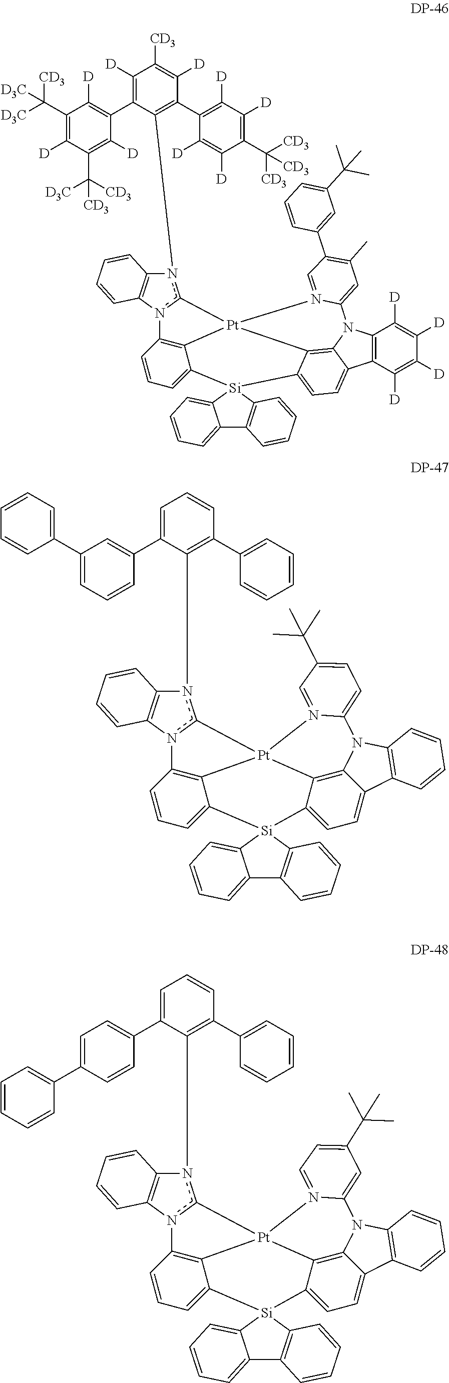

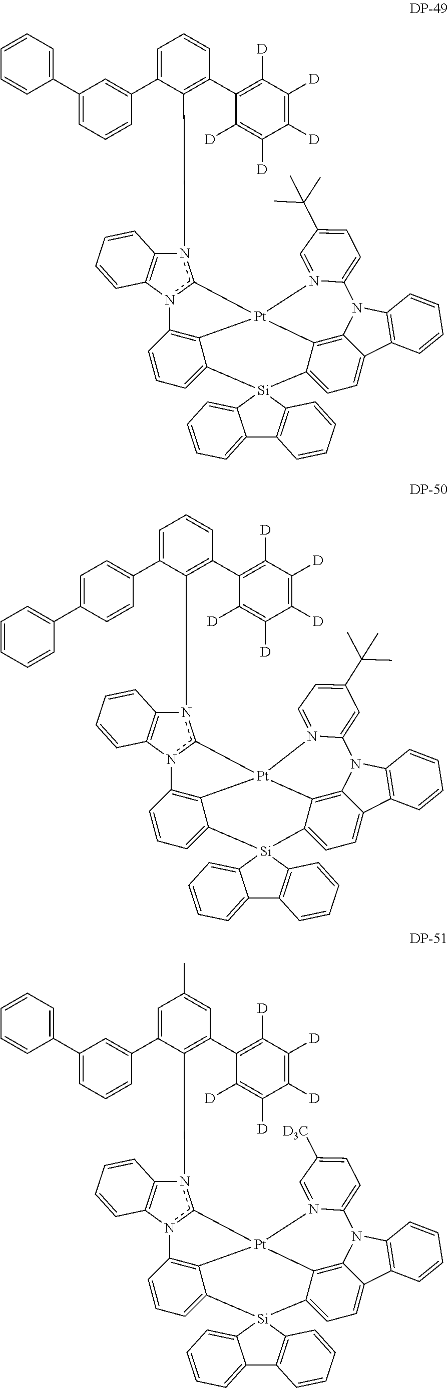

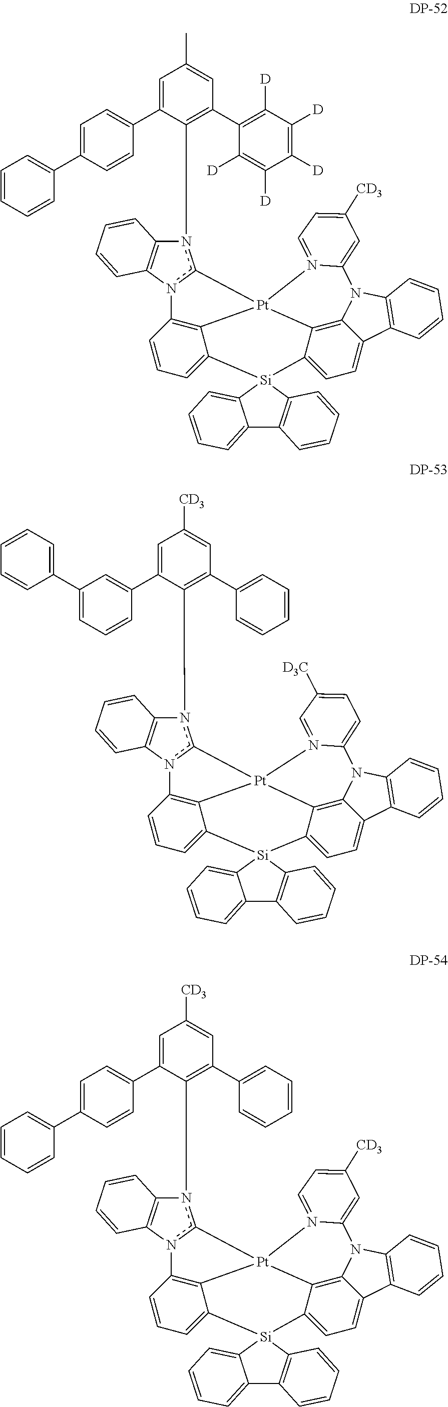

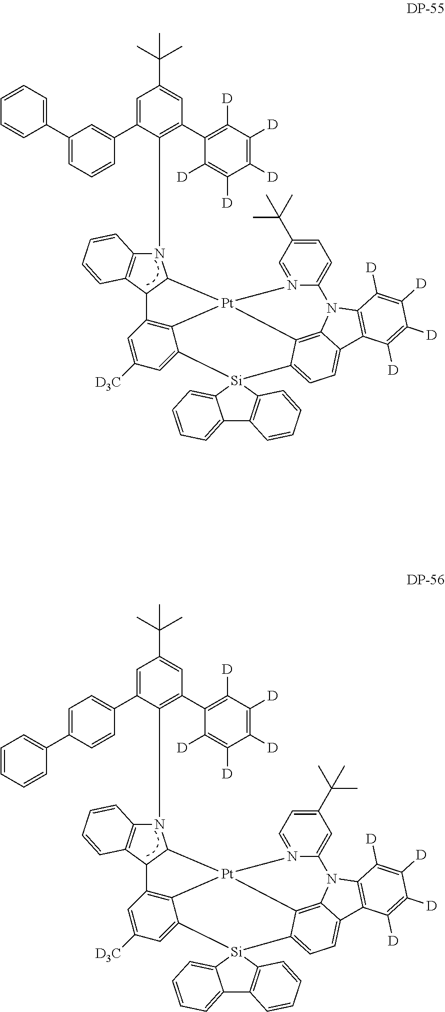

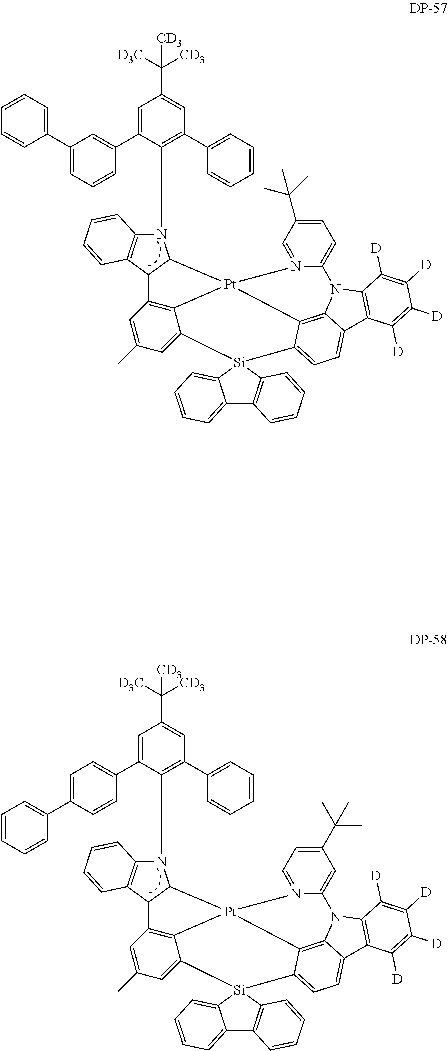

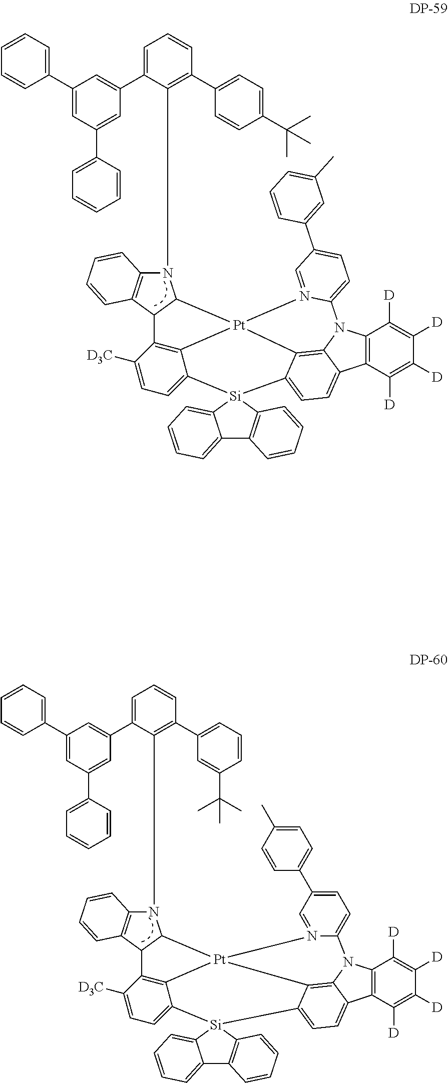

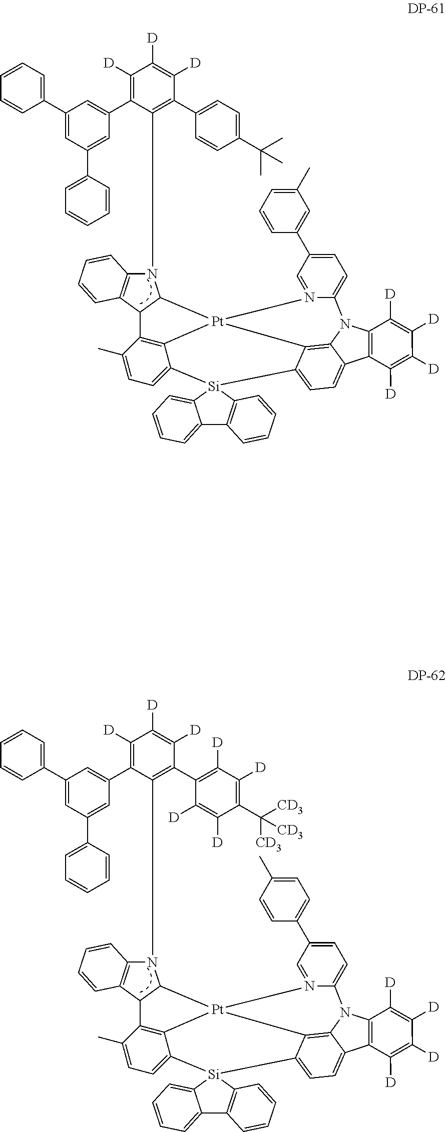

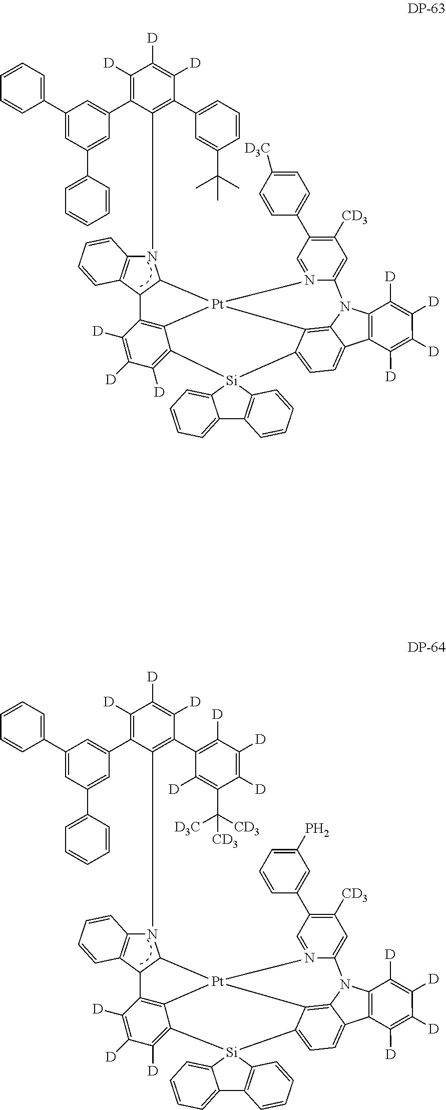

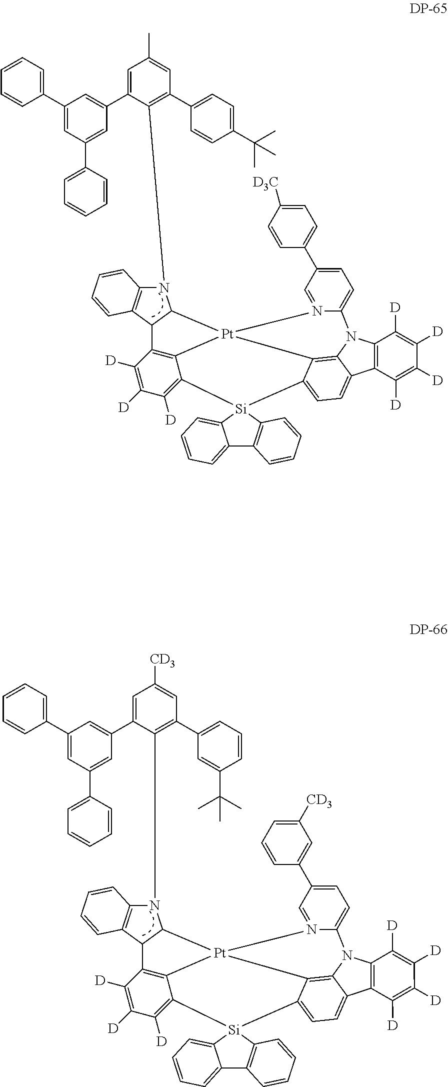

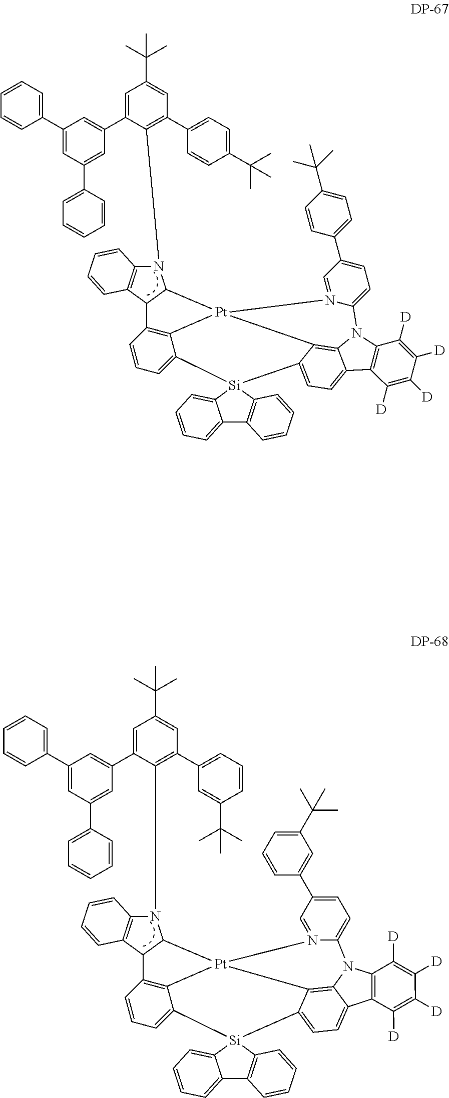

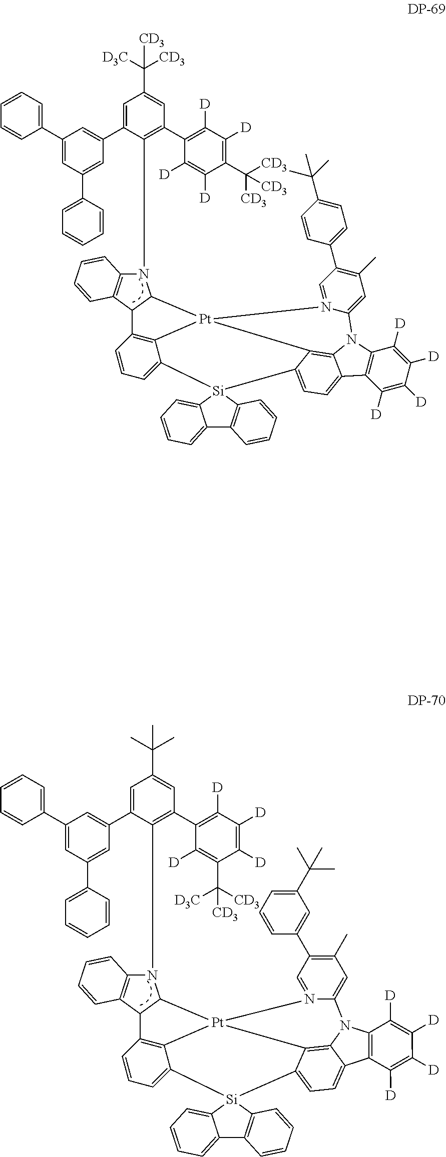

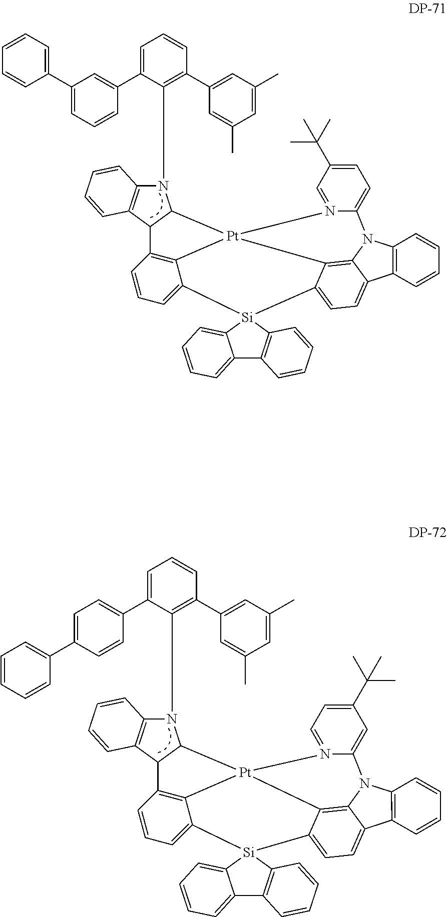

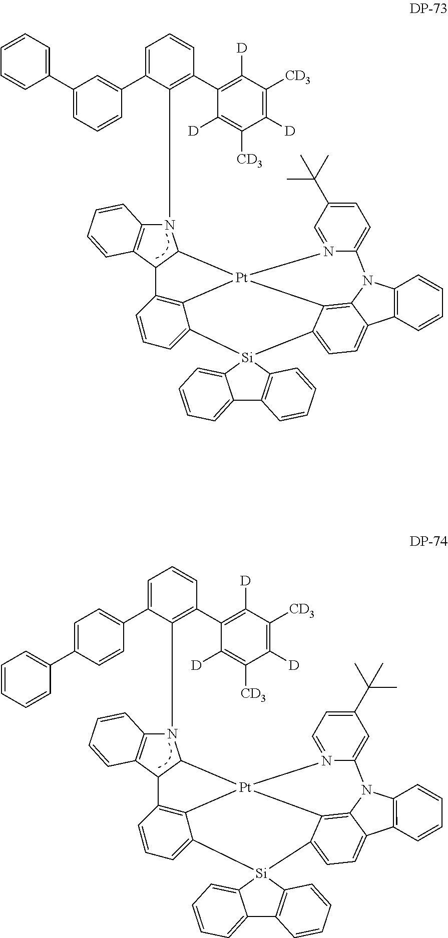

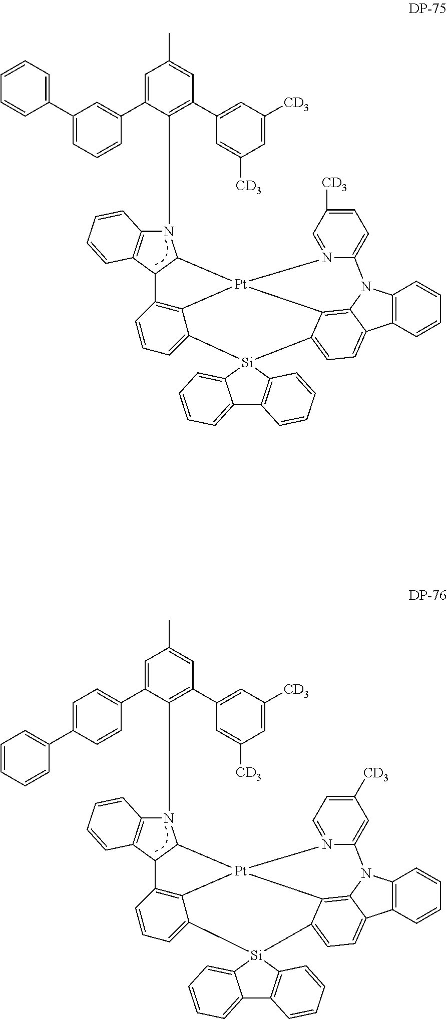

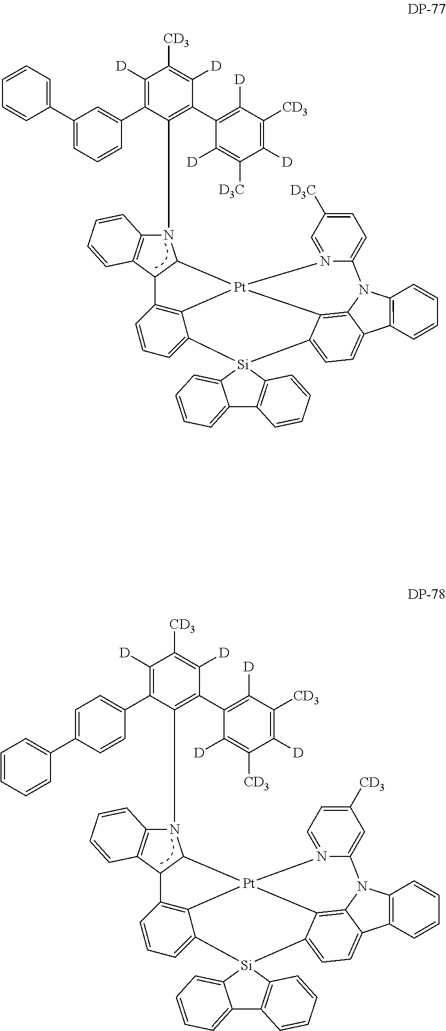

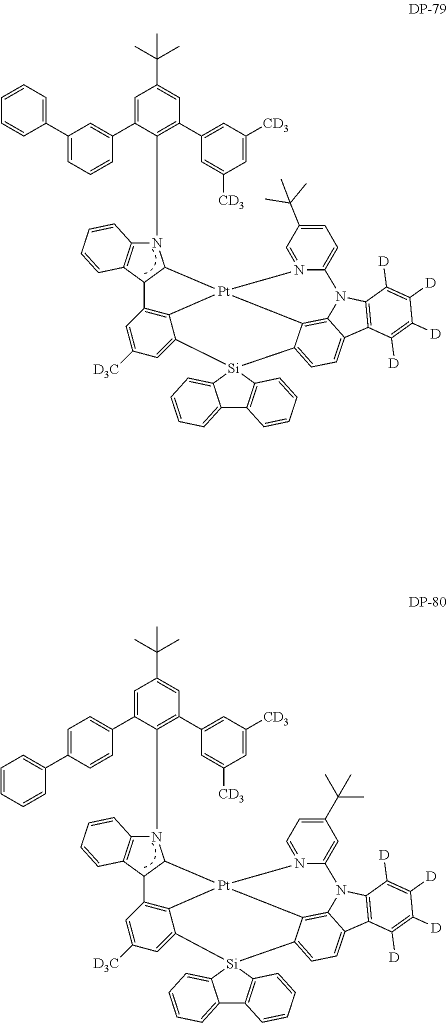

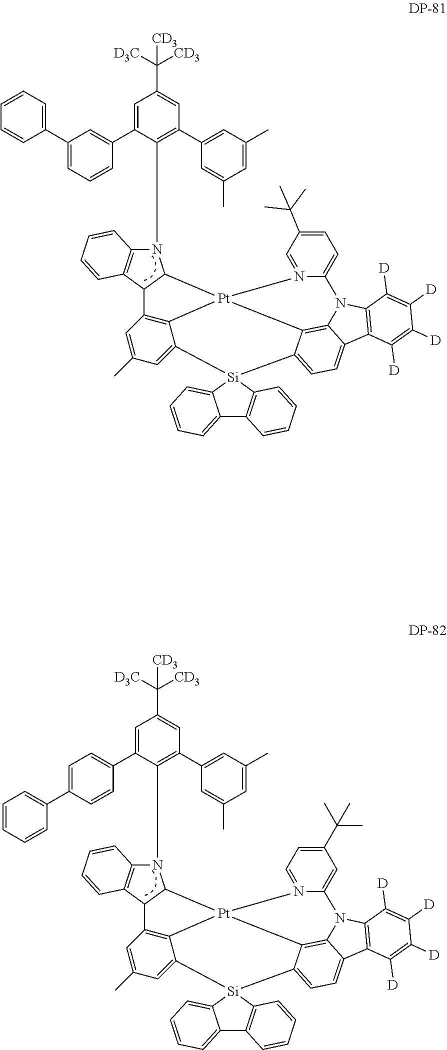

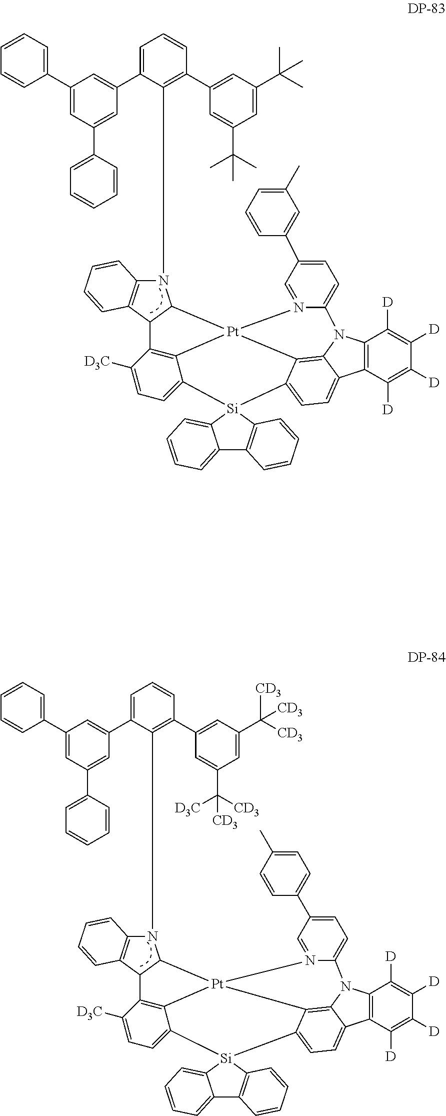

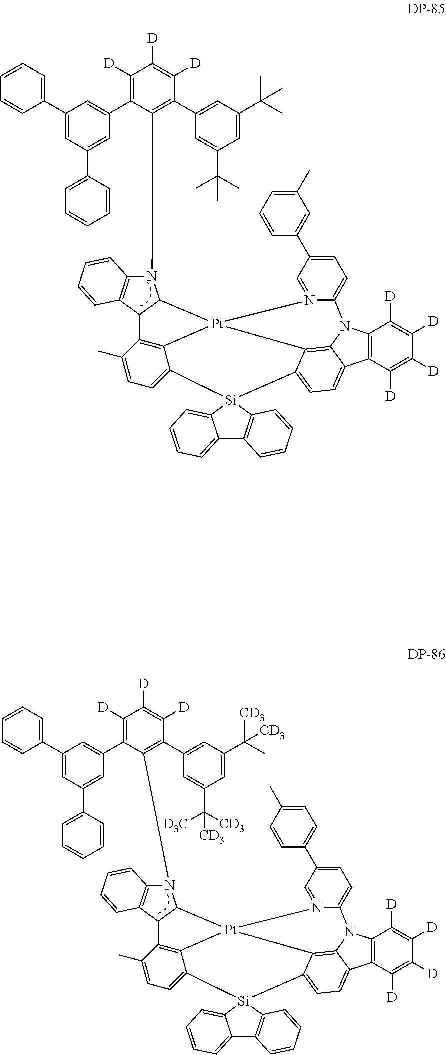

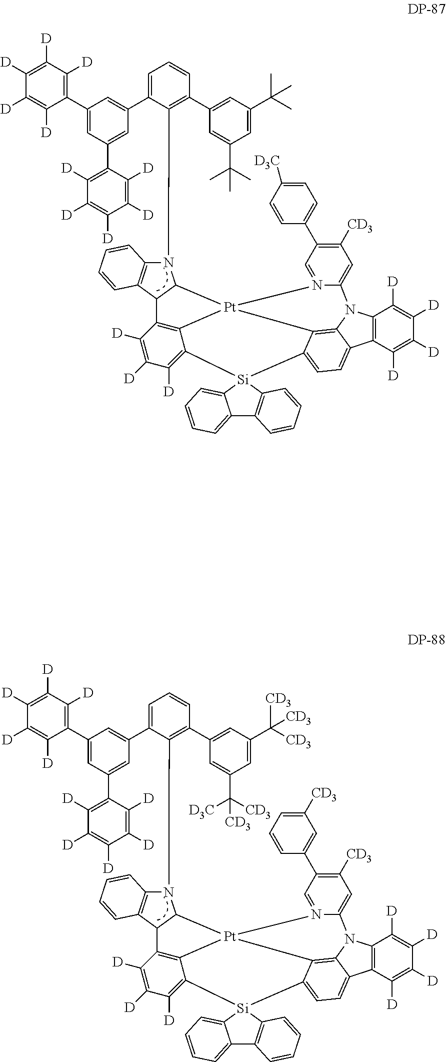

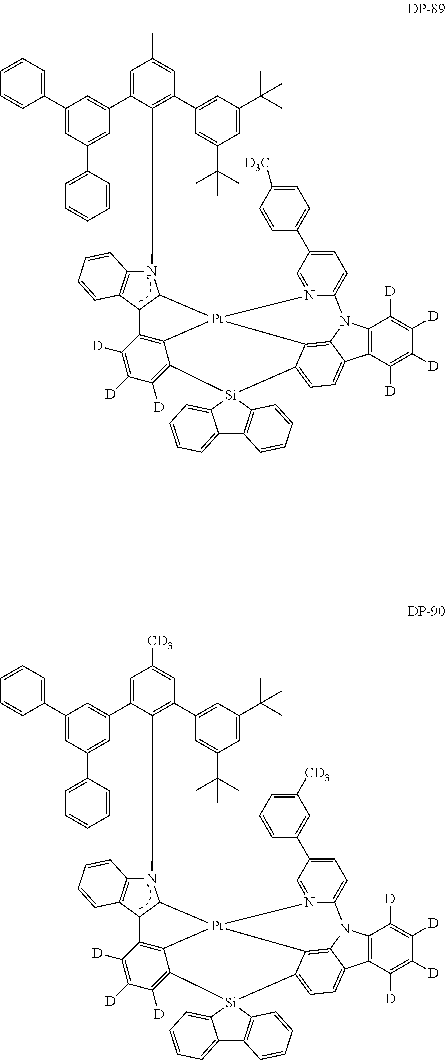

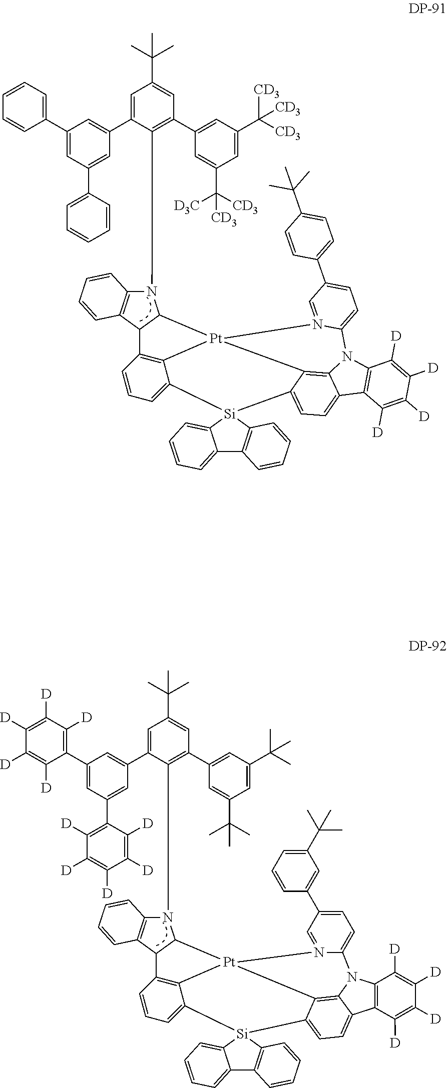

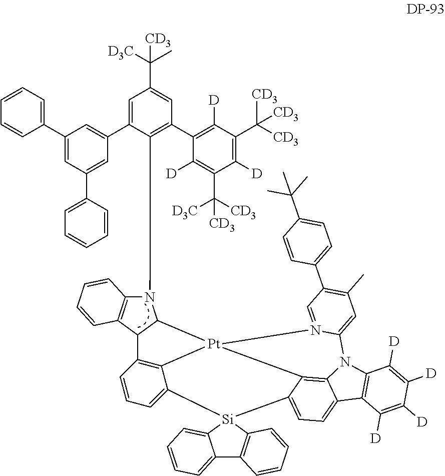

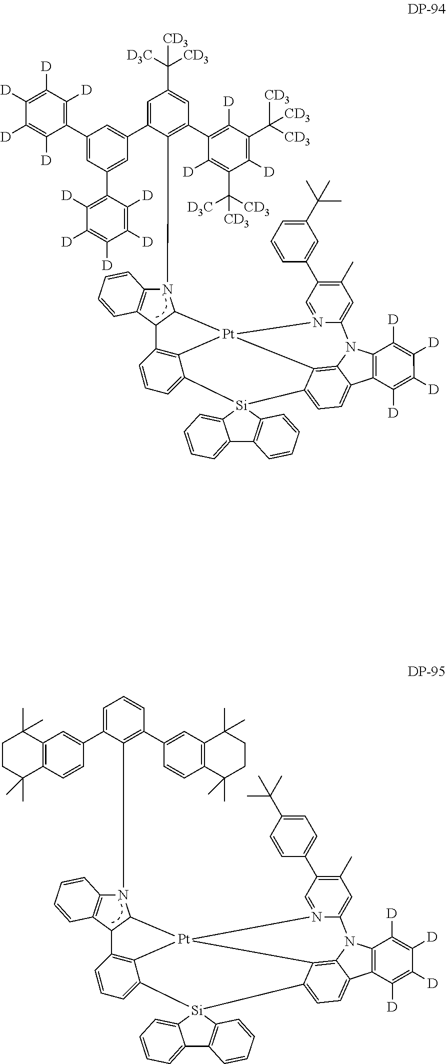

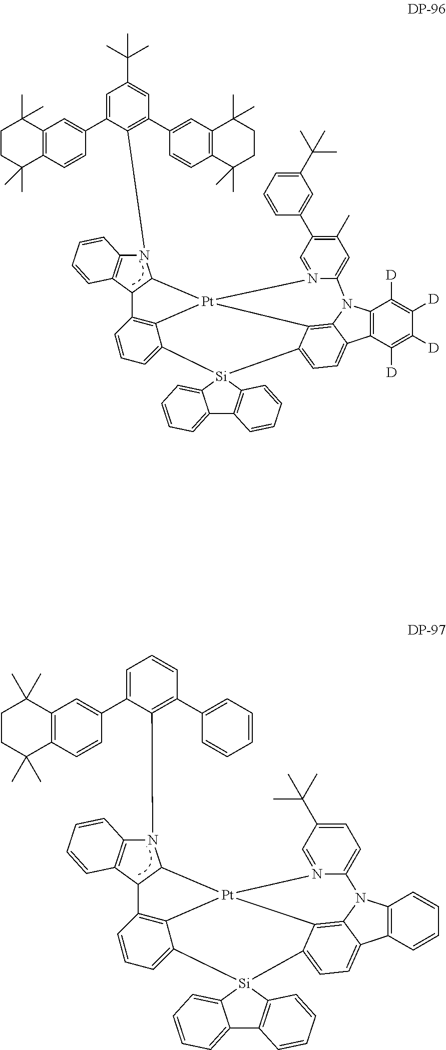

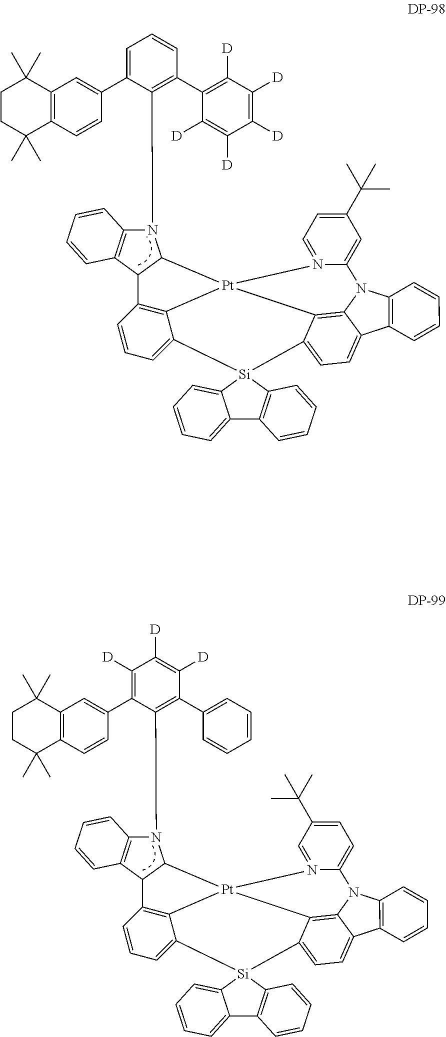

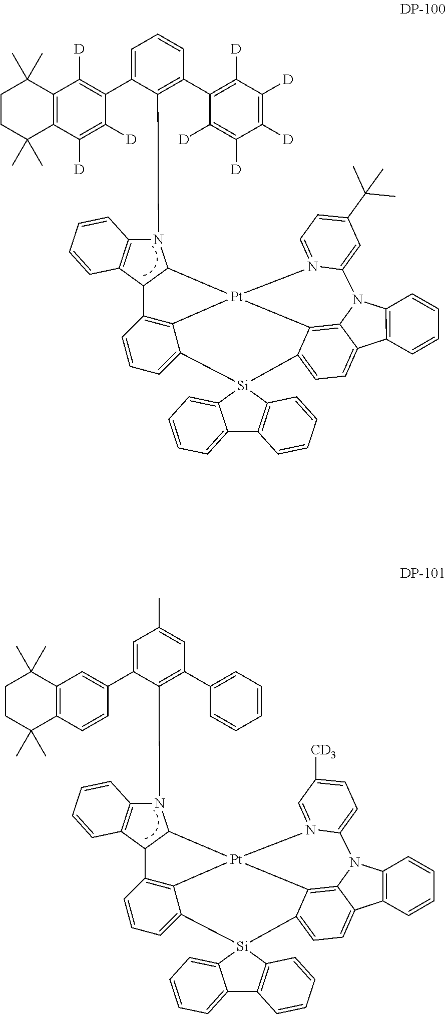

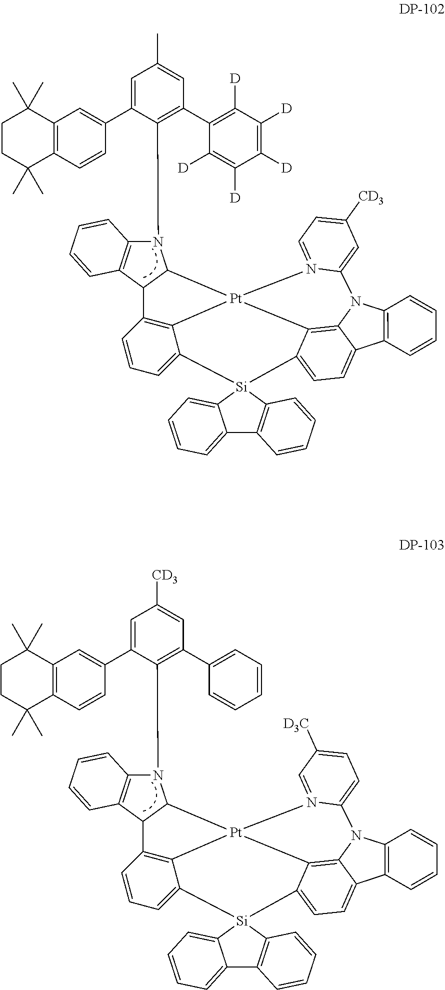

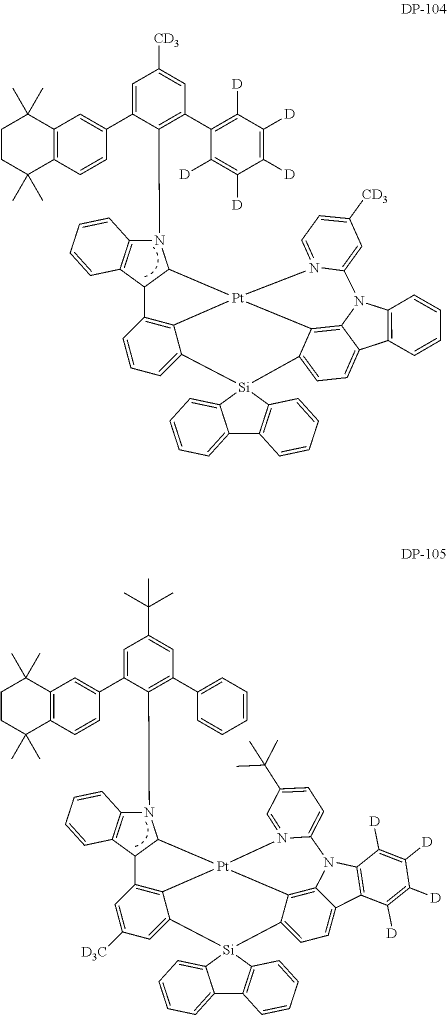

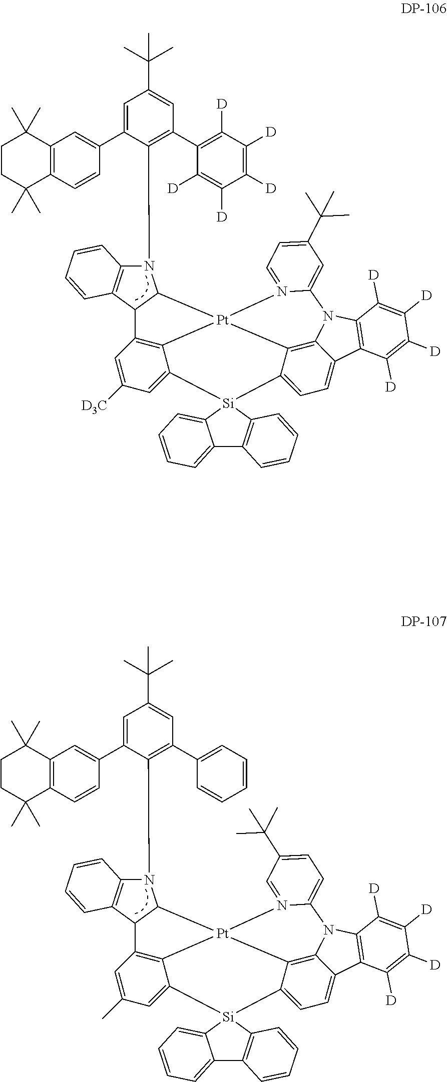

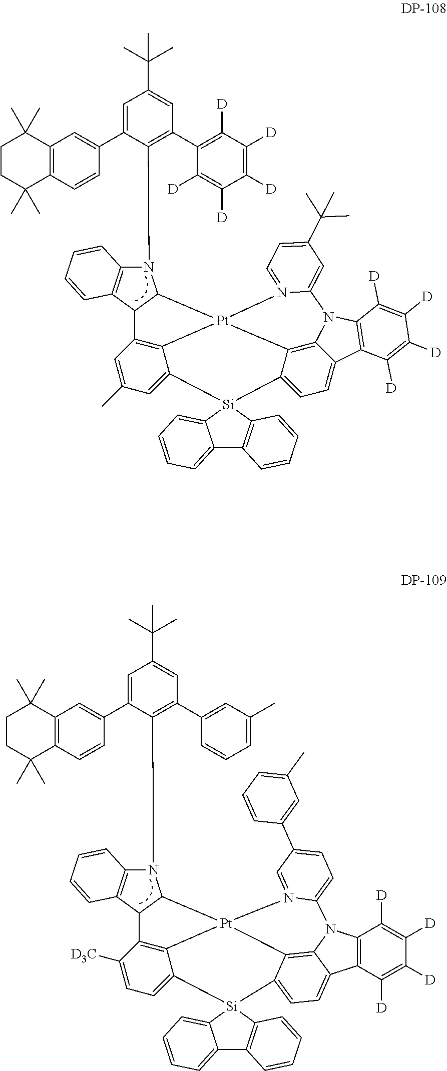

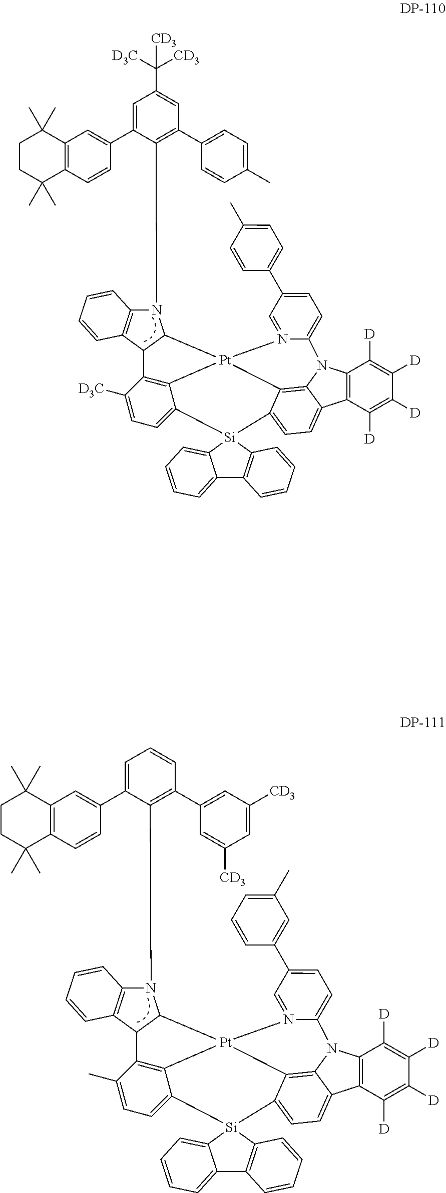

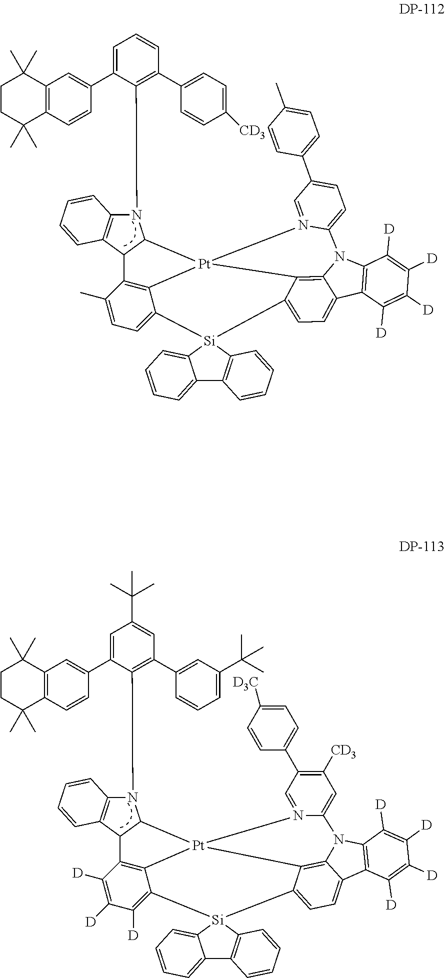

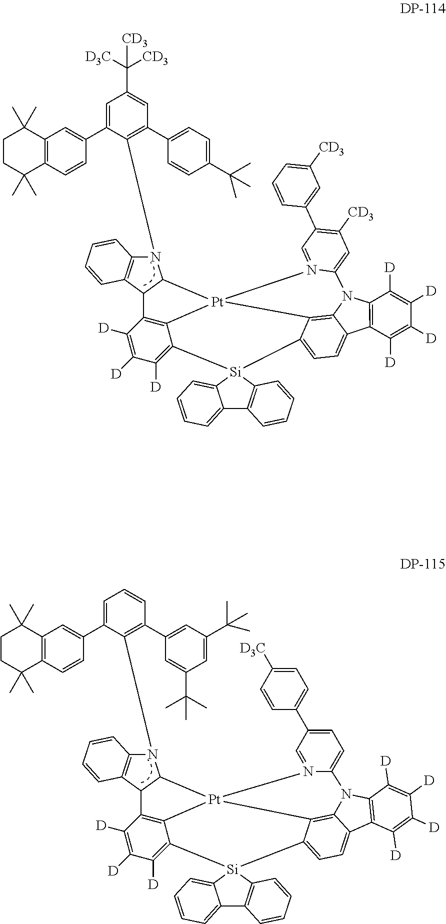

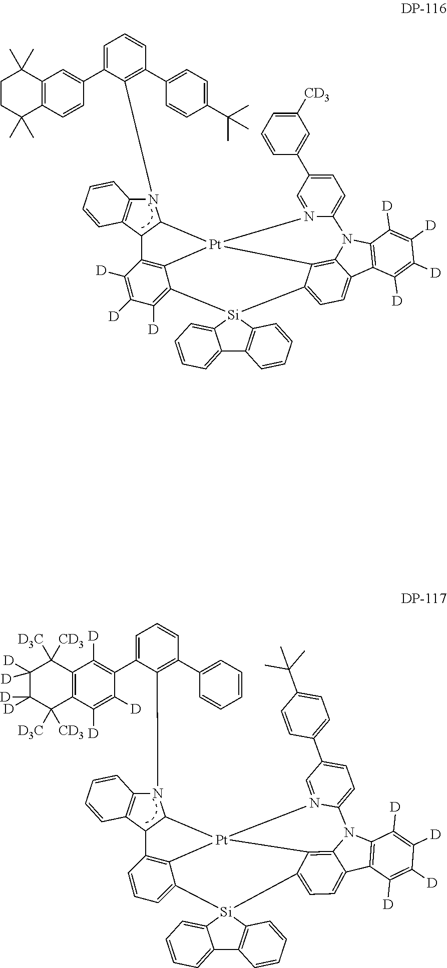

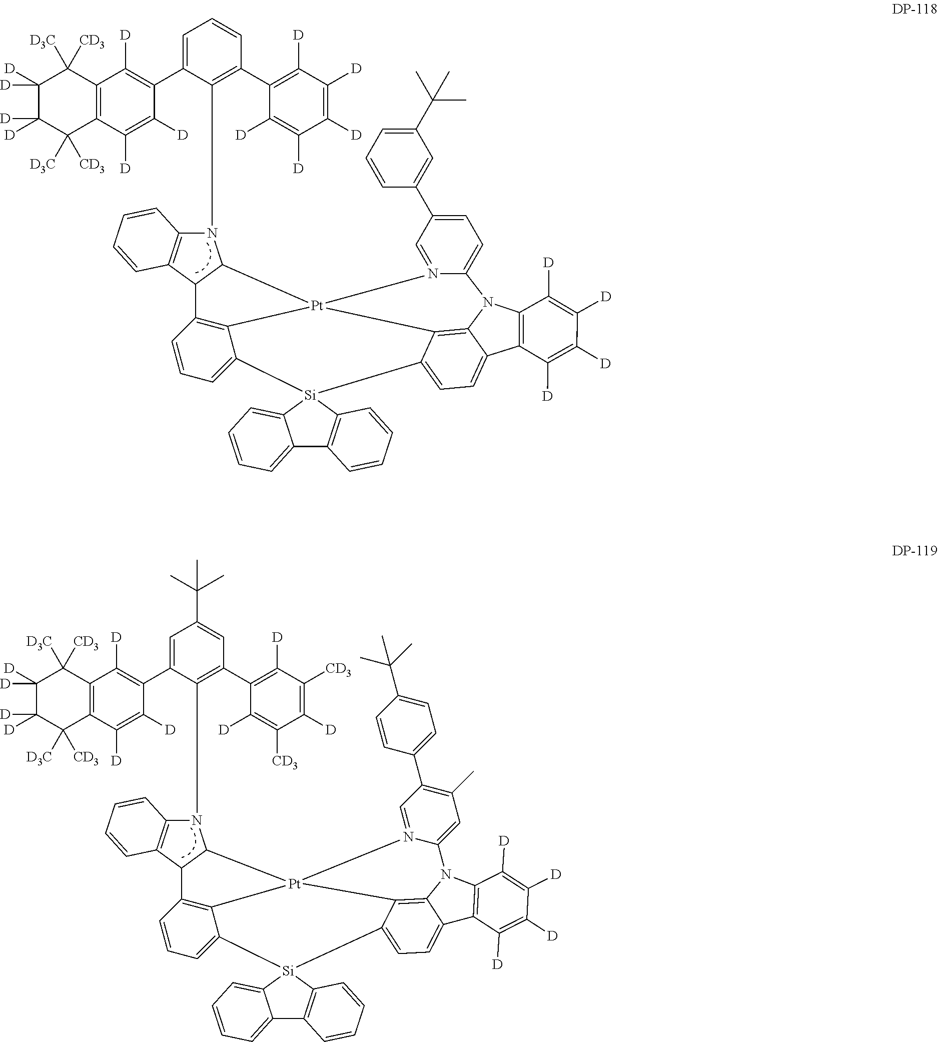

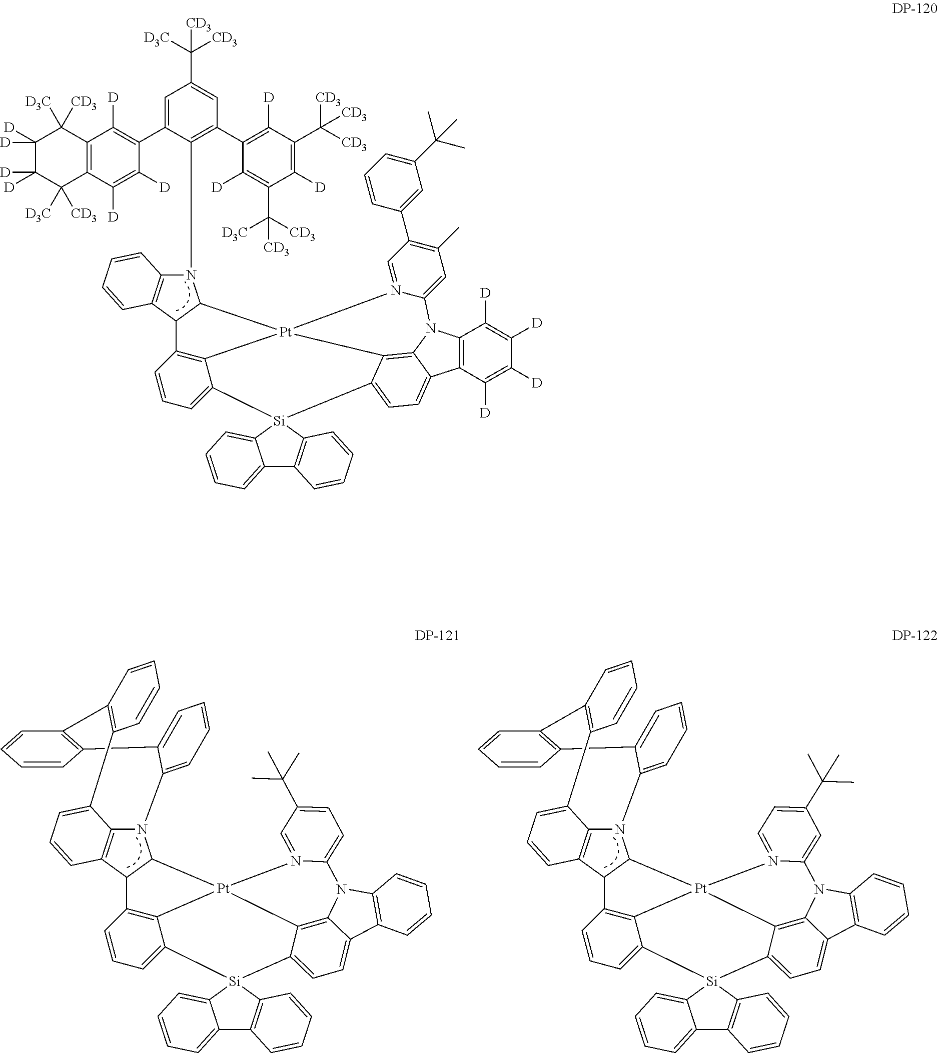

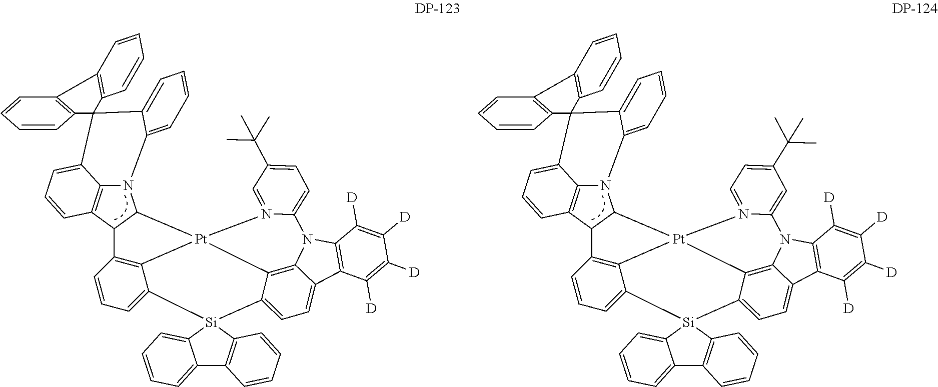

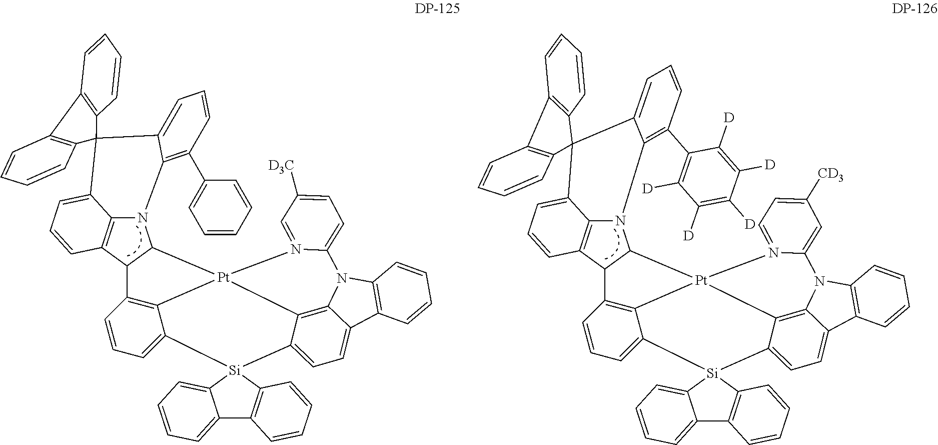

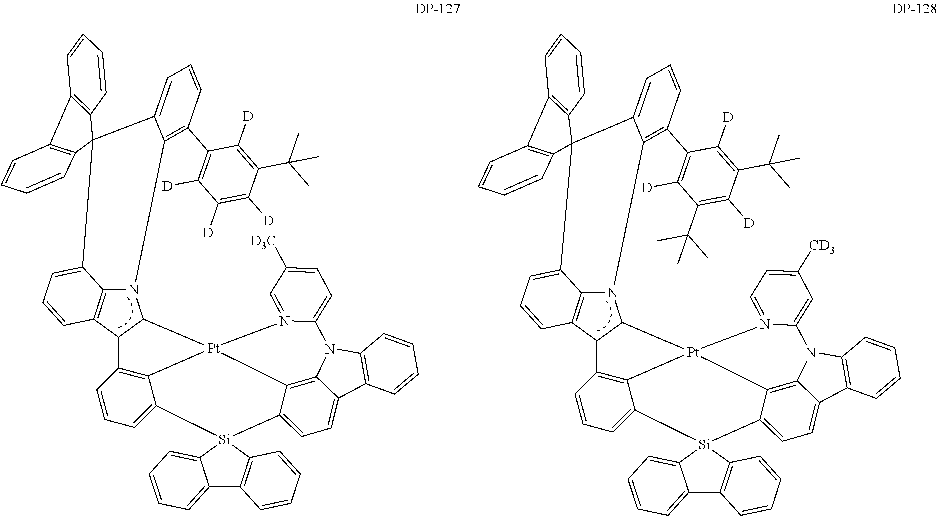

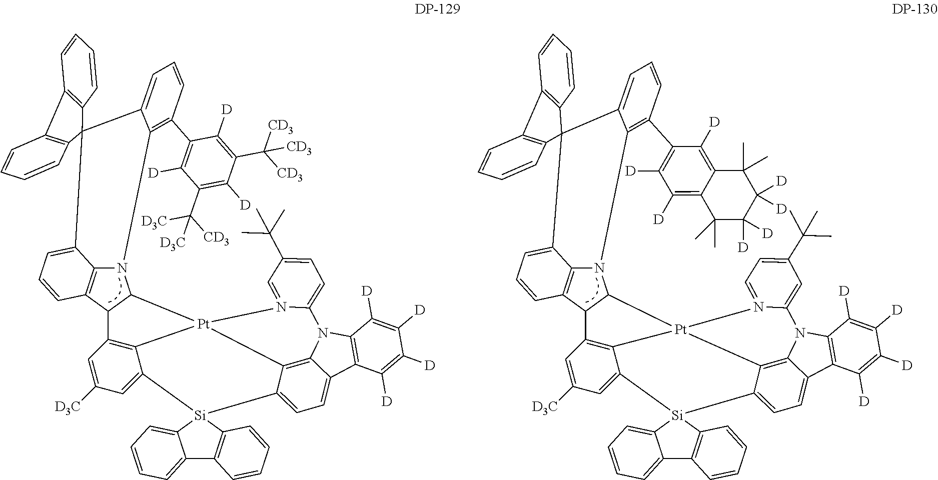

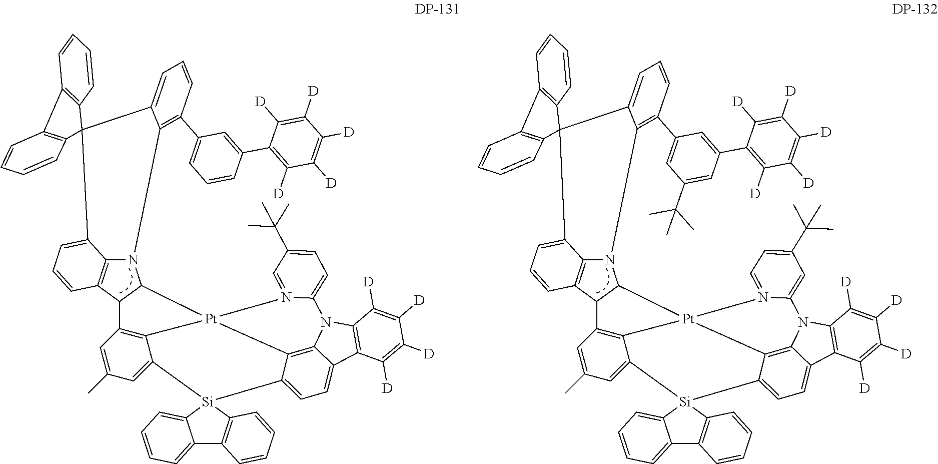

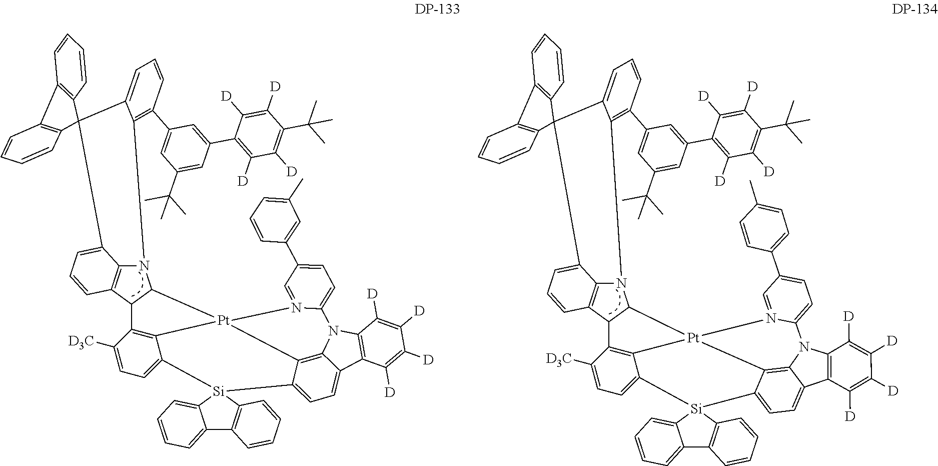

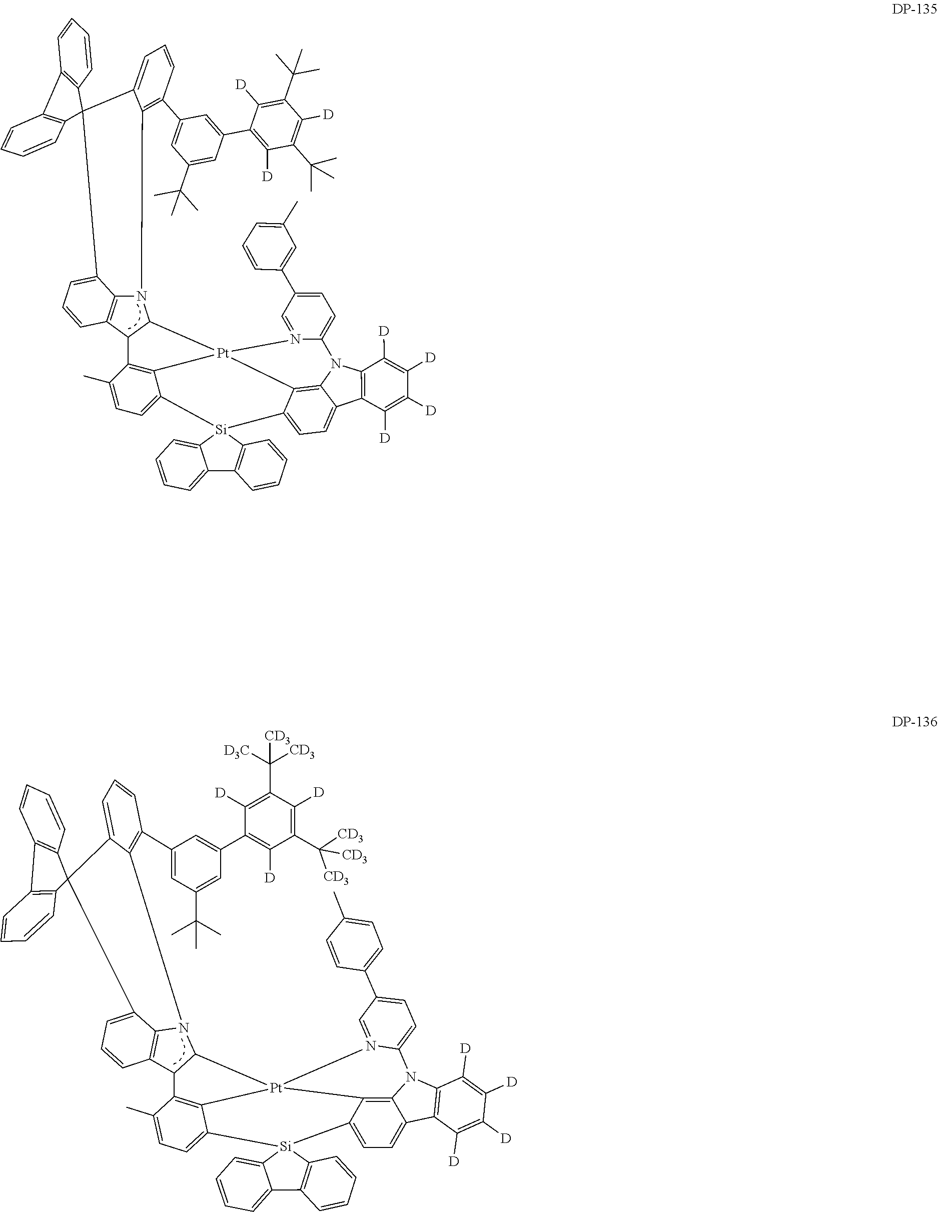

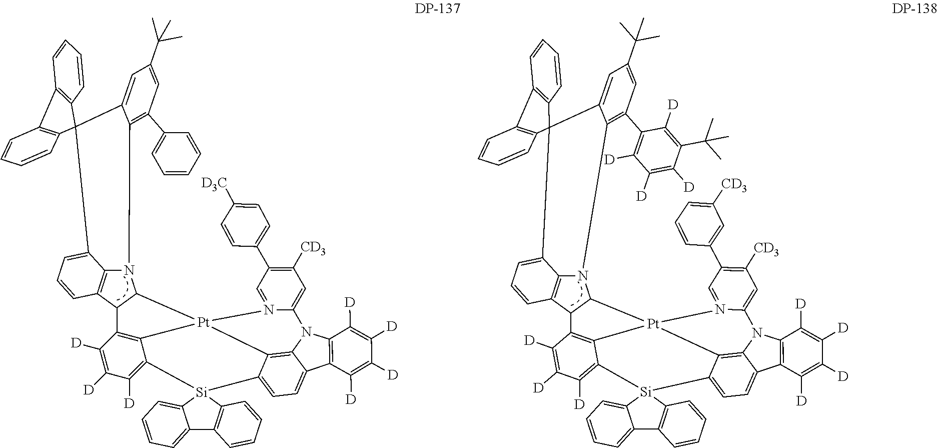

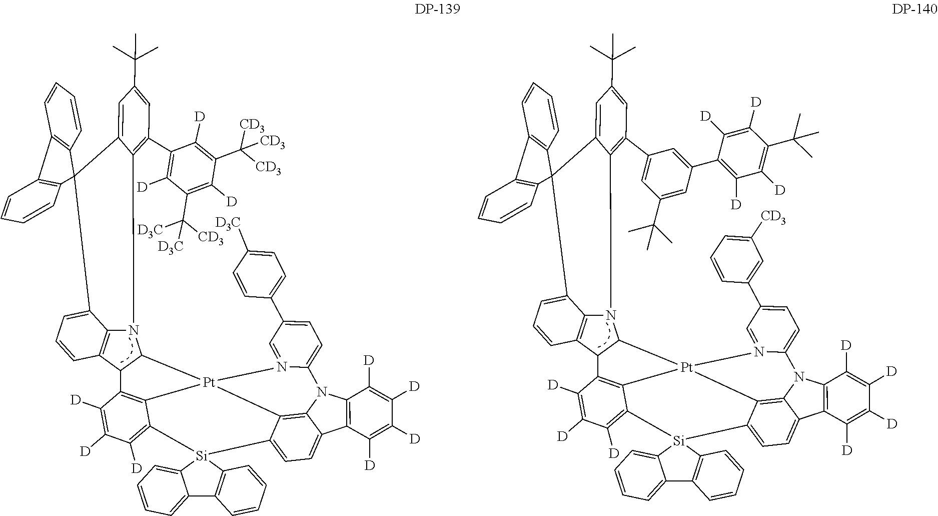

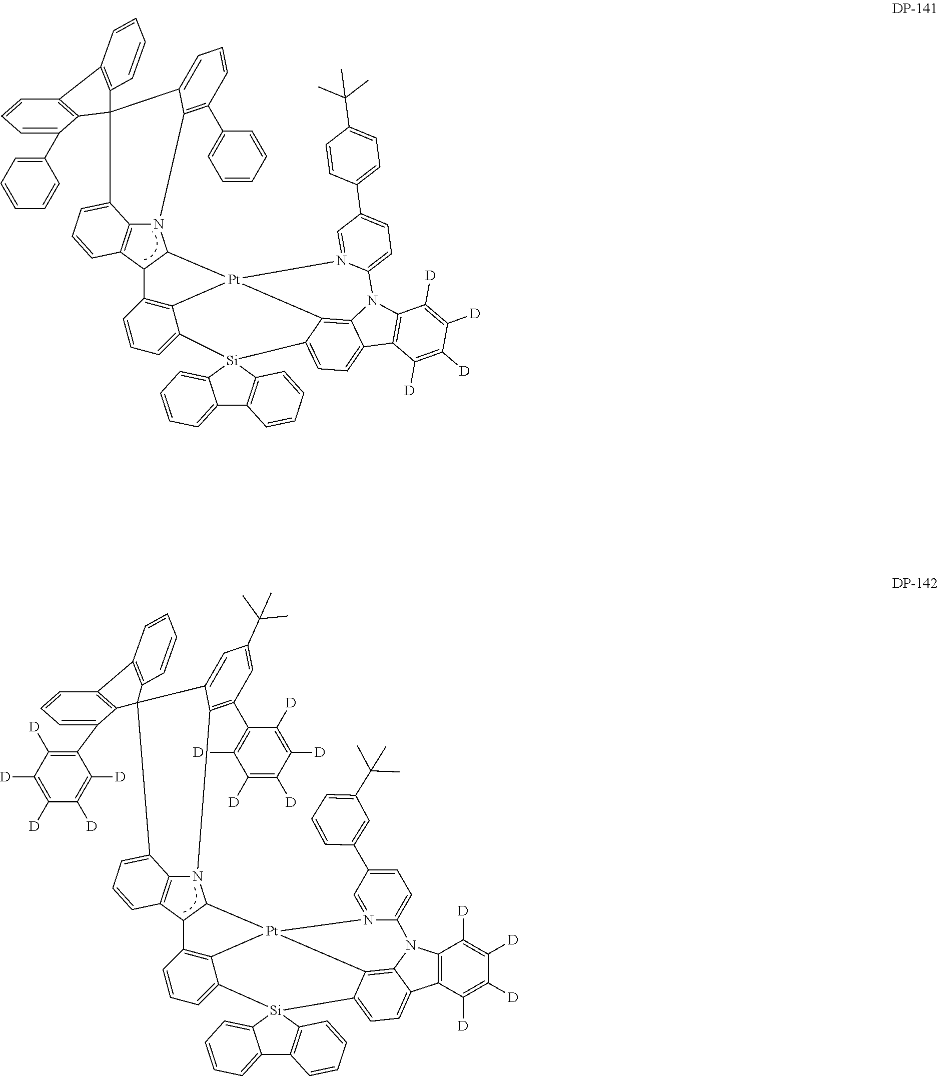

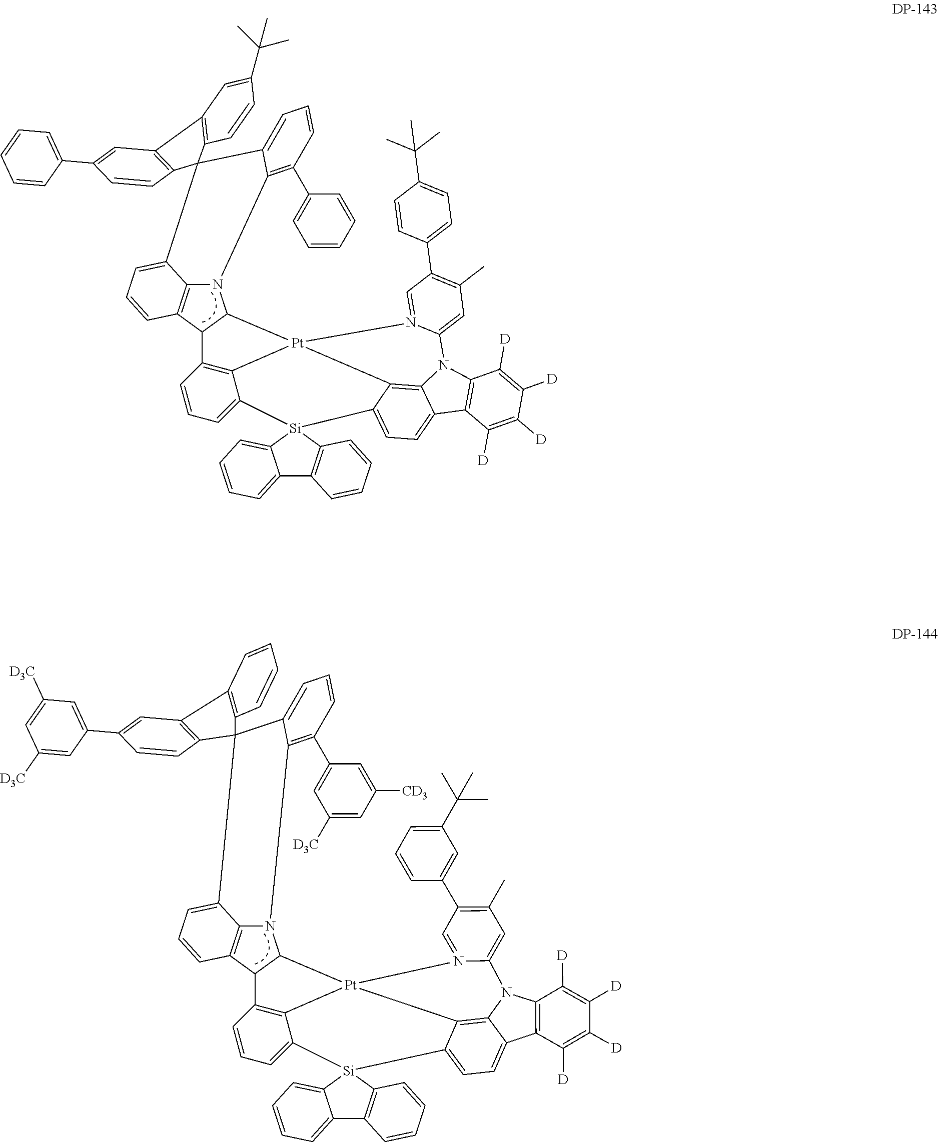

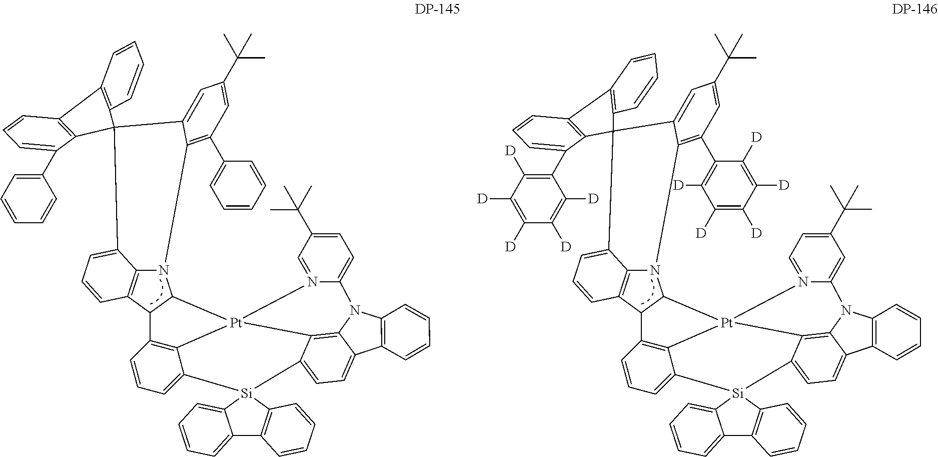

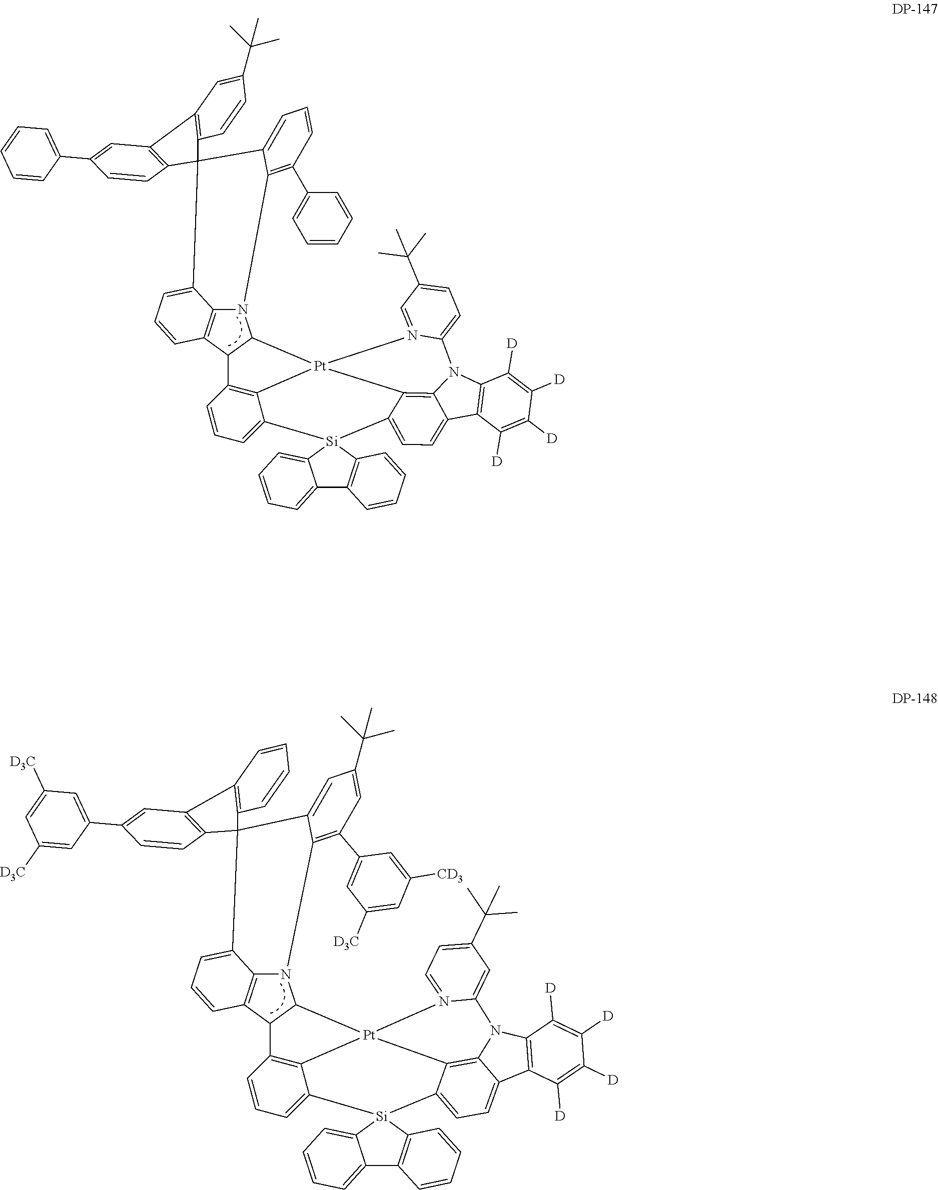

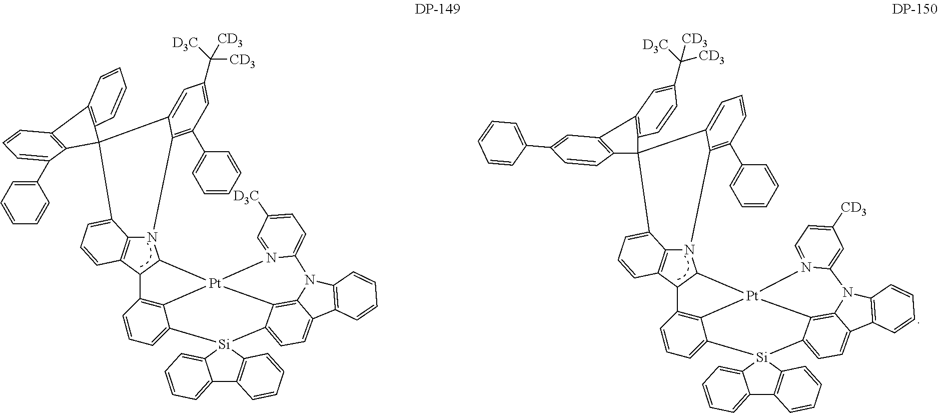

As described above, the organometallic compound may include, e.g., a silafluorene moiety as a bridge structure. In the organometallic compound, bulkiness and complexity of an aryl group connected to CG₁ (e.g., a benzimidazole group) may be increased, and twisting and rotation effects may be increased around the central metal atom (e.g., a Pt atom).

Thus, aggregation between molecules of the organometallic compound may be prevented, and inherent luminescence properties and energy transfer effects of the compound may be implemented with high reliability. Therefore, SOC (spin-orbit coupling) properties and a metal-to-ligand charge transfer (MLCT) ratio may be increased.

In embodiments, the organometallic compound may be included as a phosphorescent dopant or a thermally activated delayed fluorescence (TADF) dopant.

The organometallic compound may be used to increase a depth of a HOMO energy level of the dopant, and thus an energy gap (HOMO/LUMO) between a host and the dopant may be reduced. Accordingly, exciton generation efficiency may be enhanced, and driving properties of the light-emitting device may also be improved through enhancement of a short-wavelength effect.

In embodiments, a HOMO energy level of the organometallic compound may be in a range of about −5.35 eV to about −5.15 eV. For example, a HOMO energy level of the organometallic compound may be in a range of about −5.30 eV to about −5.20 eV. For example, a HOMO energy level of the organometallic compound may be in a range of about −5.28 eV to about −5.21 eV.

In embodiments, a LUMO energy level of the organometallic compound may be in a range of about −1.60 eV to about −1.40 eV. For example, a LUMO energy level of the organometallic compound may be in a range of about −1.55 eV to about −1.45 eV.

In embodiments, the organometallic compound may be used as a blue light-emitting dopant.

In embodiments, the blue light may have a maximum emission wavelength in a range of about 430 nm to about 475 nm. For example, the blue light may have a maximum emission wavelength in a range of about 440 nm to about 475 nm. For example, the blue light may have a maximum emission wavelength in a range of about 440 nm to about 460 nm. For example, the blue light may have a maximum emission wavelength in a range of about 440 nm to about 465 nm. For example, the blue light may have a maximum emission wavelength in a range of about 440 nm to about 460 nm. For example, the blue light may have a maximum emission wavelength in a range of about 440 nm to about 455 nm. For example, the blue light may have a maximum emission wavelength in a range of about 445 nm to about 455 nm.

In embodiments, a full-width at half maximum (FWHM) of blue light emission may be equal to or less than about 40 nm. For example, the FWHM of blue light emission may be in a range of about 5 nm to about 40 nm. For example, the FWHM of blue light emission may be in a range of about 10 nm to about 40 nm. For example, the FWHM of blue light emission may be in a range of about 15 nm to about 40 nm. For example, the FWHM of blue light emission may be in a range of about 20 nm to about 40 nm. For example, the FWHM of blue light emission may be in a range of about 5 nm to about 35 nm. For example, the FWHM of blue light emission may be in a range of about 10 nm to about 35 nm. For example, the FWHM of blue light emission may be in a range of about 15 nm to about 35 nm. For example, the FWHM of blue light emission may be in a range of about 20 nm to about 35 nm. For example, the FWHM of blue light emission may be in a range of about 5 nm to about 30 nm. For example, the FWHM of blue light emission may be in a range of about 10 nm to about 30 nm. For example, the FWHM of blue light emission may be in a range of about 15 nm to about 30 nm. For example, the FWHM of blue light emission may be in a range of about 20 nm to about 30 nm. For example, the FWHM of blue light emission may be in a range of about 5 nm to about 25 nm. For example, the FWHM of blue light emission may be in a range of about 10 nm to about 25 nm. For example, the FWHM of blue light emission may be in a range of about 15 nm to about 25 nm. For example, the FWHM of blue light emission may be in a range of about 20 nm to about 25 nm.

In embodiments, an MLCT ratio (%) of the organometallic compound evaluated by a DFT method may be equal to or greater than about 13%. For example, the MLCT ratio (%) of the organometallic compound may be in a range of about 13% to about 20%. For example, the MLCT ratio (%) of the organometallic compound may be in a range of about 13% to about 18%. For example, the MLCT ratio (%) of the organometallic compound may be in a range of about 13.5% to about 16%.

### <Light-Emitting Device>

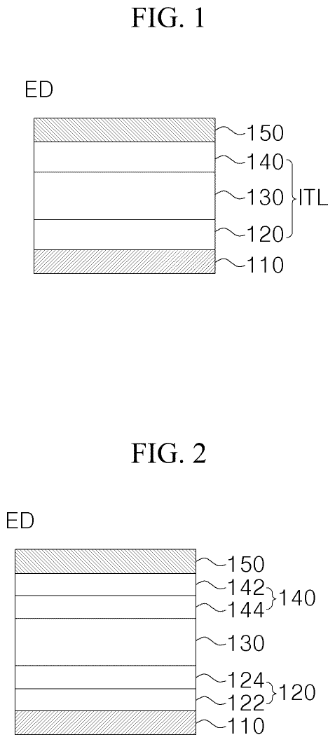

FIGS. 1 to 5 are each a schematic cross-sectional view of a light-emitting device according to an embodiment.

Referring to FIG. 1, a light-emitting device ED may include a first electrode 110, a second electrode 150, and an intermediate layer ITL disposed between the first electrode 110 and the second electrode 150. The intermediate layer ITL may include an emission layer 130. The intermediate layer ITL may further include a hole transfer region 120 and an electron transfer region 140.

The first electrode 110 may be an anode or a cathode. In embodiments, the first electrode 110 may be an anode, and may serve as a pixel electrode. In case that the first electrode 110 is an anode, the first electrode 110 may include a conductive material with a high work function that promotes hole injection.

In an embodiment, the first electrode 110 may be a transmissive electrode, in which first electrode 110 may include a transparent conductive oxide such as indium tin oxide (ITO), indium zinc oxide (IZO), zinc oxide (ZnO), indium tin oxide (ITZO), etc.

In an embodiment, the first electrode 110 may be a translucent electrode or a reflective electrode, in which the first electrode 110 may include at least one of Ag, Mg, Cu, Al, Pt, Pd, Au, Ni, Nd, Ir, Cr, Li, Ca, LiF, Mo, Ti, W, In, Sn, Zn, and an alloy thereof. For example, the first electrode 110 may include Li, Ca, LiF/Ca (a stacked structure of LiF and Ca), LiF/Al (a stacked structure of LiF and Al), a mixture of Ag and Mg, etc.

The first electrode 110 may have a single-layered structure or a multi-layered structure. For example, the first electrode 110 may have a triple-layered structure of ITO/Ag/ITO.

A thickness of the first electrode 110 may be in a range of about 700 Å to about 10,000 Å. For example, the thickness of the first electrode 110 may be in a range of about 1,000 Å to about 3,000 Å.

The second electrode 150 may be a cathode or an anode. In embodiments, the second electrode 150 may serve as an electron injection electrode or as a cathode. The second electrode 150 may include a metal, an alloy, an electrically conductive compound, etc., having a low work function.

For example, the second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, etc. The second electrode 150 may include one of the aforementioned materials, or a combination thereof.

The second electrode 150 may be a transmissive electrode, a translucent electrode, or a reflective electrode. The second electrode 150 may have a single-layered structure or a multi-layered structure.

The emission layer 130 may include the organometallic compound as described above. In embodiments, the organometallic compound may be included as a dopant. In an embodiment, the organometallic compound may serve as a phosphorescent dopant or as a thermally activated delayed fluorescence (TADF) dopant.

In an embodiment, the organometallic compound may be included as a blue light-emitting dopant. For example, the organometallic compound may be included as a light-emitting material having central wavelength in a range of about 430 nm to about 490 nm. In an embodiment, the emission layer 130 may include the organometallic compound, the emission layer 130 may emit blue light, and the blue light may have a maximum emission wavelength in a range of about 440 nm to about 460 nm.

The emission layer 130 may further include a host material. For example, the emission layer 130 may further include a host material of the related art, such as a chrysene derivative, a dihydrobenzanthracene derivative, a triphenylene derivative, etc.

In embodiments, the emission layer 130 may include, e.g., a host material represented by Chemical Formula FH. For example, the compound represented by Chemical Formula FH may be used as a fluorescent host material.

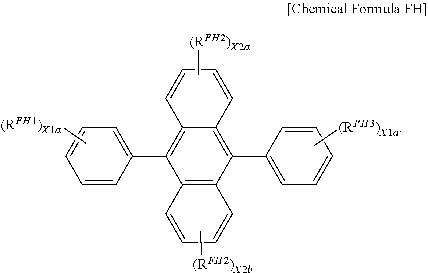

In Chemical Formula FH, R^{FH1} to R^{FH4} may each independently be a hydrogen atom, a deuterium atom, a halogen atom, a substituted or unsubstituted silyl group, a substituted or unsubstituted thio group, a substituted or unsubstituted oxy group, a substituted or unsubstituted C₁-C₁₀ alkyl group, a substituted or unsubstituted C₂-C₁₀ alkenyl group, a substituted or unsubstituted C₆-C₃₀ aryl group, a substituted or unsubstituted C₆-C₃₀ heteroaryl group, or a cyclic group formed through a combination thereof. In an embodiment, in Chemical Formula FH, at least one of R^{FH1} to R^{FH4} may form a condensed ring with a bonded benzene ring.

In Chemical Formula FH, X1a and X1b may each independently be an integer from 0 to 5; and X₂a and X₂b may each independently be an integer from 0 to 4. When x1a, x1b, x2a, and x2b are each 2 or more, two or more of each of R^{FH1} to R^{FH4} may be the same as or different from each other.

Examples of the compound represented by Chemical Formula FH may include Compounds FH-1 to FH-12, but embodiments are not limited thereto:

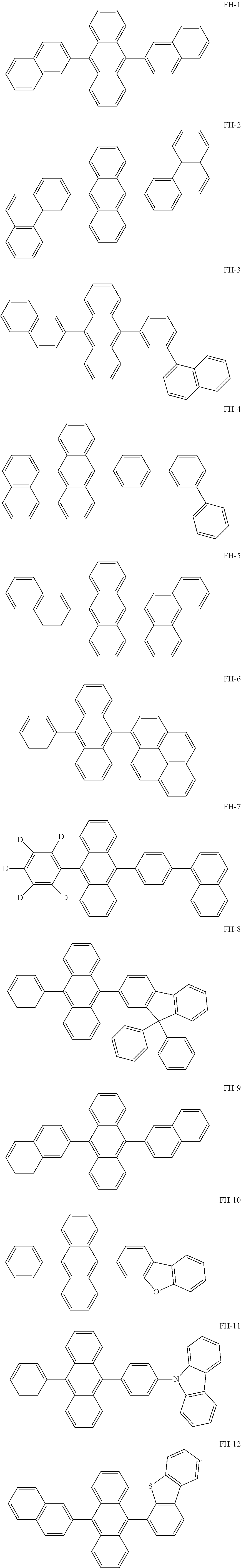

In embodiments, the emission layer 130 may include, e.g., a host material represented by Chemical Formula PH. For example, the compound represented by Chemical Formula PH may be used as a host material in a phosphorescent emission layer or a host material in a phosphorescent device.

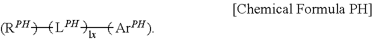

In Chemical Formula PH, RPH may be a substituted or unsubstituted carbazole group; L^{PH} may be a direct linkage, a substituted or unsubstituted C₆-C₃₀ arylene group, or a substituted or unsubstituted C₂-C₃₀ heteroarylene group; and Ar^{PH} may be a substituted or unsubstituted C₆-C₃₀ aryl group, or a substituted or unsubstituted C₂-C₃₀ heteroaryl group.

As described above, the term “C₆-C₃₀ aryl group” may encompass a group in which multiple aryl rings are condensed or bonded through a cyclic group (e.g., an alicyclic hydrocarbon ring). For example, a C₆-C₃₀ aryl group may be a fluorenyl group.

As described above, the term “C₂-C₃₀ heteroaryl group” may encompass a group in which multiple aryl rings are condensed or bonded through a heterocyclic ring. For example, a C₂-C₃₀ heteroaryl group may be a carbazole group, a dibenzofuran group, a dibenzothiophene group, etc. In an embodiment, a C₂-C₃₀ heteroaryl group may be a group in which multiple aryl rings are condensed or bonded to each other through the same or different heterocyclic rings.

In an embodiment, a substituent included in Ar^{PH} may be a silyl group represented by —Si(R^{sa})(R^{sb})(R^{sc}); and R^{sa}, R^{sb}, and R^{sc} may each independently be hydrogen, a halogen, a hydroxyl group, a C₁-C₆₀ alkyl group, a C₁-C₆₀ alkoxy group, a C₆-C₆₀ aryl group, or a C₂-C₃₀ heteroaryl group, wherein at least one of R^{sa}, R^{sb}, and R^{sc} may be a C₆-C₆₀ aryl group or a C₂-C₃₀ heteroaryl group. For example, R^{sa}, R^{sb}, and R^{sc} may each independently be a C₆-C₆₀ aryl group or a C₂-C₃₀ heteroaryl group.

In Chemical Formula PH, lx may be an integer from 0 to 10. When lx is 2 or more, two or more of L^{PH} may be the same as or different from each other.

Examples of the compound represented by Chemical Formula PH may include Compounds PH-1 to PH-12, but embodiments are not limited thereto:

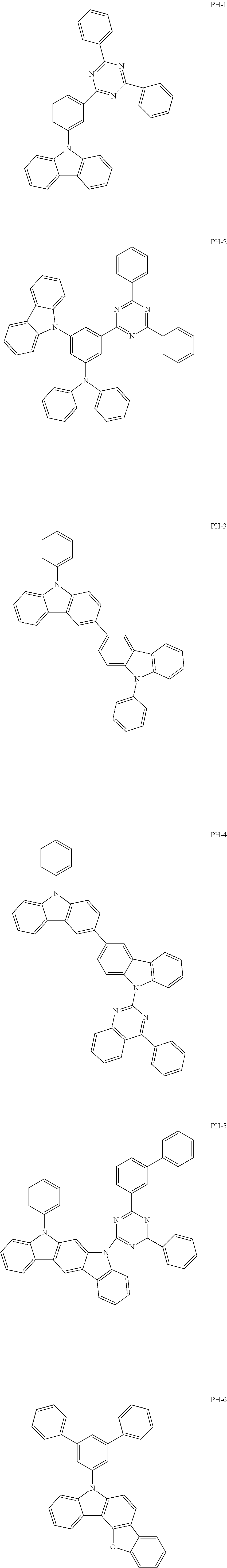 [SMILES: c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1ccc(-n2c3ccccc3c3cc(-c4ccc5c(c4)c4ccccc4n5-c4ccccc4)ccc32)cc1 ; c1ccc(-c2nc(-n3c4ccccc4c4cc(-c5ccc6c(c5)c5ccccc5n6-c5ccccc5)ccc43)nc3ccccc23)cc1 ; c1ccc(-c2cccc(-c3nc(-c4ccccc4)nc(-n4c5ccccc5c5cc6c7ccccc7n(-c7ccccc7)c6cc54)n3)c2)cc1 ; c1ccc(-c2cc(-c3ccccc3)cc(-n3c4ccccc4c4c5oc6ccccc6c5ccc43)c2)cc1]

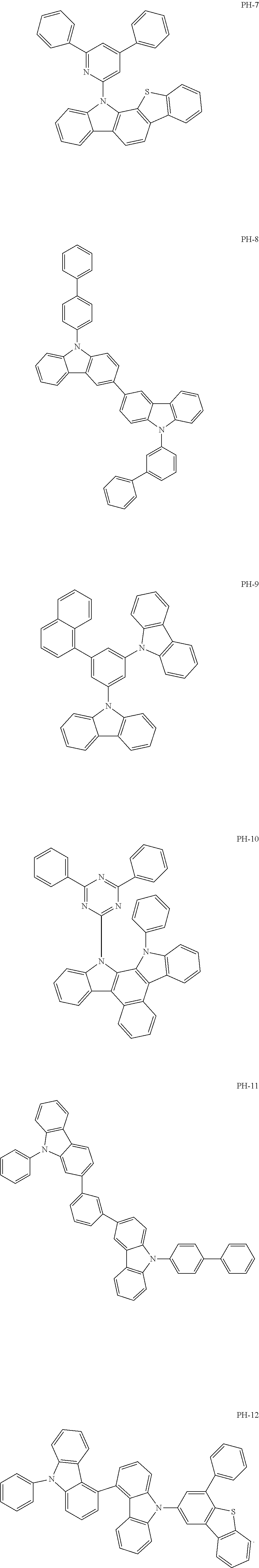 [SMILES: c1ccc(-c2cc(-c3ccccc3)nc(-n3c4ccccc4c4ccc5c6ccccc6sc5c43)c2)cc1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1 ; c1ccc(-c2nc(-c3ccccc3)nc(-n3c4ccccc4c4c5ccccc5c5c6ccccc6n(-c6ccccc6)c5c43)n2)cc1 ; c1ccc(-c2ccc(-n3c4ccccc4c4cc(-c5cccc(-c6ccc7c8ccccc8n(-c8ccccc8)c7c6)c5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

The emission layer 130 may include, e.g., BCPDS (bis(4-(9H-carbazol-9-yl) phenyl) diphenylsilane), POPCPA ((4-(1-(4-(diphenylamino) phenyl) cyclohexyl) phenyl) diphenyl-phosphine oxide), DPEPO (bis[2-(diphenylphosphino)phenyl]ether oxide), mCBP (3,3′-di(9H-carbazol-9-yl)-1,1′-biphenyl), CBP (4,4′-bis(N-carbazolyl)-1,1′-biphenyl), mCP (1,3-bis(carbazol-9-yl)benzene), PPF (2,8-bis(diphenylphosphoryl) dibenzo[b,d]furan), TCTA (4,4′,4″-tris(carbazol-9-yl)-triphenylamine), TPBi (1,3,5-tris(1-phenyl-1H-benzo[d]imidazole-2-yl)benzene), Alq3 (tris(8-hydroxyquinolino) aluminum), ADN (9,10-di(naphthalene-2-yl)anthracene), TBADN (2-tert-butyl-9,10-di(naphth-2-yl)anthracene), DSA (distyrylarylene), CDBP (4,4′-bis(9-carbazolyl)-2,2′-dimethyl-biphenyl), MADN (2-methyl-9,10-bis(naphthalen-2-yl)anthracene), CP1 (hexaphenyl cyclotriphosphazene), UGH2 (1,4-bis(triphenylsilyl)benzene), DPSiO3 (hexaphenylcyclotrisiloxane), DPSiO4 (octaphenylcyclotetrasiloxane), etc., as a host material.

In an embodiment, in the emission layer 130, the host may include one of the materials as described above, or any combination thereof.

The emission layer 130 may further include a dopant.

In embodiments, the emission layer 130 may include a dopant represented by Chemical Formula FD. For example, the compound represented by Chemical Formula FD may be used as a fluorescent dopant.

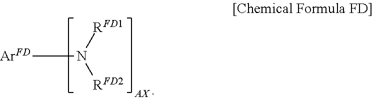

In Chemical Formula FD, Ar^{FD}, R^{FD1}, and R^{FD2} may each independently be a substituted or unsubstituted C₃-C₆₀ carbocyclic group, or a substituted or unsubstituted C₁-C₆₀ heterocyclic group. In Chemical Formula FD, Ax may be an integer from 1 to 6.

In embodiments, Ar^{FD} may include a condensed ring structure in which three or more aryl rings or benzene rings are condensed together (e.g., an anthracene group, a chrysene group, a pyrene group, etc.).

Examples of the compound represented by Chemical Formula FD may include Compounds FD-1 to FD-12, but embodiments are not limited thereto:

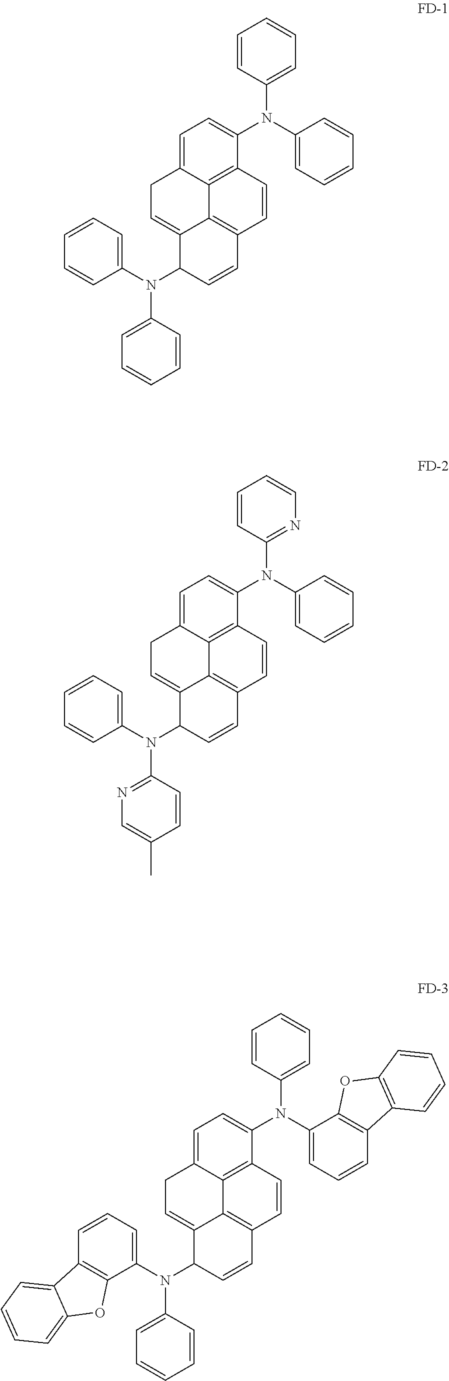 [SMILES: C1=CC(N(c2ccccc2)c2ccccc2)C2=CCc3ccc(N(c4ccccc4)c4ccccc4)c4ccc1c2c34 ; Cc1ccc(N(c2ccccc2)C2C=Cc3ccc4c(N(c5ccccc5)c5ccccn5)ccc5c4c3C2=CC5)nc1 ; C1=CC(N(c2ccccc2)c2cccc3c2oc2ccccc23)C2=CCc3ccc(N(c4ccccc4)c4cccc5c4oc4ccccc45)c4ccc1c2c34]

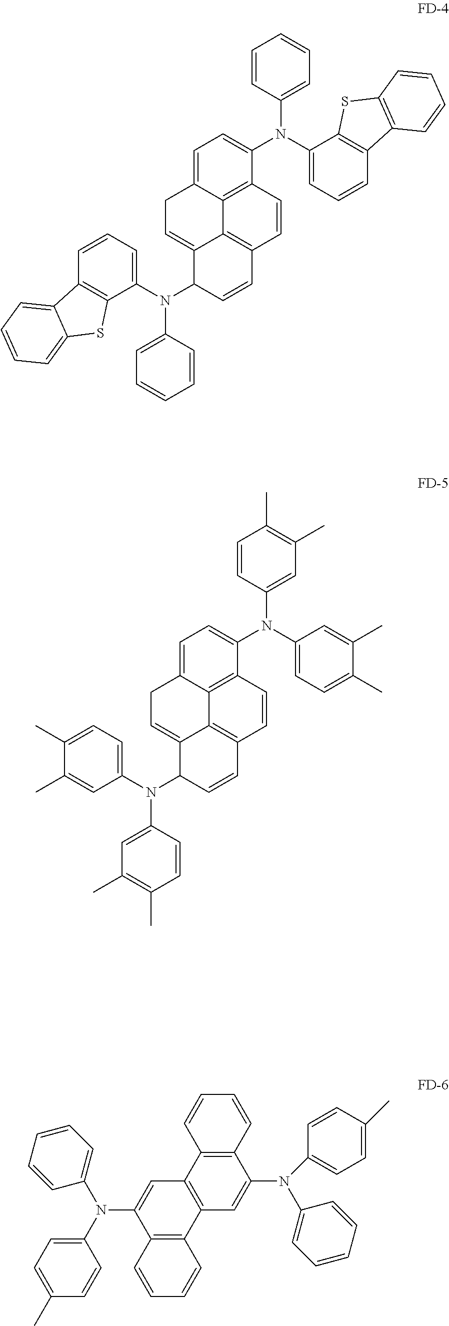

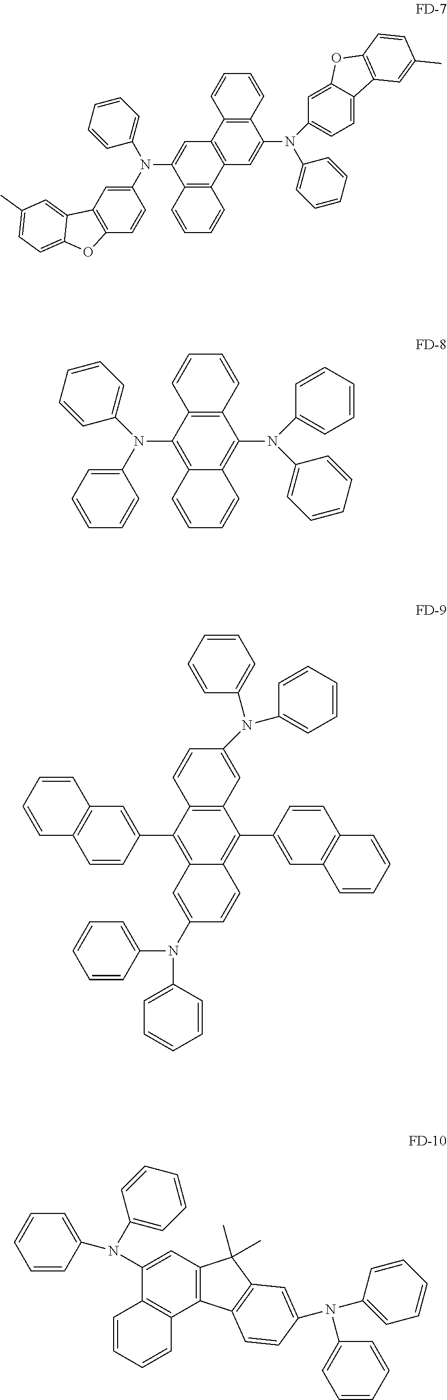

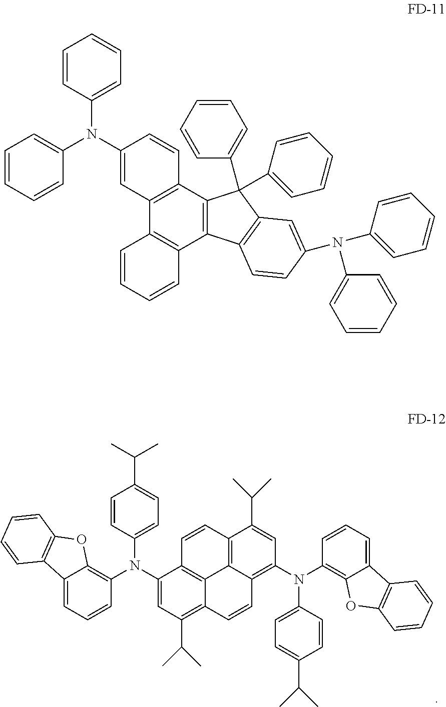 [SMILES: c1ccc(N(c2ccccc2)c2ccc3c(c2)C(c2ccccc2)(c2ccccc2)c2c-3c3ccccc3c3cc(N(c4ccccc4)c4ccccc4)ccc23)cc1 ; CC(C)c1ccc(N(c2cc(C(C)C)c3ccc4c(N(c5ccc(C(C)C)cc5)c5cccc6c5oc5ccccc56)cc(C(C)C)c5ccc2c3c54)c2cccc3c2oc2ccccc23)cc1]

In embodiments, the emission layer 130 may include a phosphorescent dopant. The phosphorescent dopant may include an organometallic compound that includes a central metal and at least one ligand bonded to the central metal via a coordination bond. The central metal may include, e.g., a transition metal, and the ligand may include, e.g., a monodentate ligand, a bidentate ligand, a tridentate ligand, a tetradentate ligand, a pentadentate ligand, a hexadentate ligand, or a combination thereof.

The phosphorescent dopant may include, e.g., a compound represented by Chemical Formula PD.

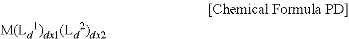

In Chemical Formula PD, M may be a transition metal atom, e.g., iridium (Ir), platinum (Pt), palladium (Pd), osmium (Os), titanium (Ti), gold (Au), hafnium (Hf), europium (Eu), terbium (Tb), rhodium (Rh), rhenium (Re), ruthenium (Ru), copper (Cu), or thulium (Tm).

In Chemical Formula PD, L_{d}^{a} may be a ligand represented by Chemical Formula LD1:

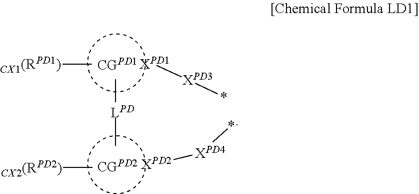

In Chemical Formula LD1, X^{PD1} and X^{PD2} may each independently be C or N.

In an embodiment, one of X^{PD1} and X^{PD2} may be C and the other may be N. In another embodiment, X^{PD1} and X^{PD2} may each be N.

In Chemical Formula LD1, CG^{PD1} and CG^{PD2} may each independently be a substituted or unsubstituted C₃-C₆₀ carbocyclic group, or a substituted or unsubstituted C₁-C⁶⁰ heterocyclic group. For example, CG^{PD1} and CG^{PD2} may each be independently a pyrrole group, a pyrazole group, an imidazole group, a triazole group, an oxazole group, an isoxazole group, a thiazole group, an isothiazole group, an oxadiazole group or a thiadiazole group, a benzene group, a pyridine group, a pyrimidine group, a naphthalene group, a dibenzofuran group, a dibenzothiophene group, a carbazole group, a fluorene group, a dibenzosilole group, a naphthobenzofuran group, a naphthobenzothiophene group, a benzocarbazole group, a benzofluorene group, a naphthobenzosilole group, a dinaphthofuran group, a dinaphthothiophene group, a dibenzocarbazole group, a dibenzofluorene group, a dinaphthosilole group, an azadibenzofuran group, an azadibenzothiophene group, an azacarbazole group, an azafluorene group, an azadibenzosilole group, an azanaphthobenzofuran group, an azanaphthobenzothiophene group, an azabenzocarbazole group, an azabenzofluorene group, an azanaphthobenzosilole group, an azadinapthofuran group, an azadinapthothiophene group, an azadibenzocarbazole group, an azadibenzofluorene group, or an azadinapthosilole group.

In Chemical Formula LD1, L^{PD} may be a single bond, a substituted or unsubstituted methylene group, a substituted or unsubstituted ethylene group, *—O—*′, *—S—*′, *—C(═O)—*′, *—N(R^{PD3})—*, *—C(R^{PD4})═*′, or *═C(R^{PD5})—*,

In Chemical Formula LD1, X^{PD3} and X^{PD4} may each independently be a chemical bond, O, S, N(R^{PD6}), B(R^{PD7}), P(R^{PD8}), C(R^{PD8})(R^{PD9}), or Si(R^{PD10})(R^{PD11}). The chemical bond may be, e.g., a covalent bond or a coordination bond.

In Chemical Formula LD1, R^{PD1} and R^{PD2} may each independently be hydrogen, deuterium, —F, —Cl, —Br, —I, —OH, —CN, —NO₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, a substituted or unsubstituted C₈-C₆₀ condensed polycyclic group, a substituted or unsubstituted silyl group, a substituted or unsubstituted amine group, a substituted or unsubstituted aniline group, —B(R^{PD12})(R^{PD13}), —C(═O)(R^{PD14}), —S(═O)₂(R^{PD15}), or —P(═O)(R^{PD16})(R^{PD17}). The silyl group may be represented by —Si(R^{sa})(R^{sb})(R^{sc}), as explained above.

In Chemical Formula LD1, R^{PD3} to R^{PD17} may each independently be hydrogen, deuterium, —F, —Cl, —Br, —I, —OH, —CN, —NO₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, or a substituted or unsubstituted C₈-C₆₀ condensed polycyclic group.

In Chemical Formula LD1, cx1 and cx2 may each independently be an integer from 0 to 10. When at least one of cx1 and cx2 is 2 or more, two or more of R^{PD1} or two or more of R^{PD2} may be the same as or different from each other.

In Chemical Formula LD1, the symbols -* and -*′ each represent a binding site where the ligand represented by Chemical Formula LD1 bonds to M.

In Chemical Formula PD, dx1 may be an integer from 1 to 3. When dx1 is 2 or 3, two or three of L_{d}¹ may be the same as or different from each other. Among two or three of L_{d}¹, CG^{PD1} and/or CG^{PD2} that are adjacent to each other may be connected to each other through a connecting group such as L^{PD1}, L^{PD2}, etc. The connecting group such as L^{PD1}, L^{PD2}, etc., may each independently be the same as defined in connection with L^{PD}.

In Chemical Formula PD, L_{d}² may be an organic ligand. L_{d}² may include, e.g., a halogen group, CO, NO, CS, picolinate, acetate, oxalate, a diketone group, an isonitrile group, isothiocyanato-N, thiosulphato-S, an alkyl phosphine, phenylphosphine, an aryl phosphine, phosphine oxide, phosphite, or a combination thereof.

In Chemical Formula PD, dx2 is an integer of 1 to 4. When dx2 is 2 or more, two or more of L_{d}² may be the same as or different from each other.

Examples of the compound represented by Chemical Formula PD may include Compounds PD1-1 to PD1-12 and Compounds PD2-1 to PD2-9, but embodiments are not limited thereto:

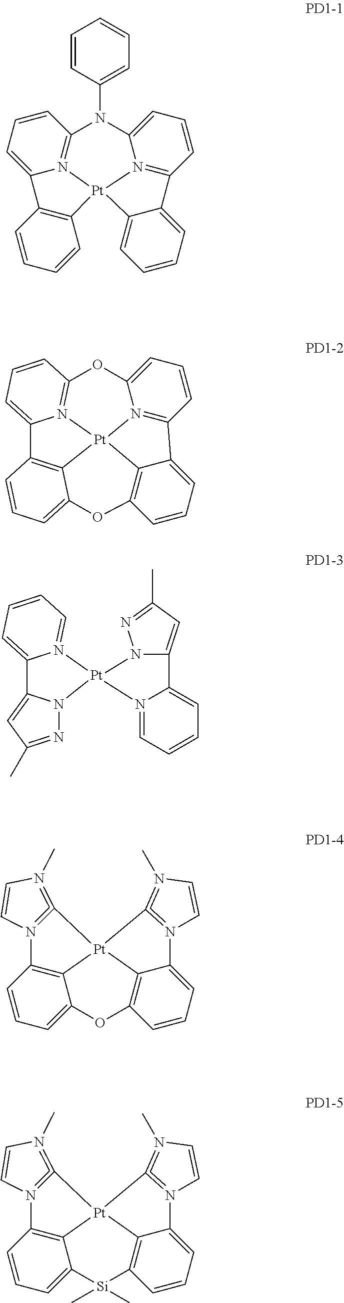

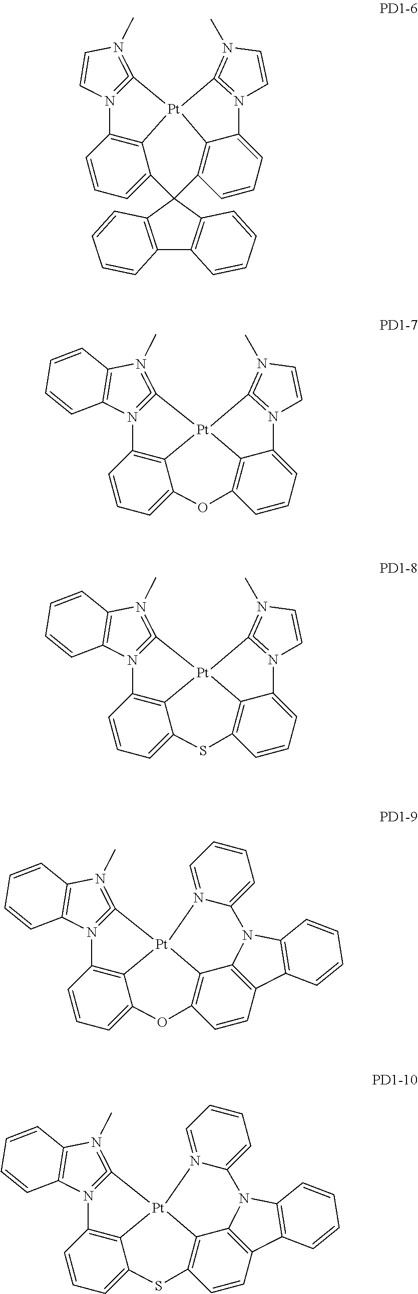

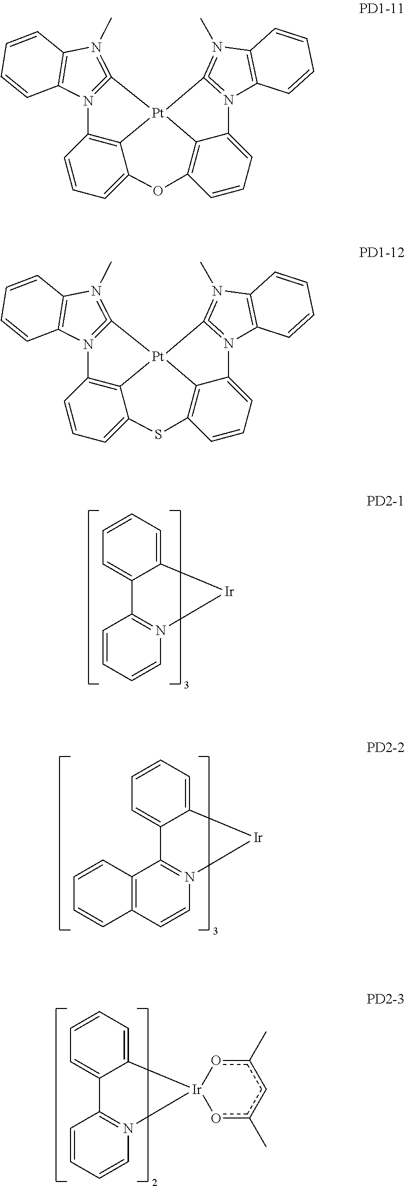

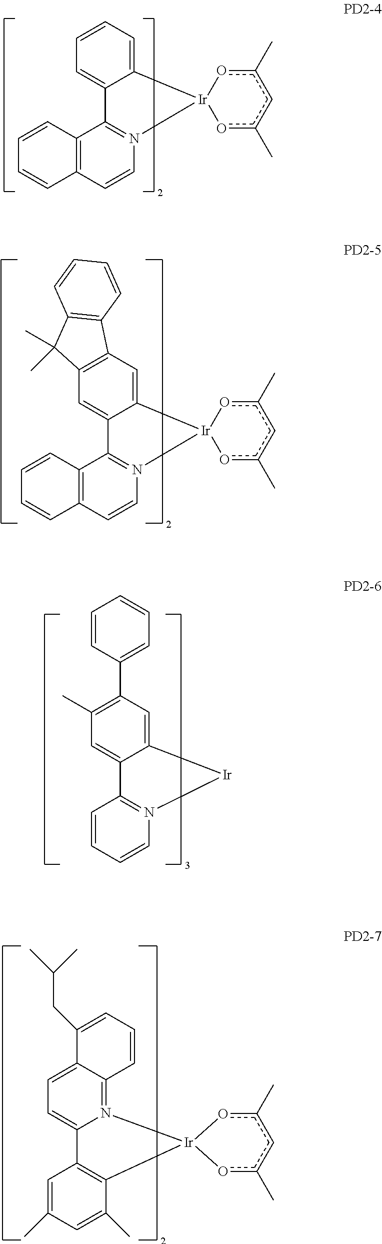

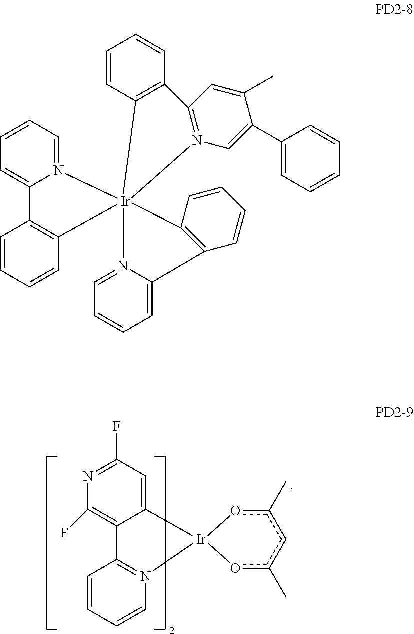

In embodiments, the emission layer 130 may include a styryl derivative (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (NBDAVBi), etc.), 4,4′-bis[2-(4-(N,N-diphenylamino)phenyl)vinyl]biphenyl (DPAVBi), perylene or a derivative thereof (e.g., 2,5,8,11-tetra-t-butylperylene (TBP)), pyrene or a derivative thereof (e.g., 1,1-dipyrene, 1,4-dipyrenylbenzene, 1,4-bis(N,N-diphenylamino)pyrene), etc.), etc., as a fluorescent dopant material.

The emission layer 130 may include a metal complex that includes iridium (Ir), platinum (Pt), osmium (Os), gold (Au), titanium (Ti), zirconium (Zr), hafnium (Hf), europium (Eu), terbium (Tb), or thulium (Tm) as a phosphorescent dopant, in addition to the materials described above. For example, FIrpic (iridium(III) bis(4,6-difluorophenylpyridinato-N,C2′)picolinate), FIr6 (bis(2,4-difluorophenylpyridinato)-tetrakis(1-pyrazolyl)borate iridium(III)), PtOEP (platinum octaethyl porphyrin), etc., may be used as a phosphorescent dopant.

In embodiments, the emission layer 130 may include a boron-containing dopant represented by Chemical Formula BD:

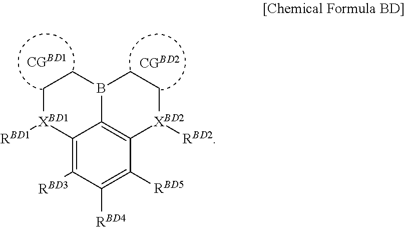

In Chemical Formula BD, X^{BD1} and X^{BD2} may each independently be N, S, O, or C. In an embodiment, X^{BD1} and X^{BD2} may each be N. In Chemical Formula BD, R^{BD1} and R^{BD2} may each independently be hydrogen, deuterium, a substituted or unsubstituted C₁-C₂₀ alkyl group, a substituted or unsubstituted C₆-C₃₀ aryl group, or a substituted or unsubstituted C₂-C₃₀ heteroaryl group. In Chemical Formula BD, R^{BD3}, R^{BD4}, and R^{BD5} may each independently be hydrogen, deuterium, halogen, a cyano group, a substituted or unsubstituted amine group, a substituted or unsubstituted boryl group, a substituted or unsubstituted oxy group, a substituted or unsubstituted thio group, a substituted or unsubstituted C₁-C₂₀ alkyl group, a substituted or unsubstituted C₆-C₃₀ aryl group, or a substituted or unsubstituted C₂-C₃₀ heteroaryl group, or bonded to an adjacent group to form a ring.

In Chemical Formula BD, CG^{BD1} and CG^{BD2} represent a cyclic group, and CG^{BD1} and CG^{BD2} may each independently be a substituted or unsubstituted C₃-C₆₀ carbocyclic group, or a substituted or unsubstituted C₁-C₆₀ heterocyclic group. In embodiments, CG^{BD1} and CG^{BD2} may each independently be a substituted or unsubstituted C₆-C₃₀ aryl group, or a substituted or unsubstituted C₂-C₃₀ heteroaryl group.

In an embodiment, CG^{BD1} and CG^{BD2} may each independently be a substituted or unsubstituted benzene ring. For example, the boron-containing dopant may serve as a thermally activated delayed fluorescence (TADF) dopant.

In an embodiment, one of CG^{BD1} and CG^{BD2} may be a non-condensed aryl group or a non-condensed heteroaryl group, and the other one thereof may be a condensed polycyclic aryl group or a condensed polycyclic heteroaryl group. For example, the boron-containing dopant may serve as a fluorescent dopant.

In an embodiment, the emission layer 130 may include one of the dopant materials as described above, or any combination thereof.

The dopant may include a thermally activated delayed fluorescent material. For example, the thermally activated delayed fluorescent material may include a cyclic group that includes B (boron) and N (nitrogen) a ring-forming atoms, such as a compound represented by Chemical Formula BD.

In embodiments, the emission layer 130 may include two or more host materials. For example, the emission layer 130 may include a hole transporting host and an electron transporting host. For example, the emission layer 130 may include a hole transporting host, an electron transporting host, a photosensitive agent, and a dopant. In embodiments, the hole transporting host and the electron transporting host may form an exciplex, and energy may be transferred from the exciplex to the photosensitive agent and from the photosensitive agent to the dopant, thereby resulting in light emission.

Examples of the hole transporting host may include a compound represented by Chemical Formula HT as described below, but embodiments are not limited thereto. Examples of the electron transporting host may include a compound represented by Chemical Formula ET as described below, but embodiments are not limited thereto.

In embodiments, the emission layer 130 may include quantum dots. A quantum dot may include a Group II-VI compound, a Group III-VI compound, a Group I-III-VI compound, a Group III-V group compound, a Group III-II-V group compound, a Group IV-VI compound, a Group IV element, a Group IV compound, or a combination thereof.

The quantum dot may include a core that includes the compound as described above, and a shell surrounding the core. The shell may include an inorganic oxide or a semiconductor compound. Examples of the semiconductor compound may include CdS, CdSe, CdTe, ZnS, ZnSe, ZnTe, ZnSe, ZnTeS, GaAs, GaP, GaSb, HgS, HgSe, HgTe, InAs, InP, InGaP, InSb, AlAs, AlP, AlSb, etc.

In embodiments, a color of light from a quantum dot may be adjusted according to a particle size of the quantum dot. The quantum dot may be a blue quantum dot, a red quantum dot, or a green quantum dot.

The intermediate layer ITL may include a hole transfer region 120 between the first electrode 110 and the emission layer 130. The hole transfer region 120 may have a structure consisting of a layer, or may have a structure including multiple layers including different materials.

The hole transfer region 120 may include a hole injection layer, a hole transport layer, and/or an electron blocking layer, and may further include an auxiliary emission layer.

In embodiments, as illustrated in FIG. 2, the hole transfer region 120 may include a hole injection layer 122 and a hole transport layer 124, stacked from the first electrode 110.

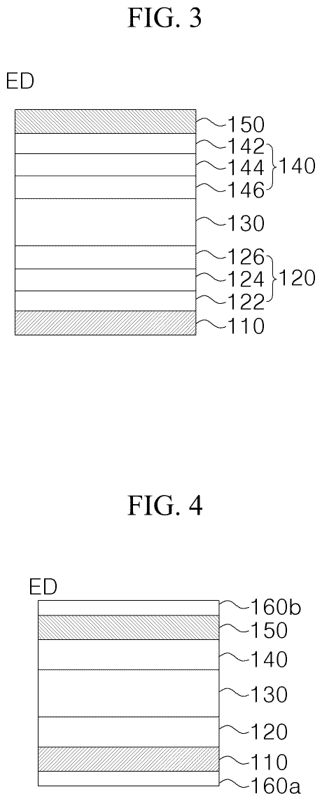

In embodiments, as illustrated in FIG. 3, the hole transfer region 120 may include a hole injection layer 122, a hole transport layer 124, and an electron blocking layer 126, stacked from the first electrode 110. The electron blocking layer 126 may block electrons from the electron transfer region 140 to the hole transfer region 120. Accordingly, the generation of excitons in the emission layer 130 may be increased, and light-emission efficiency may be further increased.

In an embodiment, the hole transfer region 120 may include a compound represented by Chemical Formula HT:

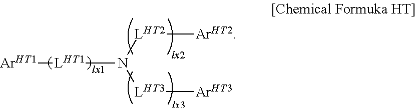

In Chemical Formula HT, L^{HT1}, L^{HT2}, and L^{HT3} may each independently be a direct linkage, a substituted or unsubstituted C₆-C₃₀ arylene group, or a substituted or unsubstituted C₂-C₃₀ heteroarylene group.

In Chemical Formula HT, lx1 to lx3 may each independently be an integer from 0 to 10. When lx1, lx2, or lx3 is 2 or more, two or more of each of L^{HT3} L^{HT1}, or L^{HT2}, respectively, may be directly connected by, e.g., carbon atoms (e.g., sp2 carbons) of each aryl ring, to form a substituted or unsubstituted C₆-C₃₀ arylene group, or a substituted or unsubstituted C₂-C₃₀ heteroarylene group.

In Chemical Formula HT, Ar^{HT1} and Ar^{HT2} may each independently be a substituted or unsubstituted C₆-C₃₀ aryl group, or a substituted or unsubstituted C₂-C₃₀ heteroaryl group. In Chemical Formula HT, Ar^{HT3} may be a substituted or unsubstituted C₆-C₃₀ aryl group.

In an embodiment, the compound represented by Chemical Formula HT may be a monoamine compound. In an embodiment, the compound represented by Chemical Formula HT may be a diamine compound in which at least one of Ar^{HT1} to Ar^{HT3} includes an amine group as a substituent.

In embodiments, the compound represented by Chemical Formula HT may be a carbazole-based compound in which at least one of Ar^{HT1} and Ar^{HT2} includes a substituted or unsubstituted carbazole group. In embodiments, the compound represented by Chemical Formula HT may be a fluorene-based compound in which at least one of Ar^{HT1} and Ar^{HT2} includes a substituted or unsubstituted fluorene group.

In embodiments, two adjacent groups among Ar^{HT1} to Ar^{HT3} may be condensed together to form a ring.

Examples of the compound represented by Chemical Formula HT may include Compounds HT-1 to HT-10, but embodiments are not limited thereto:

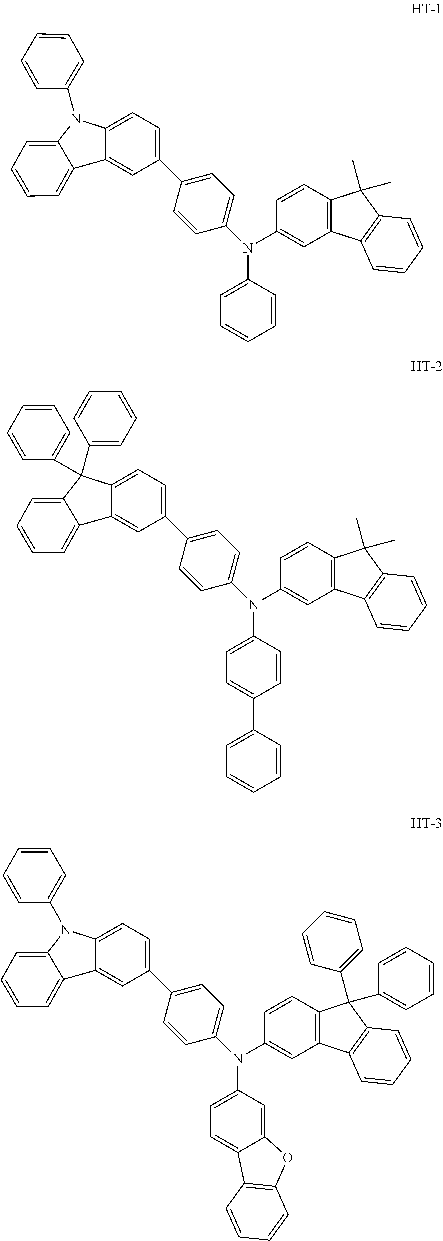 [SMILES: CC1(C)c2ccccc2-c2cc(N(c3ccccc3)c3ccc(-c4ccc5c(c4)c4ccccc4n5-c4ccccc4)cc3)ccc21 ; CC1(C)c2ccccc2-c2cc(N(c3ccc(-c4ccccc4)cc3)c3ccc(-c4ccc5c(c4)-c4ccccc4C5(c4ccccc4)c4ccccc4)cc3)ccc21 ; c1ccc(-n2c3ccccc3c3cc(-c4ccc(N(c5ccc6c(c5)-c5ccccc5C6(c5ccccc5)c5ccccc5)c5ccc6c(c5)oc5ccccc56)cc4)ccc32)cc1]

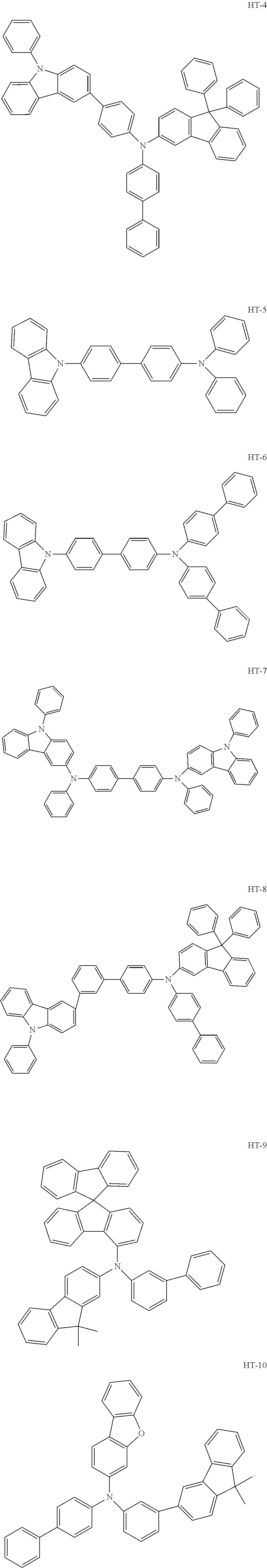

For example, the hole transfer region 120 may include m-MTDATA (4,4′,4″-[tris(3-methylphenyl)phenylamino]triphenylamine), TDATA (4,4′4″-tris(N,N-diphenylamino)triphenylamine), 2-TNATA (4,4′,4″-tris[N(2-naphthyl)-N-phenylamino]-triphenylamine), NPB (N,N′-di(naphthalene-1-yl)-N,N′-diphenyl-benzidine), TPD (N,N′-bis(3-methylphenyl)-N,N′-diphenyl-[1,1′-biphenyl]-4,4′-diamine), Spiro-TPD, Spiro-NPB, DNTPD (N¹,N^{1′}-([1,1′-biphenyl]-4,4′-diyl)bis(N¹-phenyl-N⁴,N⁴-di-m-tolylbenzene-1,4-diamine), TAPC (4,4′-cyclohexylidene bis[N,N-bis(4-methylphenyl)benzenamine]), HMTPD (4,4′-bis[N,N′-(3-tolyl)amino]-3,3′-dimethylbiphenyl), TCTA (4,4′,4″-tris(N-carbazolyl)triphenylamine), PANI/DBSA (Polyaniline/dodecylbenzenesulfonic acid), PEDOT/PSS (poly(3,4-ethylenedioxythiophene)/poly(4-styrenesulfonate)), PANI/CSA(Polyaniline/Camphor sulfonicacid), PANI/PSS (polyaniline/poly(4-styrenesulfonate)), a phthalocyanine compound, a carbazole compound (N-phenylcarbazole, polyvinylcarbazole, etc.), a fluorene compound, etc. The hole transfer region 120 may include one of the hole transfer materials described above, or a combination thereof.

The hole transfer materials described above may be included in at least one of the hole injection layer 122, the hole transport layer 124, and the electron blocking layer 126.

The hole transfer region 120 may further include a charge generating material. The charge generating material may be a dopant material such as a p-dopant, so that conductivity of the hole transfer region 120 may be improved. Examples of dopant materials may include a halogenated metal compound such as LiF, NaCl, CsF, RbCl, RbI, CuI, and KI; a quinone derivative such as TCNQ (tetracyanoquinodimethane), F4-TCNQ (2,3,5,6-tetrafluoro-7,7,8,8-tetracyanoquinodimethane), etc.; a cyano-containing compound such as HATCN (dipyrazino[2,3-f: 2′,3′-h]quinoxaline-2,3,6,7,10,11-hexacarbonitrile), NDP9 (4-[[2,3-bis[cyano-(4-cyano-2,3,5,6-tetrafluorophenyl)methylidene]cyclopropylidene]-cyanomethyl]-2,3,5,6-tetrafluorobenzonitrile), etc.; a tungsten (W) oxide; a molybdenum (Mo) oxide; etc. The hole transfer region 120 may include one of the dopant materials described above, or a combination thereof.

A thickness of the hole transfer region 120 may be in a range of about 100 Å to about 10,000 Å. For example, the thickness of the hole transfer region 120 may be in a range of about 100 Å to about 1,500 Å.

When the hole transfer region 120 includes a hole injection layer 122 or a hole transport layer 124, a thickness of the hole injection layer 122 may be in a range of about 100 Å to about 9,000 Å, and a thickness of the hole transport layer 124 may be in a range of about 50 Å to about 2,000 Å. For example, the thickness of the hole injection layer 122 may be in a range of about 100 Å to about 3,000 Å. For example, the thickness of the hole injection layer 122 may be in a range of about 100 Å to about 1,000 Å. For example, the thickness of the hole transport layer 124 may be in a range of about 100 Å to about 1,500 Å. For example, the thickness of the hole transport layer 124 may be in a range of about 100 Å to about 1,000 Å. For example, the thickness of the hole transport layer 124 may be in a range of about 100 Å to about 600 Å.

Within any of the thickness ranges described above, hole transport properties may be enhanced even at a low voltage operation, and a life-span of the device may be further improved.

Each layer of the hole transfer region 120 may be formed by a process such as a vacuum deposition, a spin coating, an inkjet printing, a laser printing, a casting, a laser thermal transfer, etc.

The intermediate layer ITL may include an electron transfer region 140 between the second electrode 150 and the emission layer 130. The electron transfer region 140 may have a structure consisting of a layer or may have a structure including multiple layers including different materials.

The electron transfer region 140 may include an electron injection layer, an electron transport layer, and/or a hole blocking layer, and may further include an auxiliary emission layer.

In embodiments, as illustrated in FIG. 2, the electron transfer region 140 may include an electron injection layer 142 and an electron transport layer 144, stacked from the second electrode 150 to the emission layer 130.

In embodiments, as illustrated in FIG. 3, the electron transfer region 140 may include an electron injection layer 142, an electron transport layer 144, and a hole blocking layer 146, stacked from the second electrode 150 to the emission layer 130. The hole blocking layer 146 may block or suppress holes from the hole transfer region 120. Accordingly, emission energy and luminescence efficiency in the emission layer 130 may be further improved.

In an embodiment, the electron transfer region 140 may include a compound represented by Chemical Formula ET:

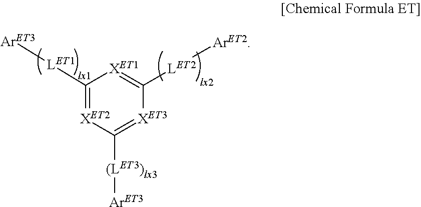

In Chemical Formula ET, at least one of X^{ET1} to X^{ET3} may be N; and the remainder of X^{ET1} to X^{ET3} may each independently be C(R^{ET}). In Chemical Formula ET, R^{ET} may be a hydrogen atom, a deuterium atom, a substituted or unsubstituted C₁-C₂₀ alkyl group, a substituted or unsubstituted C₆-C₆₀ aryl group, or a substituted or unsubstituted C₂-C₆₀ heteroaryl group.

When one of X^{ET1} to X^{ET3} is N, the compound represented by Chemical Formula ET may include a pyridine group. When two of X^{ET1} to X^{ET3} are N, the compound represented by Chemical Formula ET may include a pyrimidine group. When X^{ET1} to X^{ET3} are each N, the compound represented by Chemical Formula ET may include a triazine group.

In Chemical Formula ET, lx1 to lx3 may each independently be an integer from 0 to 10. In Chemical Formula ET, L^{ET1} to L^{ET3} may each independently be a direct linkage, a substituted or unsubstituted C₆-C₃₀ arylene group, or a substituted or unsubstituted C₂-C³⁰ heteroarylene group.

When lx1, lx2, or lx3 is 2 or more, two or more of each of L^{ET1} L^{ET2}, or L^{ET3} respectively, may be directly linked together, e.g., by carbon atoms of each aryl ring (e.g., sp2 carbons), to form a substituted or unsubstituted C₆-C₃₀ arylene group, or a substituted or unsubstituted C₂-C₃₀ heteroarylene group.

In Chemical Formula ET, Ar^{ET1} to Ar^{ET3} may each independently be a hydrogen atom, a deuterium atom, a substituted or unsubstituted C₁-C₂₀ alkyl group, a substituted or unsubstituted C₆-C₃₀ aryl group, or a substituted or unsubstituted C₂-C₃₀ heteroaryl group. For example, Ar^{ET1} to Ar^{ET3} may each independently be a substituted or unsubstituted phenyl group, a substituted or unsubstituted carbazole group, a substituted or unsubstituted fluorene group, or a substituted or unsubstituted silyl group. The silyl group may be represented by —Si(R^{sa})(R^{sb})(R^{sc}), as explained above.

Examples of the compound represented by Chemical formula ET may include Compounds ET-1 to ET-15, but embodiments are not limited thereto:

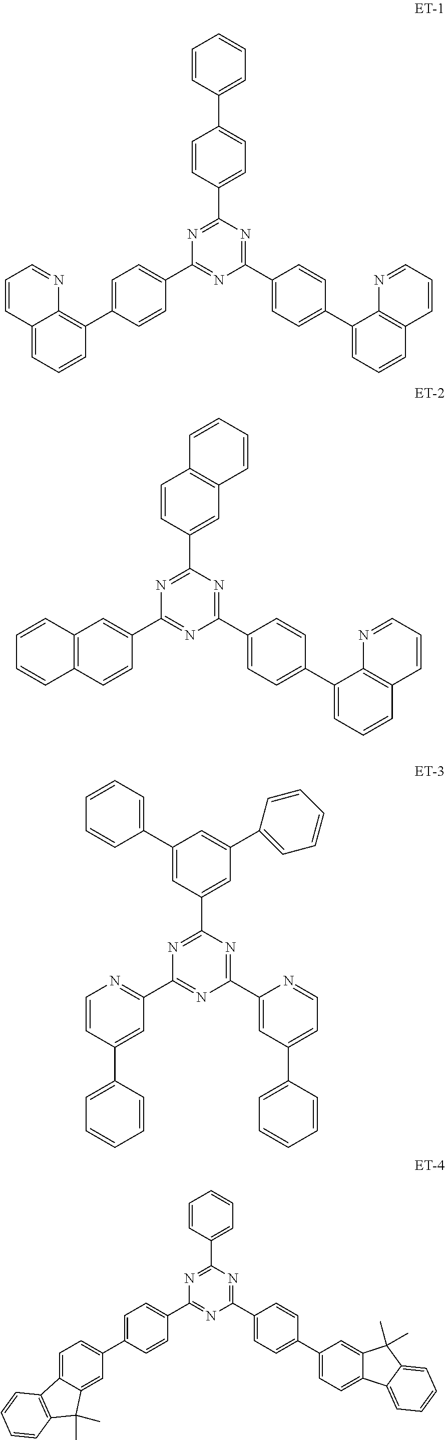 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; c1ccc(-c2cc(-c3ccccc3)cc(-c3nc(-c4cc(-c5ccccc5)ccn4)nc(-c4cc(-c5ccccc5)ccn4)n3)c2)cc1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

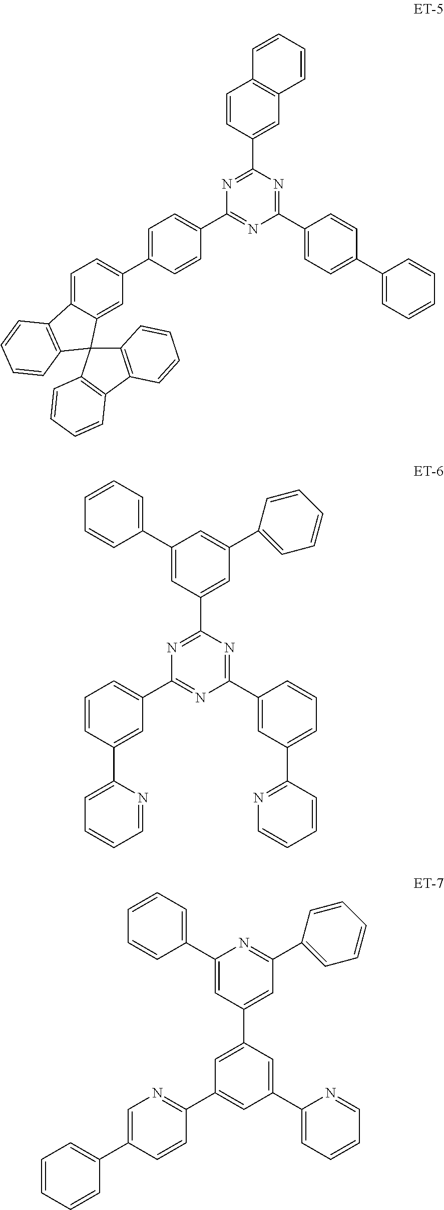 [SMILES: c1ccc(-c2ccc(-c3nc(-c4ccc(-c5ccc6c(c5)C5(c7ccccc7-c7ccccc75)c5ccccc5-6)cc4)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

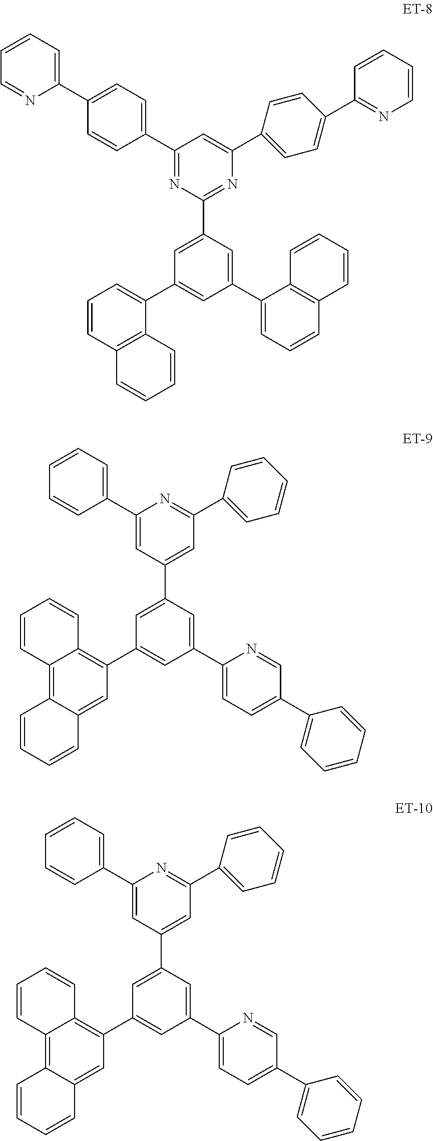 [SMILES: c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc(-c3cc(-c4cc(-c5ccccc5)nc(-c5ccccc5)c4)cc(-c4cc5ccccc5c5ccccc45)c3)nc2)cc1]

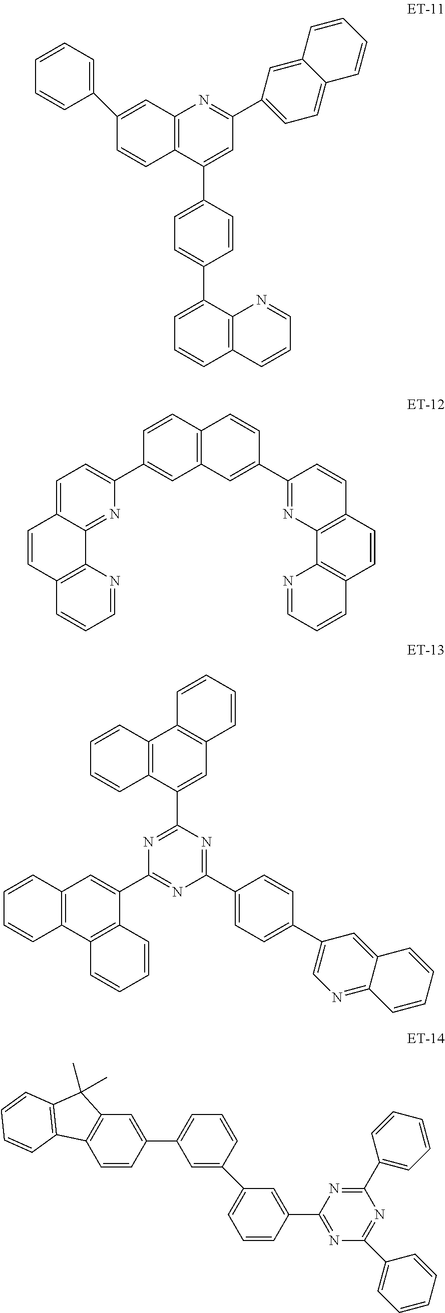 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12 ; c1ccc2ncc(-c3ccc(-c4nc(-c5cc6ccccc6c6ccccc56)nc(-c5cc6ccccc6c6ccccc56)n4)cc3)cc2c1 ; CC1(C)c2ccccc2-c2ccc(-c3cccc(-c4cccc(-c5nc(-c6ccccc6)nc(-c6ccccc6)n5)c4)c3)cc21]

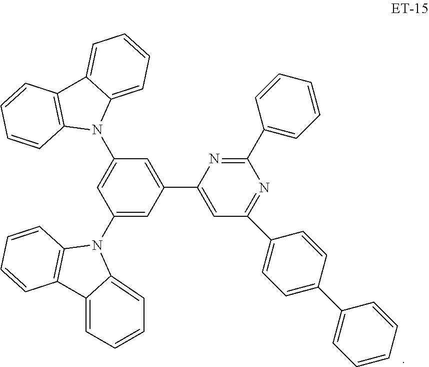 [SMILES: c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

For example, the electron transfer region 140 may include an anthracene compound, Alq3 (tris(8-hydroxyquinolinato) aluminum), 1,3,5-tri[(3-pyridyl)-phen-3-yl]benzene, 2,4,6-tris (3′-(pyridin-3-yl)biphenyl-3-yl)-1,3,5-triazine, 2-(4-(N-phenylbenzoimidazol-1-yl)phenyl)-9,10-dinaphthylanthracene, TPBi (1,3,5-tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1-biphenyl-4-olato)aluminum), Bebg₂ (beryllium bis(benzoquinolin-10-olate)), ADN (9,10-di(naphthalene-2-yl)anthracene), BmPyPhB (1,3-bis[3,5-di(pyridin-3-yl)phenyl]benzene), etc. The electron transfer region 140 may include one of the electron transfer materials described above, or a combination thereof.

The electron transfer materials described above may be included in at least one of the electron injection layer 142, the electron transport layer 144, and the hole blocking layer 146.

The electron transfer region 140 may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or a combination thereof. In an embodiment, the electron injection layer 142 may include such metals, metal compounds, and/or metal complexes.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may include an oxide, a halide (e.g., a fluoride, a chloride, a bromide, an iodide, etc.), a telluride, or a combination thereof of the alkali metal, the alkaline earth metal, and the rare earth metal, respectively.

The alkali metal complex, the alkaline earth metal complex, or the rare earth metal complex may include: an alkali metal ion, an alkaline earth metal ion, or a rare earth metal ion; and a ligand bonded to the metal ion. The ligand may include, e.g., hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenylbenzimidazole, hydroxyphenylbenzothiazole, bipyridine, phenanthroline, cyclopentadiene, or a combination thereof.

A thickness of the electron transfer region 140 may be in a range of about 100 Å to about 1,000 Å. For example, the thickness of the electron transfer region 140 may be in a range of about 150 Å to about 500 Å.

When the electron transfer region 140 includes an electron injection layer 142 or an electron transport layer 144, a thickness of the electron injection layer 142 may be in a range of about 1 Å to about 100 Å, and a thickness of the electron transport layer 144 may be in a range of about 10 Å to about 900 Å. For example, the thickness of the electron injection layer 142 may be in a range of about 1 Å to about 90 Å. For example, the thickness of the electron injection layer 142 may be in a range of about 5 Å to about 50 Å. For example, the thickness of the electron transport layer 144 may be in a range of about 10 Å to about 500 Å. For example, the thickness of the electron transport layer 144 may be in a range of about 100 Å to about 400 Å.

Within any of the thickness ranges described above, electron injection and electron transport properties may be further improved without an excessive increase in driving voltage, and stability of the electron transfer region 140 may be improved.

Each layer of the electron transfer region 140 may be formed by a process such as a vacuum deposition, a spin coating, an inkjet printing, a laser printing, a casting, a laser thermal transfer, etc.

The light-emitting device ED may further include a capping layer. When the light-emitting device ED further includes a capping layer, external light emission efficiency may be improved.

As illustrated in FIG. 4, a second capping layer 160b may be formed on an outer surface of the second electrode 150. In embodiments, a first capping layer 160a may be formed on an outer surface of the first electrode 110.

A refractive index of the first capping layer 160a and/or the second capping layer 160b may each be equal to or greater than about 1.6. For example, the refractive index of the first capping layer 160a and/or the second capping layer 160b may each be equal to or greater than about 1.6, with respect to light in a wavelength range of about 550 nm to about 660 nm. For example, the refractive index of the first capping layer 160a and/or the second capping layer 160b may each be equal to or greater than about 1.8, with respect to light in a wavelength range of about 550 nm to about 660 nm. For example, the refractive index of the first capping layer 160a and/or the second capping layer 160b may each be equal to or greater than about 2.0, with respect to light in a wavelength range of about 550 nm to about 660 nm.

The first capping layer 160a and the second capping layer 160b may each be an organic capping layer that includes an organic material, an inorganic capping layer that includes an inorganic material, or an organic-inorganic composite capping layer that includes organic materials and inorganic materials.

In embodiments, the first capping layer 160a and the second capping layer 160b may each independently include a carbocyclic compound, a heterocyclic compound, an amine group-containing compound, a porphine derivative, a phthalocyanine derivative, a naphthalocyanine derivative, an alkaline metal complex, an alkaline earth metal complex, etc. The first capping layer 160a and the second capping layer 160b may each independently include one of the aforementioned materials, or a combination thereof.

In an embodiment, the first capping layer 160a and/or the second capping layer 160b may each independently include an amine group-containing compound.

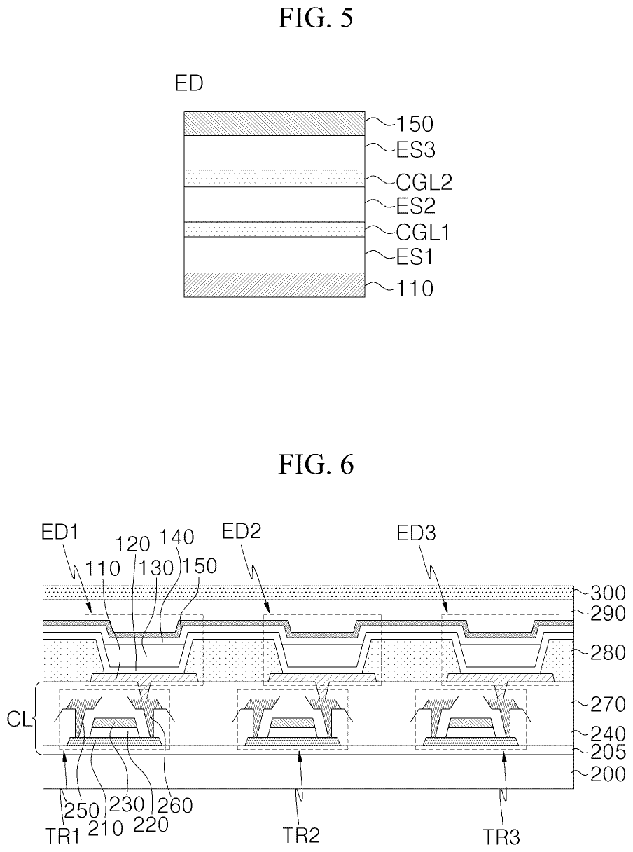

Referring to FIG. 5, the light-emitting device ED may include multiple light-emitting structures (e.g., the light-emitting structures ES1, ES2 and ES3). The light-emitting structures ES1, ES2, and ES3 may each include a stacked structure of a hole transfer region 120, an emission layer 130, and an electron transfer region 140, as described with reference to FIGS. 1 to 4. In embodiments, the light-emitting device ED of FIG. 5 may be a light-emitting device having a tandem structure.

Charge generation layers CGL1 and CGL2 may each be disposed between adjacent structures among the light-emitting structures ES1, ES2, and ES3. Charge generation layers CGL1 and CGL2 may each independently include a p-type charge generation layer and/or an n-type charge generation layer.

The p-type charge generation layer may include a hole transport host compound, such as NPB. For example, the p-type charge generation layer may include a compound represented by Chemical Formula HT as described above. The p-type charge generation layer may further include a p-dopant, such as TCNQ.

The n-type charge generation layer may include an electron transport host compound. For example, the n-type charge generation layer may include a compound represented by Chemical Formula ET as described above. In an embodiment, the n-type charge generation layer may include a phenanthroline-based compound.

The charge generation layers CGL1 and CGL2 may include a first charge generation layer CGL1 disposed between the first light-emitting structure ES1 and the second light-emitting structure ES2, and a second charge generation layer CGL2 disposed between the second light-emitting structure ES2 and the third-light emitting structure ES3.

In embodiments, the first light-emitting structure ES1, the first charge generation layer CGL1, the second light-emitting structure ES2, the second charge generation layer CGL2, the third light-emitting structure ES3, and the second electrode 150 may be stacked in this stated order on a top surface of the first electrode 110.

### <Display Device/Electronic Device>

The light-emitting device ED as described above may be included in an electronic device, and may be provided as a light-emitting portion or a light-emitting unit of the electronic device.

Examples of an electronic device may include a display device, a billboard, a signboard, a light source, a lighting device, a personal computer such as a laptop computer or a desktop computer, a mobile phone, an electronic book, an electronic dictionary, an electronic notebook, various sensors, a diagnostic device, various display units for transportation means (automobile, aircraft, ship, train, etc.).

In embodiments, the light-emitting device ED may be applied to an organic light emitting diode (OLED) display device or a quantum dot (QD)-OLED display device.

FIG. 6 is a schematic cross-sectional view of a display device according to embodiments.

Referring to FIG. 6, the display device may include a circuit layer CL disposed on a base substrate 200, and light-emitting devices ED1, ED2, and ED3 disposed on the circuit layer CL.

The base substrate 200 may serve as a supporting substrate or as a back-plane substrate of a display device. The base substrate 100 may be a glass substrate or a plastic substrate.

In embodiments, the base substrate 200 may include a polymer material having transparent and flexible properties. When the base substrate 200 includes a polymer material, the base substrate 200 may be used in a transparent flexible display device. For example, the base substrate 200 may include a polymer material such as polyimide, polysiloxane, an epoxy resin, an acrylic resin, polyester, etc. In an embodiment, the base substrate 200 may include polyimide.

The circuit layer CL may include transistors TR1, TR2, and TR3. The circuit layer CL may include wiring layers and insulating layers that form a thin film transistor array (TFT-Array).

The circuit layer CL may further include a buffer layer 205 on a top surface of the base substrate 200. The buffer layer 205 may block the penetration of moisture through the base substrate 200, and may also block the diffusion of impurities between the base substrate 200 and the structures formed thereon.

The buffer layer 205 may include, e.g., silicon oxide, silicon nitride, or silicon oxynitride. The buffer layer 205 may include one of the aforementioned materials, or a combination thereof. In embodiments, the buffer layer 205 may have a stacked structure that includes a silicon oxide layer and a silicon nitride layer.

The transistors TR1, TR2, and TR3 may be disposed on the buffer layer 205. A first transistor TR1, a second transistor TR2, and a third transistor TR3 may be electrically connected to a first light-emitting device ED1, a second light-emitting device ED2, and a third light-emitting device ED3, respectively.

The transistors TR1, TR2 and TR3 may each include an active layer 210, a gate insulation layer 220, and a gate electrode 230.

The active layer 210 may be disposed on the buffer layer 205, and may be patterned for each pixel. The active layer 210 may include a silicon compound such as amorphous silicon or polysilicon. A p-type dopant or an n-type dopant may be doped in a region of the active layer 210, and the active layer 210 may include a source region, a drain region, and a channel region.

The active layer 210 may include an oxide semiconductor, such as indium gallium zinc oxide (IGZO), zinc tin oxide (ZTO), or ITZO.

The gate insulation layer 220 may be formed on the active layer 210, and the gate electrode 230 may be stacked on the gate insulation layer 220. As illustrated in FIG. 6, the gate insulation layer 220 may be patterned so that it partially covers each active layer 210. In another embodiment, the gate insulation layer 220 may extend continuously over multiple pixels or light-emitting regions, so that it may be provided as a common layer for the first, second, and third transistors TR1, TR2, and TR3.

The gate electrode 230 may overlap the channel region of the active layer 210 in a thickness direction.

An insulating interlayer 240 may be formed on the active layer 210 so that it covers the gate electrode 230 and the gate insulation layer 220. Connection electrodes 250 and 260 which contact (for example, electrically contact) the active layer 210 may each be disposed on the insulating interlayer 240.

The connection electrodes 250 and 260 may extend through the insulting interlayer 240, and may contact (for example, electrically contact) the active layer 210. When the gate insulation layer 220 is provided as a common layer for multiple light-emitting regions, the connection electrodes 250 and 260 may also extend through the gate insulation layer 220.

The connection electrodes 250 and 260 may include a source electrode 250 that contacts (for example, electrically contacts) the source region of the active layer 210, and a drain electrode 250 that contacts (for example, electrically contacts) the drain region of the active layer 210.

The gate insulation layer 220 and the insulating interlayer 240 may each independently include silicon oxide, silicon nitride, or silicon oxynitride, and for example, may each have a stacked structure that includes a silicon oxide layer and a silicon nitride layer.

The gate electrode 230 and the connection electrodes 250 and 260 may include a metal such as Ag, Mg, Al, W, Cu, Ni, Cr, Mo, Ti, Pt, Ta, Nd, Sc, an alloy thereof, or a nitride thereof.

A via insulation layer 270 may be formed on the insulating interlayer 240 to cover the connection electrodes 250 and 260.

The via insulation layer 270 may accommodate a via structure wherein the first electrode 110 electrically contacts the drain electrode 260. The via insulation layer 270 may serve as a planarization layer of the circuit layer CL. In embodiments, the via insulation layer 270 may include an organic material such as polyimide, an epoxy resin, an acrylic resin, polyester, etc.

The light-emitting devices ED1, ED2, and ED3 may be disposed on the via insulation layer 270. For example, as described with reference to FIGS. 1 to 4, the light-emitting devices ED1, ED2, and ED3 may include the first electrode 110, the hole transfer region 120, the emission layer 130, the electron transfer region 140, and the second electrode 150, which are stacked in that order from the via insulation layer 270.

The first electrode 110 may electrically contact the transistors TR1, TR2, and TR3 or the connection electrodes 250 and 260 in the circuit layer CL through the via structure. As illustrated in FIG. 6, the first electrode 110 may contact (for example, electrically contact) the drain electrode 260 to serve as a pixel electrode for each light-emitting region or pixel.

A pixel defining layer 280 may be formed on the via insulation layer 270 to define each light-emitting region or pixel. A blue light-emitting region, a red light-emitting region, and a green light-emitting region may be separated and defined by the pixel defining layer 280, and the light-emitting devices ED1, ED2, and ED3 may respectively correspond to a blue light-emitting device, a red light-emitting device, and a green light-emitting device.

The pixel defining layer 280 may partially cover the first electrode 110 of each light-emitting region.

As illustrated in FIG. 6, the hole transfer region 120 and the electron transfer region 140 may each be provided as a common layer that continuously extends over the pixel defining layer 280 and the first electrodes 110. The emission layer 130 may be formed within each light emitting-region or pixel, and may be separated by the pixel defining layer 280.

In another embodiment, the emission layer 130 may also be provided as a common layer that continuously extends over the light emitting-regions or pixels. In yet another embodiment, the hole transfer region 120, the emission layer 130, and the electron transfer region 140 may each be patterned and separately formed for each light-emitting region or pixel.

The second electrode 150 may be provided as a common electrode that continuously extends over the light-emitting regions or the pixels.

An encapsulation layer 290 may be disposed on the pixel defining layer 280 and the light emitting devices ED1, ED2, and ED3 to protect the light-emitting devices ED1, ED2, and ED3 from moisture and/or oxygen. The encapsulation layer 290 may be a thin film encapsulation (TFE) that consists of a single layer or may be a structure that includes multiple layers.

The encapsulation layer 290 may include: an inorganic layer that includes silicon nitride (SiNₓ), silicon oxide (SiOₓ), indium tin oxide, indium zinc oxide, or any combination thereof; an organic layer that includes polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, etc.), an epoxy resin (e.g., an aliphatic glycidyl ether (AGE)) or any combination thereof; or a combination of the inorganic layer and the organic layer.

The display device may further include a functional layer 300 disposed on the encapsulation layer 290. The functional layer 300 may include a sensor layer such as a touch sensor layer, an optical layer such as a polarizing layer, a color conversion layer, a color filter layer, a window film, or any combination thereof.

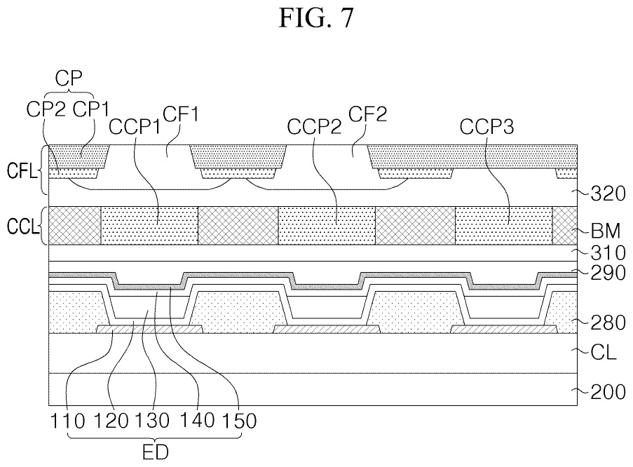

FIG. 7 is a schematic cross-sectional view of a display device according to an embodiment.

FIG. 7 illustrates a display device having a QD-OLED structure according to embodiments. Detailed descriptions regarding elements and structures that are the same as or substantially similar to what has been described above with respect to FIGS. 1 to 6 will not be repeated here.

Referring to FIG. 7, the pixel defining layer 280 and the light-emitting device ED may be disposed on the circuit layer CL, as described above with respect to FIG. 6. In embodiments, each pixel may emit light of a same wavelength region. In an embodiment, each light-emitting device ED may emit blue light.

In an embodiment, each light-emitting region may include a light-emitting device having a tandem structure, as described above with respect to FIG. 5. For example, when each light-emitting device ED has a tandem structure, the intermediate layer ITL of each light-emitting device ED may be provided as a common layer that continuously extends over the light-emitting regions.

A color control layer CCL may be disposed on the encapsulation layer 290, and the color control layer CCL may include color control portions CCP1, CCP2, and CCP3.

The color control portions CCP1, CCP2, and CCP3 may each include a light transformer such as a quantum dot or a phosphor. In each of the color control portions CCP1, CCP2, and CCP3, the light transformer may convert the wavelength of a provided light and emit the resulting light.

The color control portions CCP1, CCP2, and CCP3 may be separated or spaced apart from each other by a bank BM. The bank BM may substantially overlap the pixel defining layer 280, and the color control portions CCP1, CCP2, and CCP3 may substantially overlap each of the emission layers 130.

The color control layer CCL may include a first color control portion CCP1 including a first quantum dot that converts a first color light provided from the light-emitting device ED into a second color light, a second color control portion CCP2 including a second quantum dot that converts the first color light into a third color light, and a third color control portion CCP3 that transmits the first color light.

In embodiments, the first color light, the second color light, and the third color light may respectively be a blue light, a red light, and a green light. The first quantum dot and the second quantum dot may respectively be a red quantum dot and a green quantum dot.

The color control portions CCP1, CCP2, and CCP3 may each further include a scattering material such as inorganic particles. The third color control portion CCP3 may not include quantum dots and may include the scattering material. The scattering material may include TiO₂, ZnO, Al₂O₃, SiO₂, hollow silica, etc. The scattering material may be one of the aforementioned materials or a combination thereof.

The color control portions CCP1, CCP2, and CCP3 may each further include a binder resin that disperses the quantum dot and the scattering material. The binder resin may include an acrylic resin, a urethane resin, a silicone resin, an epoxy resin, etc.

A color filter layer CFL that includes color filters CF1 and CF2 and a light-shielding portion CP may be disposed on the color control layer CCL.

The color filter layer CFL may include a first filter CF1 that transmits the second color light, a second filter CF2 that transmits the third color light, and a third filter that transmits the first color light. For example, the first filter CF1 may be a red filter, the second filter CF2 may be a green filter, and the third filter may be a blue filter.

The color filters CF1 and CF2 may each include a photosensitive binder resin and a colorant including a pigment and/or a dye. The first filter CF1 may include a red pigment or dye, and the second filter CF2 may include a green pigment or dye.

The light-shielding portion CP may be disposed between the color filters. In embodiments, the light-shielding portion may include a first light-shielding portion CP1 and a second light-shielding portion CP2 that includes colorants of different colors.

In embodiments, the first light-shielding portion CP1 may include a blue colorant, and the second light-shielding portion CP2 may include a red colorant or a black colorant. In an embodiment, in the blue light-emitting region, a portion of the first light-shielding portion CP1 may be provided as a blue color filter and may be exposed between the second light-shielding portions CP2, so that an additional color filter (e.g., a third filter) may be omitted.

A first barrier layer 310 may be disposed between the color control layer CCL and the light-emitting device ED (or the encapsulation layer 290). A second barrier layer 320 may be disposed between the color control layer CCL and the color filter layer CFL.

The barrier layers 310 and 320 may each include at least one inorganic layer. For example, the barrier layers 310 and 320 may each independently include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, etc.

In an embodiment, the barrier layers 310 and 320 may each have a multilayered structure that further includes an organic layer.

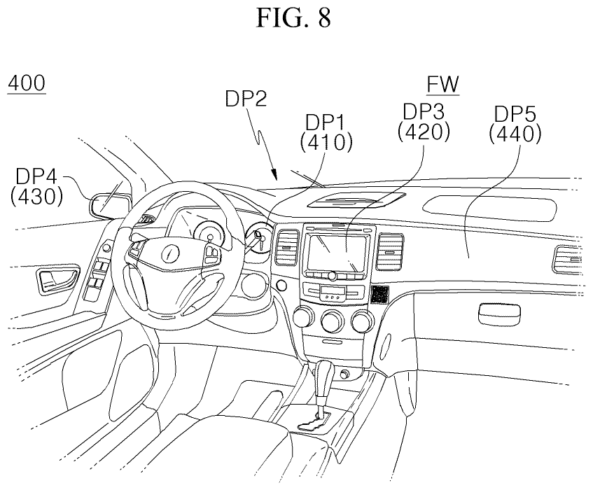

FIG. 8 is a schematic perspective view of an electronic device according to an embodiment.

The electronic device may be installed in, embedded in, attached to, or integrated with a vehicle 400. However, the vehicle 400 is not limited to the embodiment illustrated in FIG. 8. Further examples of the vehicle 400 may include a transportation means such as a three-wheeled or four-wheeled vehicle, a construction machine, a two-wheeled vehicle, a motor vehicle, a bicycle, a train, etc. Other examples of the vehicle 400 may include an electric vehicle, a hybrid vehicle, etc.

Referring to FIG. 8, at least one of first to fifth display devices DP1, DP2, DP3, DP4, and DP5 may be applied to the vehicle 400.

In embodiments, the first display device DP1 may be disposed in a cluster area 410. Driving information such as a driving distance and speed, and various warning lights may be displayed in the cluster area 410.

The second display device DP2 may be disposed on a front window FW of the vehicle 400. For example, the second display device DP2 may be installed as a head-up display (HUD).

The third display device DP3 may be disposed on a center fascia 420 of the vehicle 400. In the center fascia 420, a button or a switch for controlling an image display or a music player, an air conditioner, a heater, etc., may be displayed, and vehicle information may be displayed thereon.

The fourth display device DP4 may be applied to side mirrors 430 of the vehicle 400. A side mirror 430 may be installed at either side of an exterior of the vehicle 400, and the fourth display device DP4 may be applied to at least one of the side mirrors 430 installed at either side.

The fifth display device DP5 may be disposed on a passenger seat dashboard 440. Information (e.g., an image) that is identical to or different from information displayed on the cluster area 410 and/or the center fascia 420 may be displayed at the passenger seat dashboard 440.

Hereinafter, an organometallic compound according to an embodiment will be described in detail with reference to the Examples and the Comparative Examples. The Examples are provided to assist in understanding the disclosure, but they are provided as non-limiting examples, and the scope of the disclosure is not limited thereto. It will be clear to those skilled in the art that various changes and modifications to disclosed examples can be made within the scope of the disclosure.

### Synthesis Example 1: Synthesis of Compound DP-2

Compound DP-2 was synthesized through Synthesis Scheme 1 below.

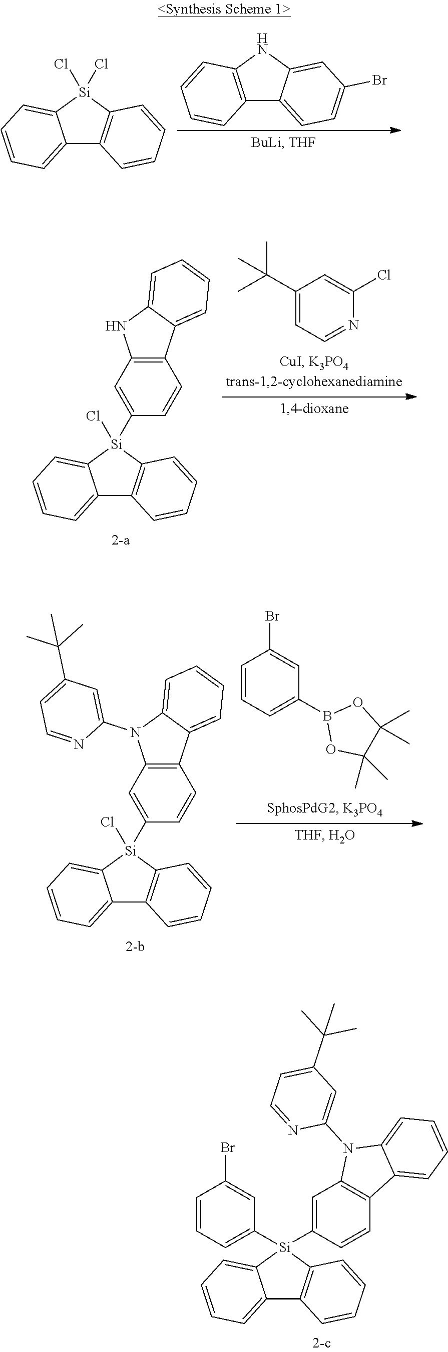

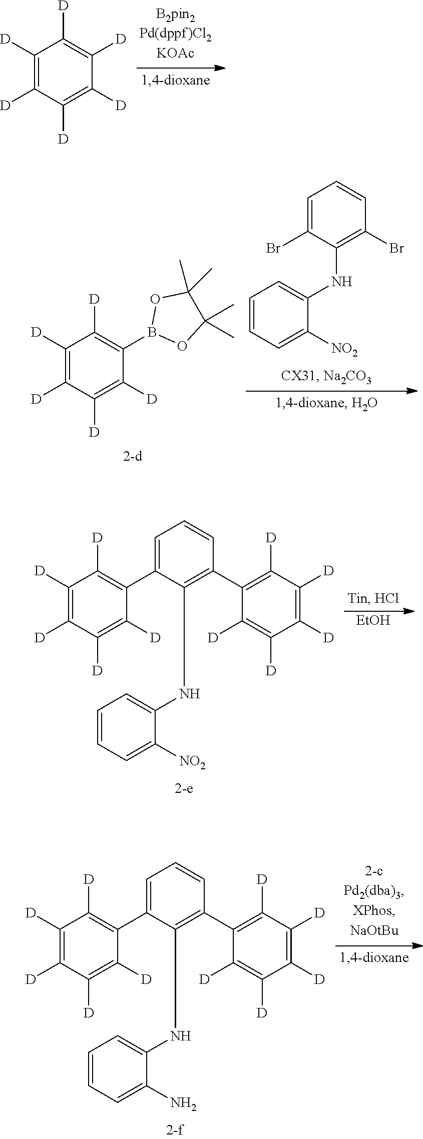

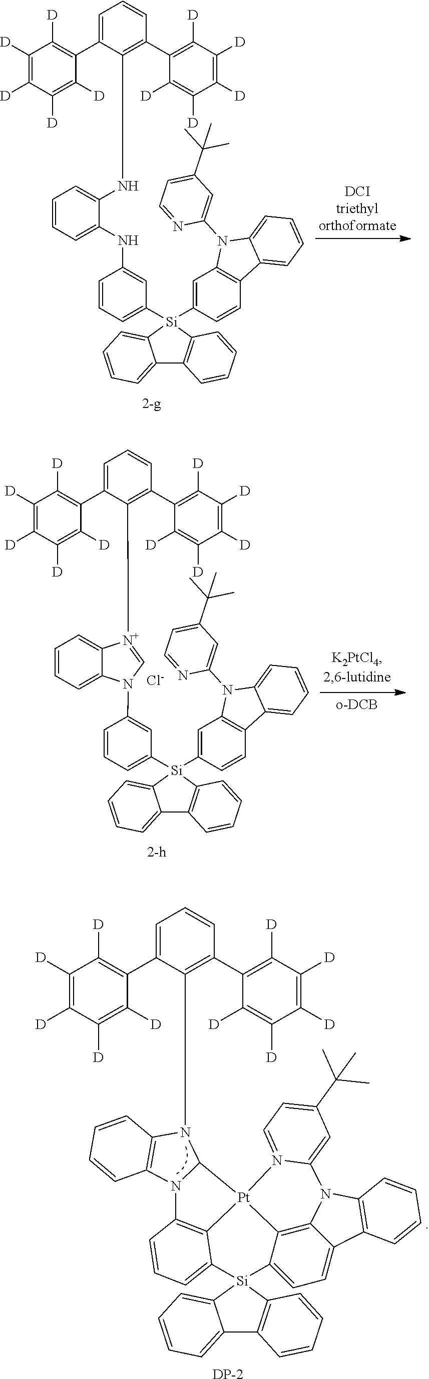

### 1) Synthesis of Intermediate 2-a

5,5-dichloro-5H-dibenzo[b,d]silole (1.5 eq) was dissolved in THF (0.5 M), and a reaction temperature was lowered to −78° C. 2.5 M n-butyllithium solution (hexane solvent) (1.5 eq) was added dropwise and reacted for 1 hour. 2-bromo-9H-carbazole (1.0 eq) was added, slowly warmed to room temperature, stirred for 12 hours, and extracted three times using dichloromethane (MC) and water to obtain an organic layer.

The obtained organic layer was dried with magnesium sulfate, and recrystallized using ethyl acetate (EA) and hexane solution (EA:hexane (v/v)=1:10) to synthesize Intermediate 2-a (yield 41%).

### 2) Synthesis of Intermediate 2-b

Intermediate 2-a (1.0 eq) and 4-(tert-butyl)-2-chloropyridine (1.5 eq) were dissolved in 1,4-dioxane (0.3 M), and copper(I) iodide (0.5 eq), potassium phosphate tribasic (1.5 eq) and trans-1,2-cyclohexanediamine (0.7 eq) were added. The mixture was refluxed at 120° C. for 12 hours.

The product was cooled to room temperature, and an organic layer was obtained by extracting three times using ethyl acetate (EA) and water. The obtained organic layer was dried using magnesium sulfate, and concentrated by a column chromatography to synthesize Intermediate 2-b (yield 80%).

### 3) Synthesis of Intermediate 2-c

Intermediate 2-b (1.0 eq), 2-(3-bromophenyl)-4,4,5,5-tetramethyl-1,3,2-dioxaborolane (1.0 eq), SphosPdG2 (0.1 eq), and potassium phosphate tribasic (7.0 eq) were dissolved in THF:H₂O (1:2) and stirred at 90° C. for 5 hours.

After cooling the product to room temperature, an organic layer was obtained by extracting three times using ethyl acetate (EA) and water. The obtained organic layer was dried using magnesium sulfate, and concentrated by using a column chromatography to obtain Intermediate 2-c (yield 71%).

### 4) Synthesis of Intermediate 2-d

1-bromobenzene-2,3,4,5,6-d5 (1.0 eq), bis(diphenylphosphino) ferrocene dichloropalladium (0.05 eq), bis(pinacolato)diboron (1.5 eq), and potassium acetate (3.0 eq) were dissolved in 1,4-dioxane and stirred at 100° C. for 24 hours.

After cooling the product to room temperature, distilled water was added and extracted three times with ethyl acetate (EA). The obtained organic layer was dried using magnesium sulfate, and concentrated by a column chromatography (EA/Hex) to obtain Intermediate 2-d (yield 82%).

### 5) Synthesis of Intermediate 2-e

Intermediate 2-d (1.0 eq), CX31 (Umicore) (0.05 eq), potassium carbonate (3.0 eq), and 2,6-dibromo-N-(2-nitrophenyl)aniline (1.2 eq) were dissolved in 1,4-dioxane:H₂O (3:1), and stirred at 100° C. for 18 hours. After cooling the product to room temperature, distilled water was added, and extraction was repeated three times with ethyl acetate. The obtained organic layer was dried using magnesium sulfate, and concentrated by a column chromatography (MC/Hex) to obtain Intermediate 2-e (yield 65%).

### 6) Synthesis of Intermediate 2-f

Intermediate 2-e (1.0 eq) and tin (5 eq) were dissolved in ethanol (EtOH) and stirred. Thereafter, hydrogen chloride (12M) was injected and stirred at 80° C. for 20 hours. After cooling the product to room temperature, distilled water was added and extraction was repeated three times with ethyl acetate. The obtained organic layer was dried using magnesium sulfate, and concentrated by a column chromatography (MC/Hex) to obtain Intermediate 2-f (yield 82%).

### 7) Synthesis of Intermediate 2-g

Intermediate 2-c (1.0 eq), Intermediate 2-f (1.0 eq), Pd₂(dba)₃ (tris(dibenzylideneacetone)dipalladium(0), 0.05 eq), Xphos (2-dicyclohexylphosphino-2′,4′,6′-triisopropylbiphenyl, 0.10 eq), and sodium tert-butoxide (2.0 eq) were dissolved in 1,4-dioxane (0.1 M), and stirred at 110° C. for 3 hours.

After cooling the product to room temperature, distilled water was added, and extraction was repeated three times with ethyl acetate. The obtained organic layer was dried using magnesium sulfate, and concentrated by a column chromatography (MC/Hex) to obtain Intermediate 2-g (yield 69%).

### 8) Synthesis of Intermediate 2-h

Intermediate 2-g (1.0 eq) was dissolved in triethyl orthoformate (30.0 eq), 37% HCl (1.5 eq) was added, and the mixture was stirred at 80° C. for 24 hours. After cooling the product to room temperature, triethyl orthoformate in the product was removed, distilled water was added, and extraction was repeated three times with ethyl acetate. The obtained organic layer was dried using magnesium sulfate, and concentrated by a column chromatography (MC/methanol) to synthesize Intermediate 2-h (yield 87%).

### 9) Synthesis of Compound DP-2

Intermediate 2-h (1.0 eq), potassium platinum (II) chloride (1.1 eq), and 2,6-Lutidine (4.0 eq) were dissolved in 1,2-dichlorobenzene (0.05 M), and stirred at 120° C. for 24 hours under a nitrogen condition. After cooling the product to room temperature, 1,2-dichlorobenzene in the product was concentrated and removed, distilled water was added, and extraction was repeated three times with ethyl acetate. The obtained organic layer was dried using magnesium sulfate, and concentrated by a column chromatography (MC/Hex) to synthesize Compound DP-2 (yield 40%).

### Synthesis Example 2: Synthesis of Compound DP-30

Compound DP-30 was synthesized based on Synthesis Scheme 2 below.

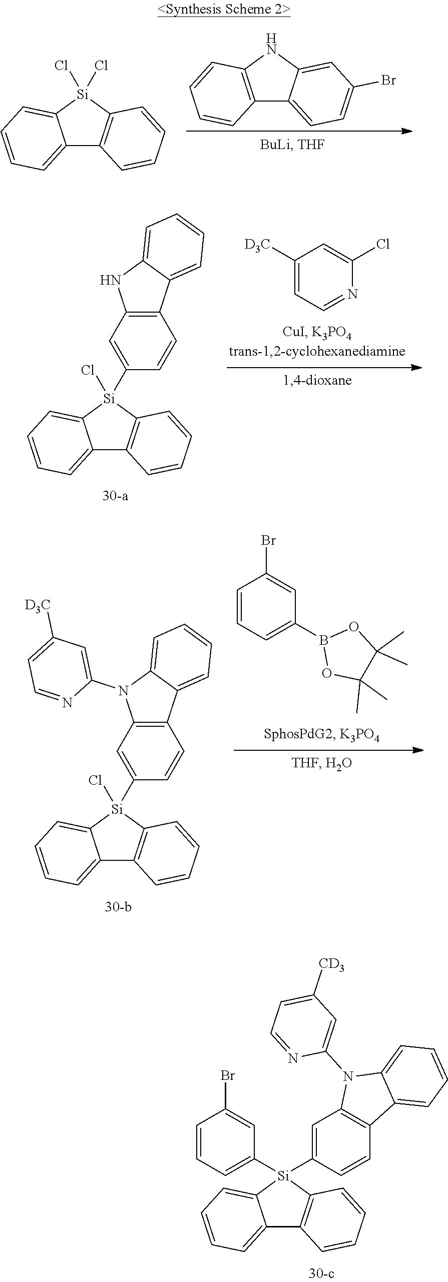

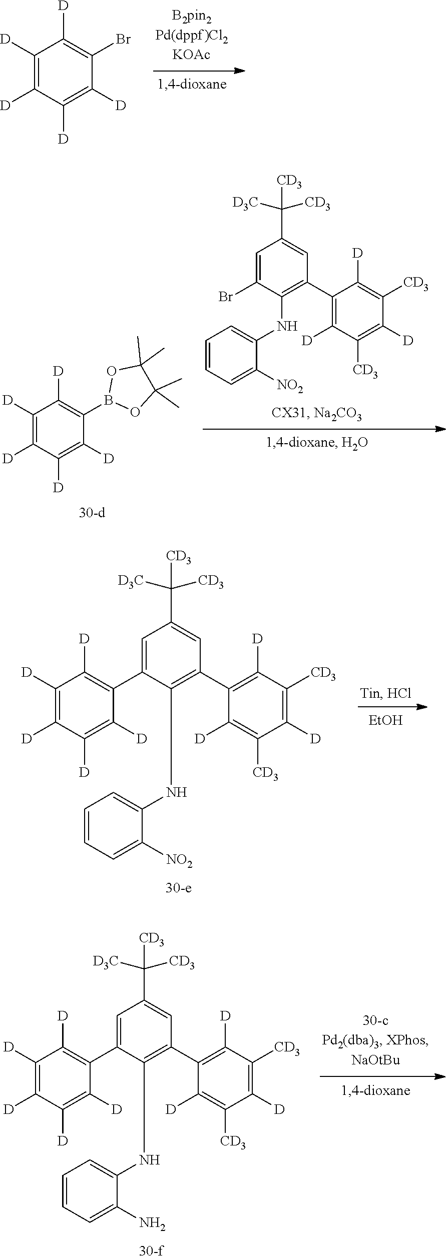

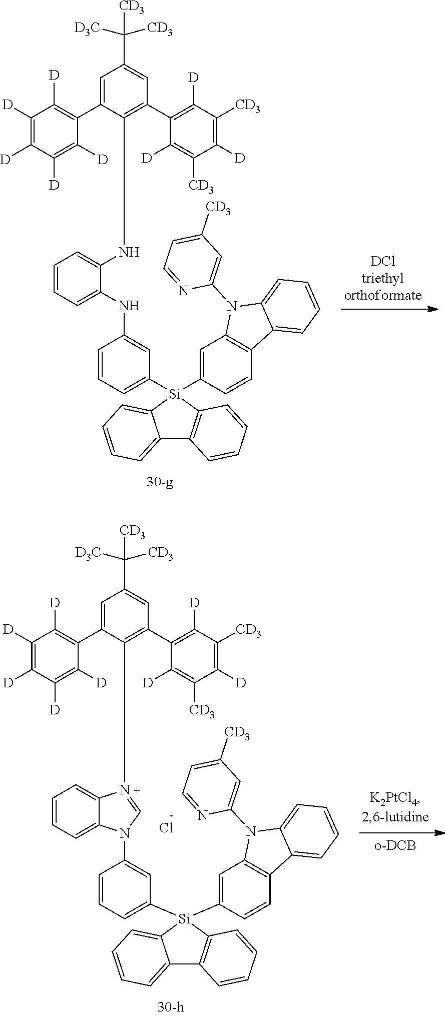

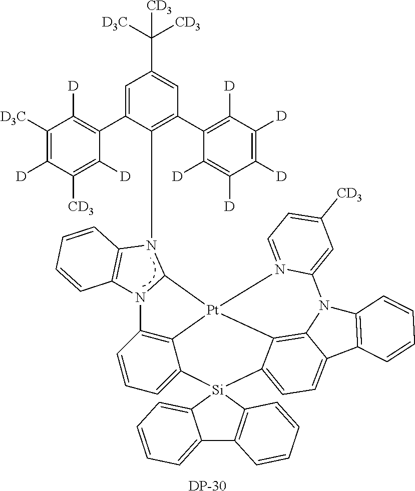

Compound DP-30 (yield 39%) was obtained using the same method as that in the synthesis of Compound DP-2, except that 2-chloro-4-(methyl-d3)pyridine was used instead of 4-(tert-butyl)-2-chloropyridine in the synthesis of Intermediate 30-b, and 3-bromo-3′,5′-bis(methyl-d3)-5-(2-(methyl-d3)propan-2-yl-1,1,1,3,3,3-d6)-N-(2-nitrophenyl)-[1,1′-biphenyl]-2′,4′,6′-d3-2-amine was used instead of 2,6-dibromo-N-(2-nitrophenyl)aniline in the synthesis of Intermediate 30-e.

### Synthesis Example 3: Synthesis of Compound DP-32

Compound DP-32 was synthesized based on Synthesis Scheme 3 below.

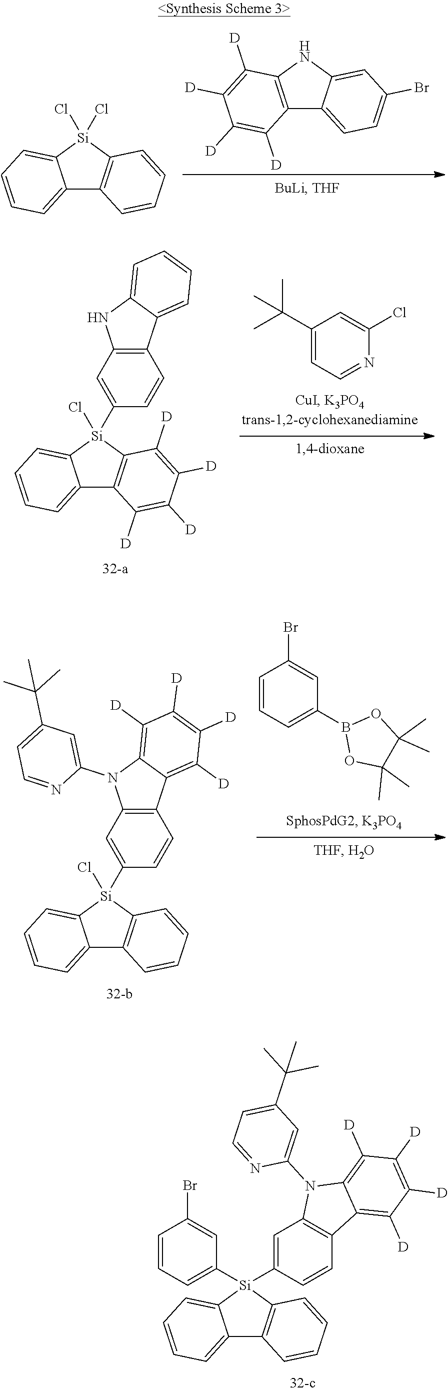

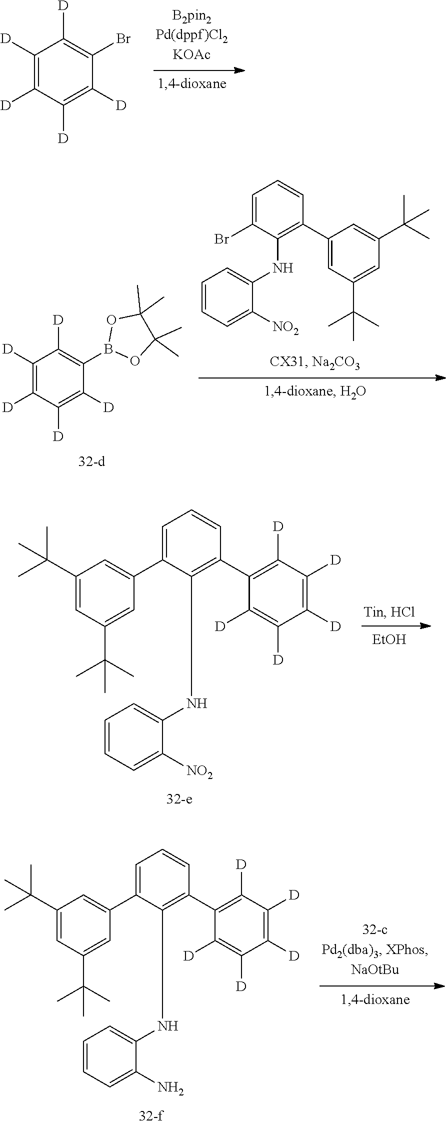

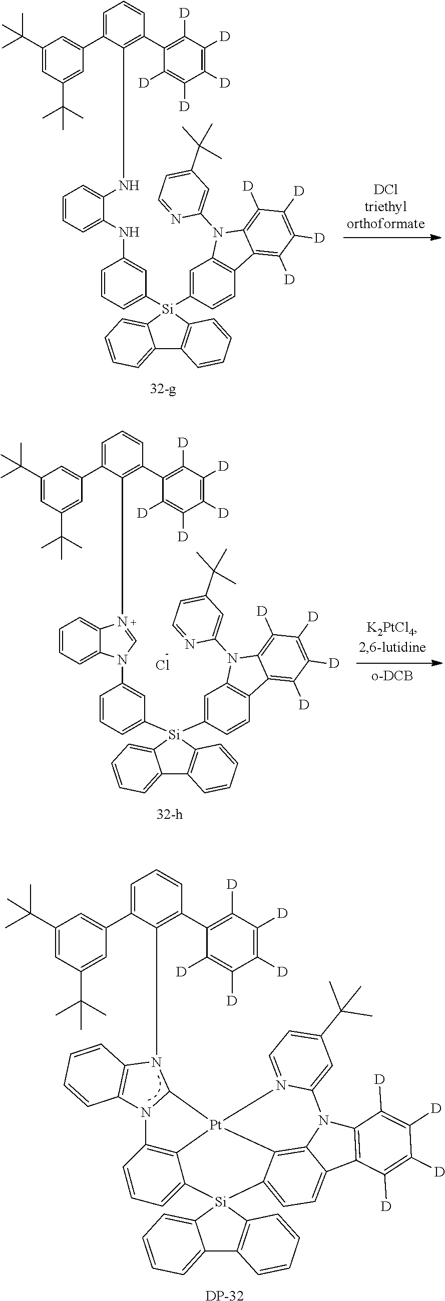

Compound DP-32 (yield 43%) was obtained using the same method as that in the synthesis of Compound DP-2, except that 2-bromo-9H-carbazole-5,6,7,8-d4 was used instead of 2-bromo-9H-carbazole in the synthesis of Intermediate 32-a, and 3-bromo-3′,5′-di-tert-butyl-N-(2-nitrophenyl)-[1,1′-biphenyl]-2-amine was used instead of 2,6-dibromo-N-(2-nitrophenyl)aniline in the synthesis of Intermediate 32-e.

### Synthesis Example 4: Synthesis of Compound DP-101

Compound DP-101 was synthesized based on Synthesis Scheme 4 below.

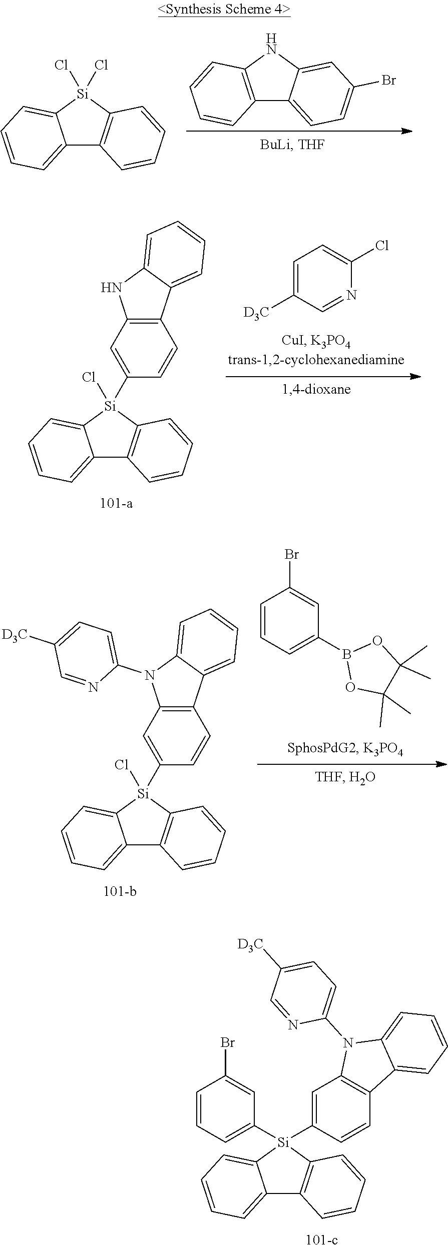

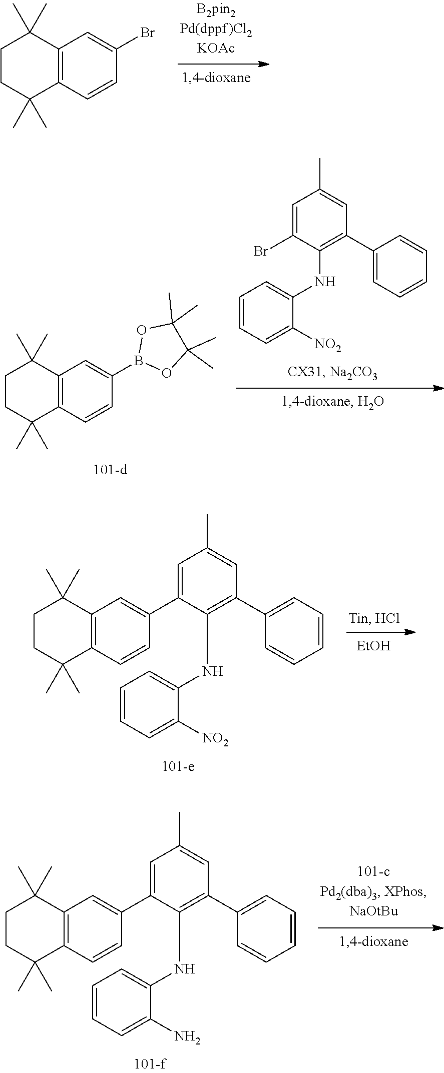

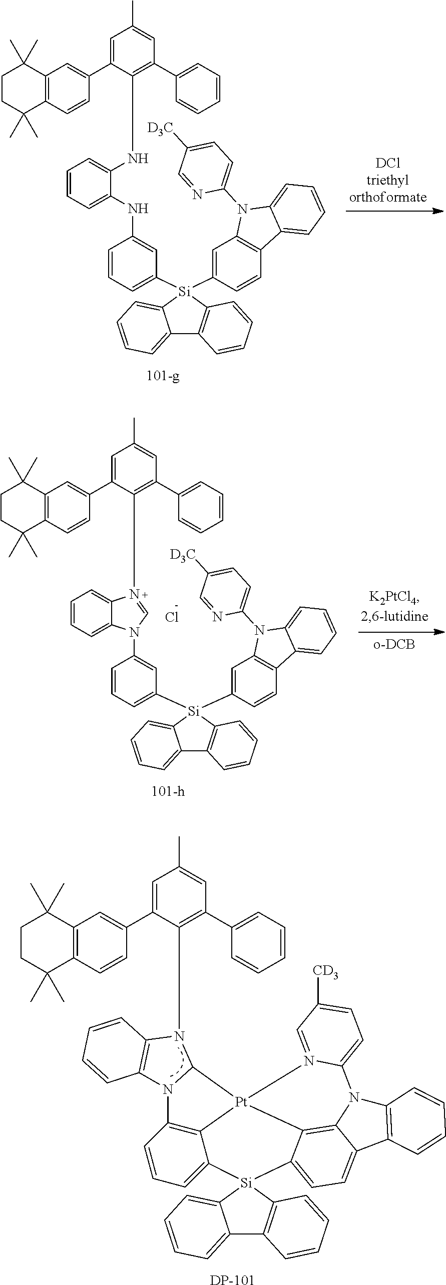

Compound DP-101 (yield 43%) was obtained using the same method as that for the synthesis of Compound DP-2, except that 2-chloro-5-(methyl-d3)pyridine was used instead of 4-(tert-butyl)-2-chloropyridine in the synthesis of Intermediate 101-b, 6-bromo-1,1,4,4-tetramethyl-1,2,3,4-tetrahydronaphthalene was used instead of 1-bromobenzene-2,3,4,5,6-d5 in the synthesis of Intermediate 101-d, and 3-bromo-5-methyl-N-(2-nitrophenyl)-[1,1′-biphenyl]-2-amine was used instead of 2,6-dibromo-N-(2-nitrophenyl)aniline in the synthesis of Intermediate 101-e.

### Synthesis Example 5: Synthesis of Compound DP-111

Compound DP-111 was synthesized based on Synthesis Scheme 5 below.

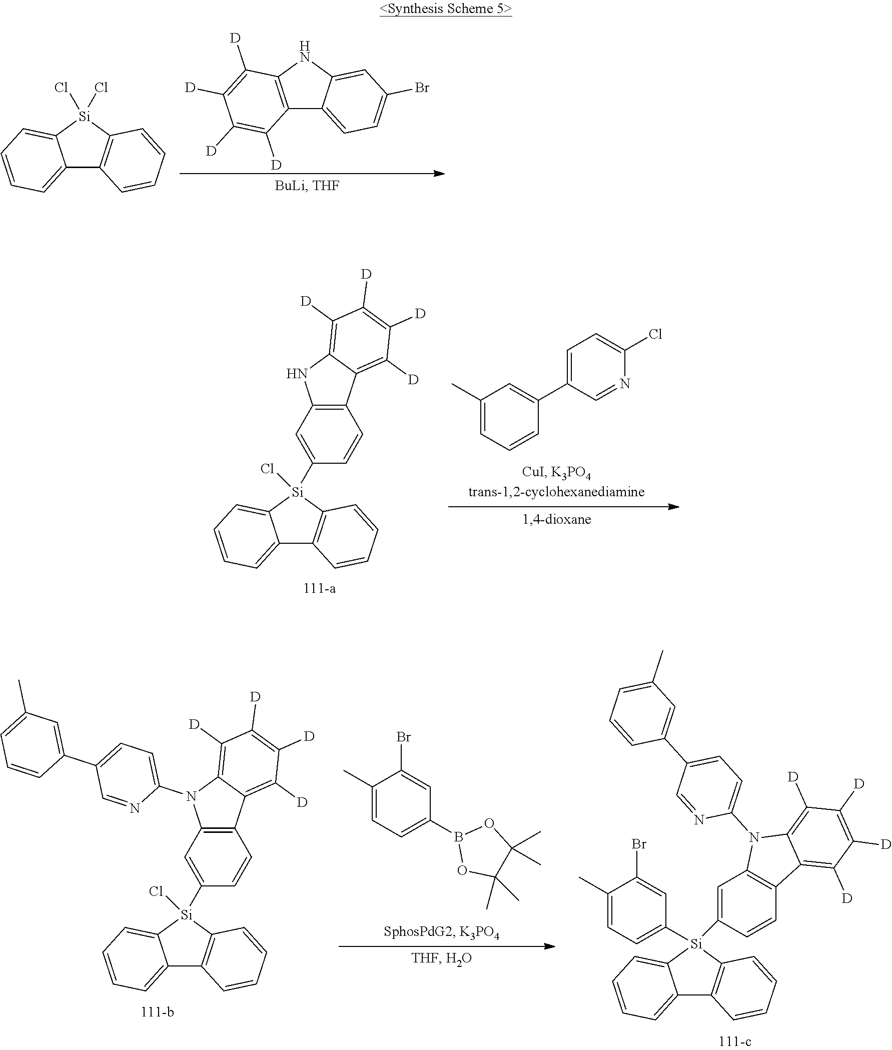

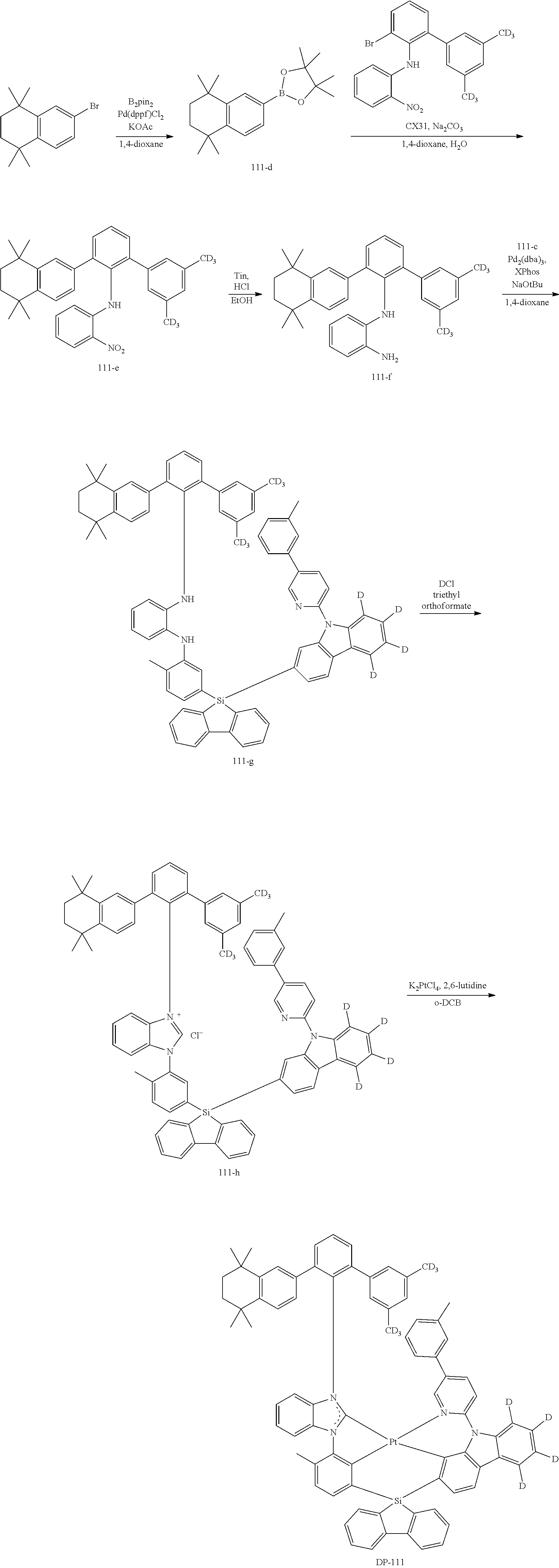

Compound DP-111 was synthesized (yield 37%) using the same method as that for the synthesis of Compound DP-2, except that 2-bromo-9H-carbazole-5,6,7,8-d was used instead of 2-bromo-9H-carbazole in the synthesis of Intermediate 111-a, 2-chloro-5-(m-tolyl)pyridine was used instead of 4-(tert-butyl)-2-chloropyridine in the synthesis of Intermediate 111-b, 2-(3-bromo-4-methylphenyl)-4,4,5,5-tetramethyl-1,3,2-dioxaborolane was used instead of 2-(3-bromophenyl)-4,4,5,5-tetramethyl-1,3,2-dioxaborolane in the synthesis of Intermediate 111-c, 6-bromo-1,1,4,4-tetramethyl-1,2,3,4-tetrahydronaphthalene was used instead of 1-bromobenzene-2,3,4,5,6-d5 in the synthesis of Intermediate 111-d, 3-bromo-3′,5′-bis(methyl-d3)-N-(2-nitrophenyl)-[1,1′-biphenyl]-2-amine was used instead of 2,6-dibromo-N-(2-nitrophenyl)aniline was used in the synthesis of Intermediate 111-e.

### Synthesis Example 6: Synthesis of Compound DP-122

Compound DP-122 was synthesized based on Synthesis Scheme 6 below.

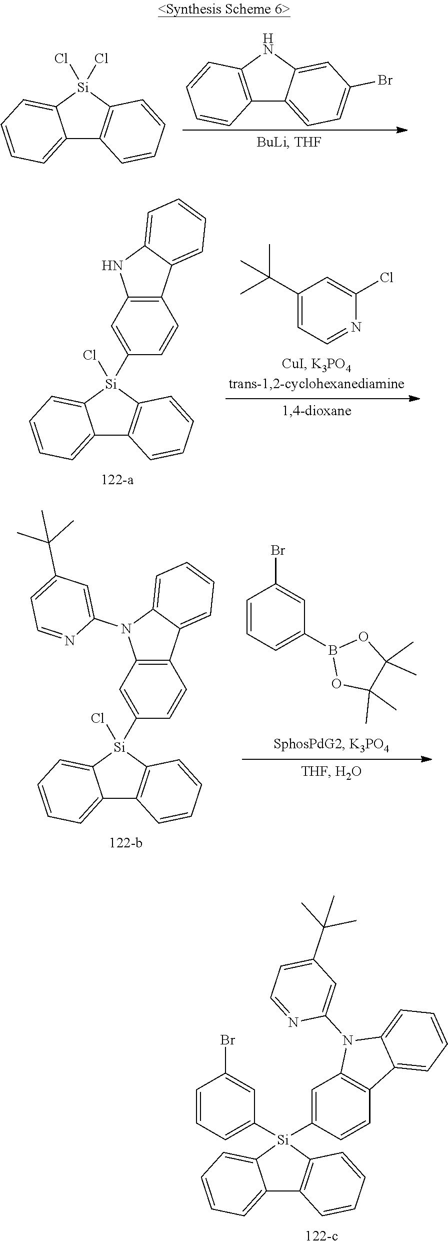

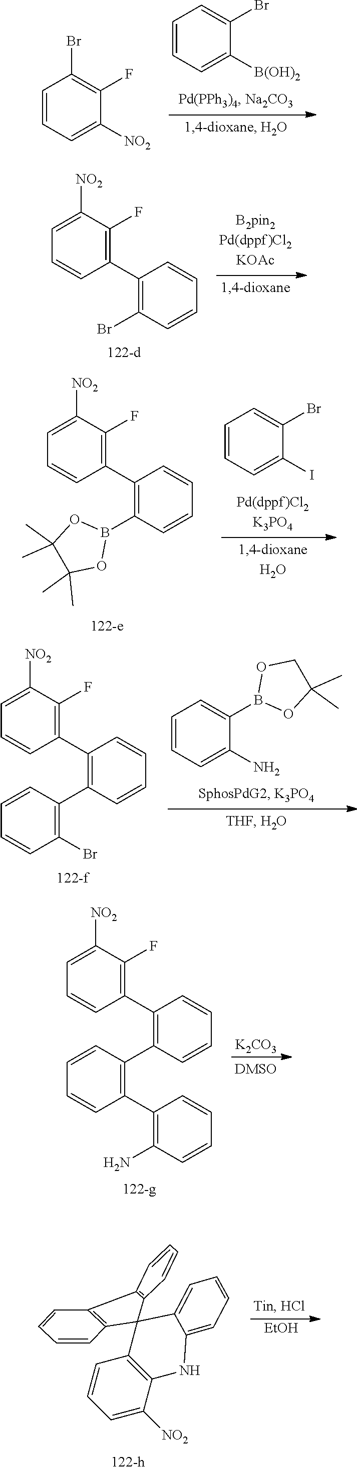

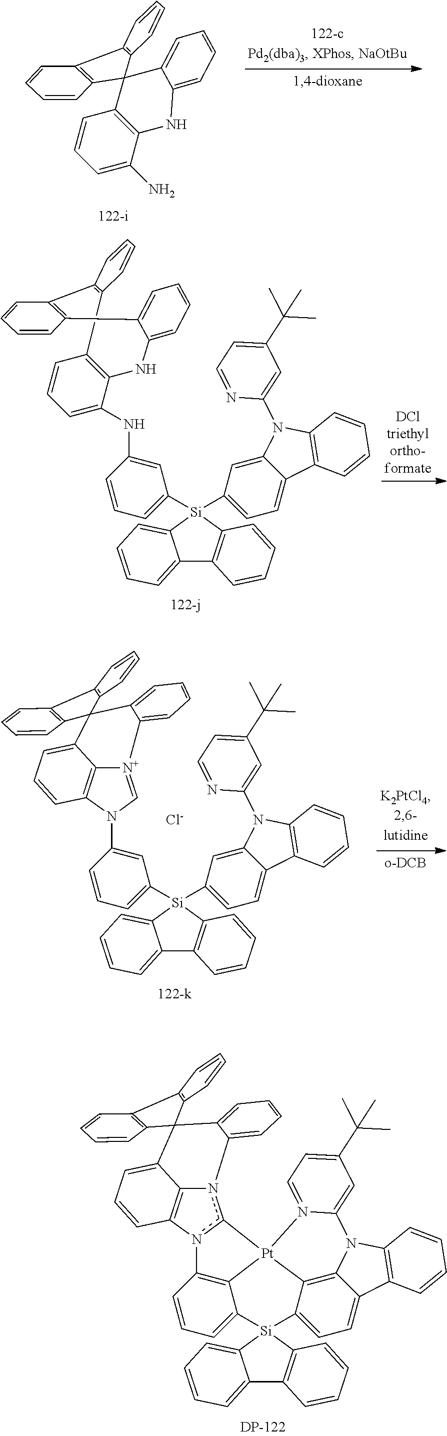

### 1) Synthesis of Intermediate 122-d

1-bromo-2-fluoro-3-nitrobenzene (1.5 eq), (2-bromophenyl)boronic acid (1.0 eq), Pd(PPh₃)₄ (10 mol %), and potassium carbonate (3.0 eq) were dissolved in 1,4-dioxane:H₂O (volume ratio=4:1) (0.1 M), and stirred at 100° C. for 12 hours. After cooling the product to room temperature, an organic layer was obtained by extracting three times using EA and water.

The obtained organic layer was dried using magnesium sulfate, and concentrated by a column chromatography (EA:Hexane=1:20 (volume ratio)) to obtain Intermediate 122-d (yield 64%).

### 2) Synthesis of Intermediate 122-e

Intermediate 122-d (1.0 eq), bis(diphenylphosphino)ferrocene dichloropalladium (0.05 eq), bis(pinacolato)diboron (1.5 eq), and potassium acetate (3.0 eq) were dissolved in 1,4-dioxane and stirred at 100° C. for 24 hours. After cooling the product to room temperature, distilled water was added and extracted three times with ethyl acetate.

The obtained organic layer was dried using magnesium sulfate, and concentrated by a column chromatography (EA/Hex) to obtain Intermediate 122-e (yield 76%).

### 3) Synthesis of Intermediate 122-f

The Intermediate 122-e (1.5 eq), 1-bromo-2-iodobenzene (1.5 eq), bis(diphenylphosphino)ferrocene dichloropalladium (0.05 eq), and potassium phosphate tribasic (5.0 eq) were dissolved in a 1,4-dioxane/H₂O solution, and stirred at 100° C. for 24 hours.

After cooling the product to room temperature, distilled water was added, and extraction was repeated three times with ethyl acetate.

The obtained organic layer was dried using magnesium sulfate, and concentrated by a column chromatography (EA/Hex) to obtain Intermediate 122-f (yield 72%).

### 4) Synthesis of Intermediate 122-g

Intermediate 122-f (1.0 eq), 2-(4,4,5,5-tetramethyl-1,3,2-dioxaborolan-2-yl)aniline (1.0 eq), SphosPdG2 (0.1 eq), and potassium phosphate tribasic (7.0 eq) were dissolved in THF:H₂O (1:2) solution and stirred at 90° C. for 5 hours. After cooling the product to room temperature, the organic layer was obtained by extracting three times using ethyl acetate (EA) and water.

The obtained organic layer was dried using magnesium sulfate, and concentrated by a column chromatography to obtain Intermediate 122-g (yield 67%).

### 5) Synthesis of Intermediate 122-h

Intermediate 122-g (1.0 eq) and K₂CO₃ (2.0 eq) were dissolved in dimethylsulfoxide (0.1 M), and stirred at 160° C. for 9 hours. After cooling the product to room temperature, the organic layer was extracted three times using ethyl acetate (EA) and water.

The obtained organic layer was dried using magnesium sulfate, and concentrated by a column chromatography to obtain Intermediate 122-h (yield 75%).

Compound DP-122 (yield 35%) was synthesized using the same method as that for the synthesis of Compound DP-2, except for the intermediate synthesis described above.

The results of ¹H NMR and HR-MS (High-Resolution Mass Spectroscopy) measurements of the compounds synthesized by the above Synthesis Examples are shown in Table 1.

TABLE 1

| | | | HR- |
|---|---|---|---|
| | | | MS |
| | | | (m/z) |
| | Compound | ¹H NMR (CDCl₃, 500 MHz) | [M+] |
| Synthesis Example 1 (Example 1) | 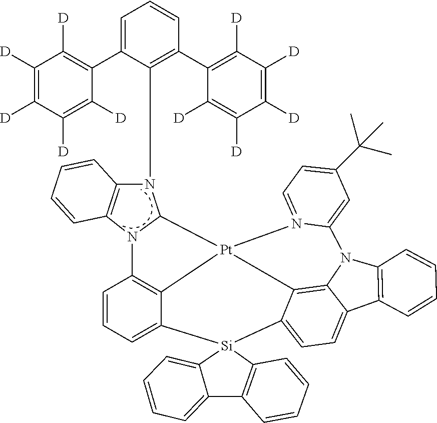 | δ 8.74 (d, 1H), 8.56 (d, 2H), 8.53 (d, 1H), 8.19 (d, 1H), 7.87 (m, 4H), 7.73- 7.46 (m, 8H), 7.65-7.40 (m, 7H), 7.28 (tr, 2H), 7.20 (tr, 1H) 1.32( s, 9H) | 1104.33 |
| | DP-2 | | |
| Synthesis Example 2 (Example 2) | 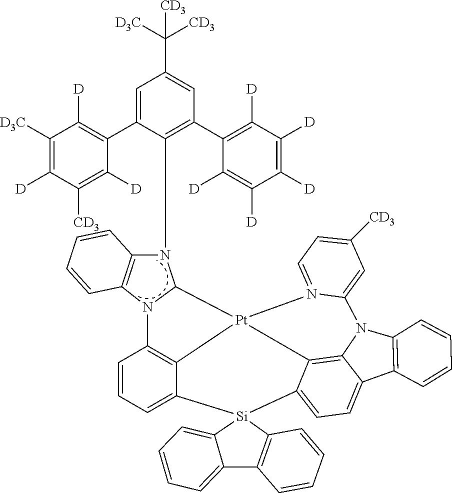 | δ 8.74 (d, 1H), 8.56 (d, 2H), 8.53 (d, 1H), 8.19 (d, 1H), 8.03 (s, 2H) 7.87 (d, 2H), 7.71-7.40 (m, 14H), 7.28 (tr, 2H), 7.20 (tr, 1H) | 1161.55 |
| | DP-30 | | |
| Synthesis Example 3 (Example 3) | 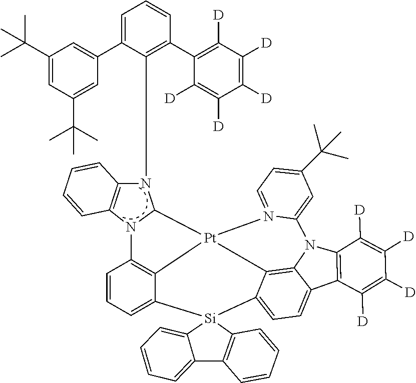 | δ 8.74 (d, 1H), 8.56 (d, 2H), 8.53 (d, 1H), 7.87 (d, 2H), 7.73-7.60 (m, 10H), 7.47-7.40 (m, 5H), 7.28 (tr, 2H), 2H), 7.20 (tr, 1H), 1.32 (s, 27H) | 1214.50 |
| | DP-32 | | |
| Synthesis Example 4 (Example 4) | 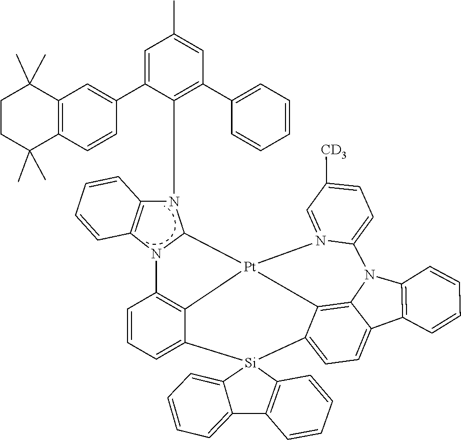 | δ 8.71 (d, 1H), 8.56 (d, 2H), 8.53 (d, 1H), 8.19 (d, 1H), 7.93-7.87 (m, 5H), 7.71-7.58 (m, 8H), 7.50-7.41 (m, 7H), 7.28-7.19 (m, 9H), 2.36 (s, 3H), 1.48 (s, 4H), 0.91 (s, 12H) | 1178.41 |
| | DP-101 | | |
| Synthesis Example 5 (Example 5) | 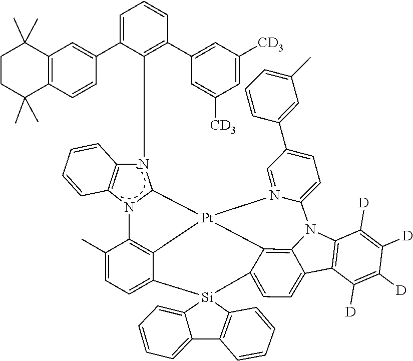 | δ 9.07 (s, 1H), 8.56 (d, 2H), 8.53 (d, 1H), 8.23-8.21 (m, 2H), 7.87 (m, 4H), 7.78-7.60 (m, 9H), 7.49-7.35 (m, 6H), 7.28-7.26 (m, 4H), 7.18-7.11 (m, 3H), 2.46 (s, 3H), 1.92 (s, 3H), 1.48 (s, 4H), 0.91 (s, 12H) | 1289.53 |
| | DP-111 | | |
| Synthetic Example 6 (Example 6) | 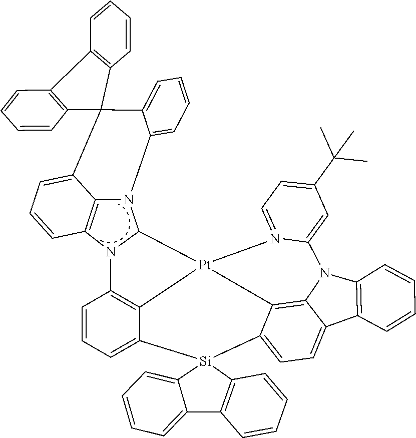 | δ 8.74 (d, 1H), 8.56 (d, 2H), 8.53 (d, 1H), 8.42 (m, 5H), 8.19 (d, 1H), 8.10 (m, 5H), 7.87-7.72 (m, 4H), 7.71-7.46 (m, 7H), 7.65-7.39 (m, 5H), 7.28 (tr, 2H), 7.22- 7.20 (m, 2H) 1.32 (s, 9H) | 1091.30 |
| | DP-122 | | |

The compounds below were used in Comparative Examples 1 to 3.

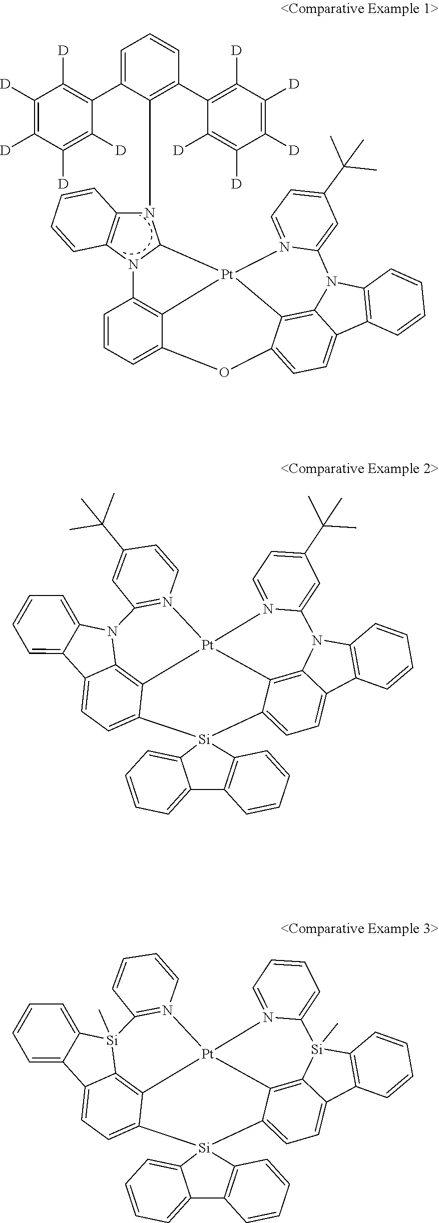

### Evaluation Example

HOMO/LUMO energy levels (eV), a maximum emission wavelength (nm), a spin-orbit coupling (SOC), and a triplet metal-to-ligand charge transfer (MLCT) ratio (%) of the compounds in Table 1 were evaluated using a DFT method of a Gaussian program structure-optimized at a B3LYP/6-31G(d,p) level.

The evaluation results are shown in Table 2.

TABLE 2

| | | | maximum | | |
|---|---|---|---|---|---|
| | HOMO | LUMO | emission wavelength | | MLCT |
| | (eV) | (eV) | (λmax)(nm) | SOC | (%) |
| Example 1 | −5.24 | −1.48 | 447.12 | 62.11 | 14.81 |
| Example 2 | −5.11 | −1.49 | 450.28 | 61.86 | 14.55 |
| Example 3 | −5.23 | −1.54 | 451.05 | 63.01 | 14.05 |
| Example 4 | −5.13 | −1.51 | 449.60 | 60.78 | 13.68 |
| Example 5 | −5.14 | −1.52 | 449.87 | 60.53 | 13.42 |
| Example 6 | −5.22 | −1.57 | 451.01 | 59.46 | 13.79 |
| Comparative | −4.88 | −1.50 | 457.10 | 50.18 | 12.90 |
| Example 1 | | | | | |
| Comparative | −4.72 | −1.49 | 490.89 | 40.37 | 7.98 |
| Example 2 | | | | | |
| Comparative | −4.75 | −1.59 | 495.11 | 45.33 | 8.25 |
| Example 3 | | | | | |

Referring to Table 2, a short-wavelength effect was induced as a depth of the HOMO energy level increased in the organometallic compounds according to embodiments of the disclosure. SOC and MLCT properties were also enhanced in the organometallic compounds according to embodiments.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. An organometallic compound represented by Chemical Formula 1: 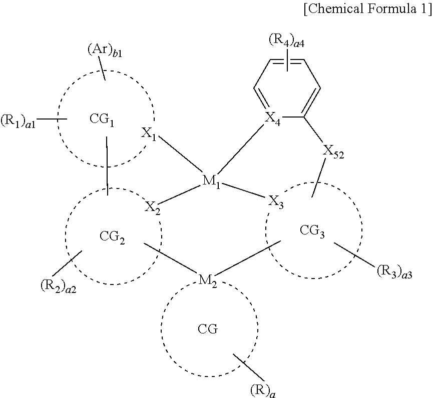
wherein in Chemical Formula 1,
M₁ is platinum (Pt), palladium (Pd), gold (Au), nickel (Ni), silver (Ag), or copper (Cu),
M₂ is carbon (C) or silicon (Si),
X₁ to X₄ are each independently C or nitrogen (N),
CG, CG₁, CG₂, and CG₃ are each independently a C₃-C₆₀ carbocyclic group or a C₁-C₆₀ heterocyclic group, provided that a ring formed by X₁ and CG₁ is not a benzene group or a pyridine group,
X₅ is a direct linkage, *—N(R₅)—*′, *—B(R₅)—*′, *—P(R₅)—*′, *—C(R₅ₐ)(R_{5b})—*′, *—Si(R₅ₐ)(R_{5b})—*′, *—Ge(R₅ₐ)(R_{5b})—*′, *—S—*′, *—Se—*′, *—O—*′, *—C(═O)—*′, *—S(═O)—*′, *—S(═O)₂—*′, *—C(R₅)═*′, *═C(R₅)—*′, *—C(R₅ₐ)═C(R_{5b})—*′, *—C(═S)—*′ or *—C≡C—*′,
Ar is a substituted or unsubstituted C₆-C₆₀ aryl group, or a substituted or unsubstituted C₅-C₆₀ heteroaryl group,
R, R₂ to R₄, R₅, R₅ₐ, and R_{5b} are each independently hydrogen, deuterium, a halogen, a substituted or unsubstituted C₁-C₁₀ alkyl group, a substituted or unsubstituted C₂-C₁₀ alkenyl group, a substituted or unsubstituted C₂-C₁₀ alkynyl group, a substituted or unsubstituted C₆-C₃₀ aryl group, or a substituted or unsubstituted C₅-C₃₀ heteroaryl group,
R₁ is: hydrogen, deuterium, a halogen, a substituted or unsubstituted C₁-C₁₀ alkyl group, a substituted or unsubstituted C₂-C₁₀ alkenyl group, a substituted or unsubstituted C₂-C₁₀ alkynyl group, a substituted or unsubstituted C₆-C₃₀ aryl group, a substituted or unsubstituted C₅-C₃₀ heteroaryl group; a direct linkage bonded to Ar; or a substituted or unsubstituted C₁-C₁₀ alkylene group bonded to Ar,
a, a1, a2, a3, and a4 are each independently an integer from 0 to 20, and
b1 is 1 or 2.

2. The organometallic compound of claim 1, wherein in Chemical Formula 1,
M₁ is Pt, and
M₂ is Si.

3. The organometallic compound of claim 2, wherein in Chemical Formula 1, CG forms a bridge of a silafluorene moiety.

4. The organometallic compound of claim 1, wherein in Chemical Formula 1,
CG₂ and CG₃ are different from each other, and
the number of carbon atoms in CG₂ is less than the number of carbon atoms in CG₃.

5. The organometallic compound of claim 4, wherein
CG₂ forms a benzene group with X₂, and
CG₃ forms a carbazole group with X₃.

6. The organometallic compound of claim 1, wherein in Chemical Formula 1, the number of carbon atoms in Ar is greater than the number of carbon atoms in (R₄)ₐ₄.

7. The organometallic compound of claim 1, wherein the organometallic compound is represented by Chemical Formula 1-1: 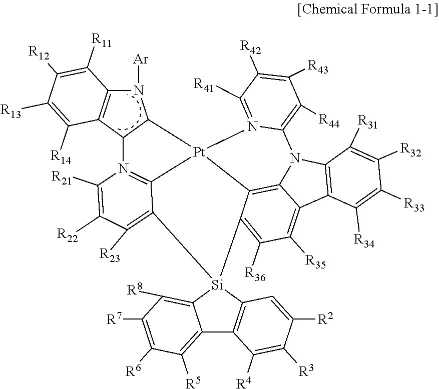
wherein in Chemical Formula 1-1,
R¹ to R⁸, R₁₁ to R₁₄, R₂₁ to R₂₃, R₃₁ to R₃₆, and R₄₁ to R₄₄ are each independently hydrogen, deuterium, a halogen, a substituted or unsubstituted C₁-C₁₀ alkyl group, a substituted or unsubstituted C₂-C₁₀ alkenyl group, a substituted or unsubstituted C₂-C₁₀ alkynyl group, a substituted or unsubstituted C₆-C₃₀ aryl group, or a substituted or unsubstituted C₅-C₃₀ heteroaryl group, and
Ar is the same as defined in Chemical Formula 1.

8. The organometallic compound of claim 7, wherein in Chemical Formula 1-1,
at least one of R₄₁ to R₄₄ each independently includes a substituted or unsubstituted aryl group, or a substituted or unsubstituted heteroaryl group,
the number of carbon atoms in the aryl group or in the heteroaryl group included in R₄₁ to R₄₄ is less than the number of carbon atoms in Ar.

9. The organometallic compound of claim 7, wherein Ar includes three or more benzene rings.

10. The organometallic compound of claim 7, wherein the organometallic compound is represented by Chemical Formula 1-2: 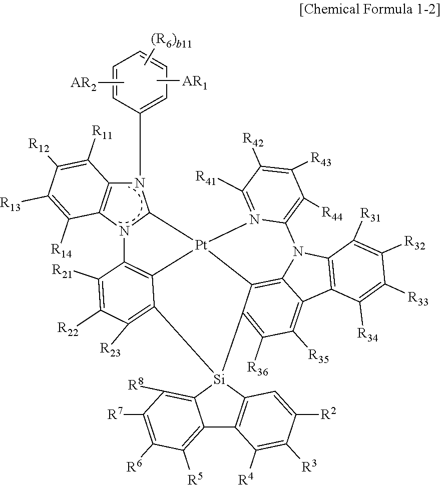
wherein in Chemical Formula 1-2,
Ar₁ and Ar₂ are each independently a substituted or unsubstituted C₆-C₃₀ aryl group, or a substituted or unsubstituted C₅-C₃₀ heteroaryl group,
R₆ is each independently hydrogen, deuterium, a halogen, a substituted or unsubstituted C₁-C₁₀ alkyl group, a substituted or unsubstituted C₂-C₁₀ alkenyl group, or a substituted or unsubstituted C₂-C₁₀ alkynyl group,
b₁₁ is an integer from 0 to 3, and
R¹ to R⁸, Ru to R₁₄, R₂ to R₂, R₃₁ to R₃₆, and R₄₁ to R₄₄ are each the same as defined in Chemical Formula 1-1.

11. The organometallic compound of claim 10, wherein in Chemical Formula 1-2, at least one of Ar₁ and Ar₂ is each independently a substituted or unsubstituted C₆-C₃₀ aryl group condensed with a cycloalkyl group, or a substituted or unsubstituted C₅-C₃₀ heteroaryl group condensed with a cycloalkyl group.

12. The organometallic compound of claim 11, wherein in Chemical Formula 1-2,
at least one of Ar and Ar₂ is each independently represented by 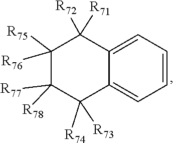
and
R₇₁ to R₇₈ are each independently hydrogen, deuterium, a halogen, a substituted or unsubstituted C₁-C₁₀ alkyl group, a substituted or unsubstituted C₂-C₁₀ alkenyl group, or a substituted or unsubstituted C₂-C₁₀ alkynyl group.

13. The organometallic compound of claim 1, wherein the organometallic compound is represented by Chemical Formula 1-3: 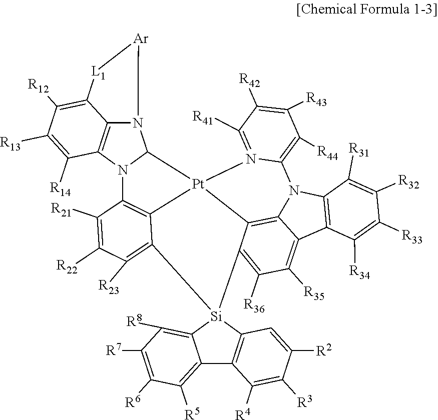
wherein in Chemical Formula 1-3,
L₁ is a direct linkage or a substituted or unsubstituted C₁-C₁₀ alkylene group,
R¹ to R⁸, R₁₂ to R₁₄, R₂₁ to R₂₃, R₃₁ to R₃₆, and R₄₁ to R₄₄ are each independently hydrogen, deuterium, a halogen, a substituted or unsubstituted C₁-C₁₀ alkyl group, a substituted or unsubstituted C₂-C₁₀ alkenyl group, a substituted or unsubstituted C₂-C₁₀ alkynyl group, a substituted or unsubstituted C₆-C₃₀ aryl group, or a substituted or unsubstituted C₅-C₃₀ heteroaryl group, and
Ar is the same as defined in Chemical Formula 1.

14. The organometallic compound of claim 13, wherein the organometallic compound is represented by Chemical Formula 1-4: 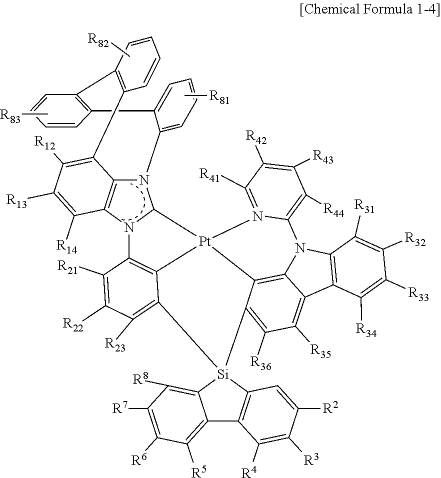
wherein in Chemical Formula 1-4,
R₈₁ to R₈₃ are each independently hydrogen, deuterium, a halogen, a substituted or unsubstituted C₁-C₁₀ alkyl group, a substituted or unsubstituted C₂-C₁₀ alkenyl group, a substituted or unsubstituted C₂-C₁₀ alkynyl group, a substituted or unsubstituted C₆-C₃₀ aryl group, or a substituted or unsubstituted C₅-C₃₀ heteroaryl group, and
R¹ to R⁸, R₁₂ to R₁₄, R₂₁ to R₂₃, R₃₁ to R₃₆, and R₄₁ to R₄₄ are each the same as defined in Chemical Formula 1-3.

15. The organometallic compound of claim 1, wherein the organometallic compound is one of Compounds DP-1 to DP-150:

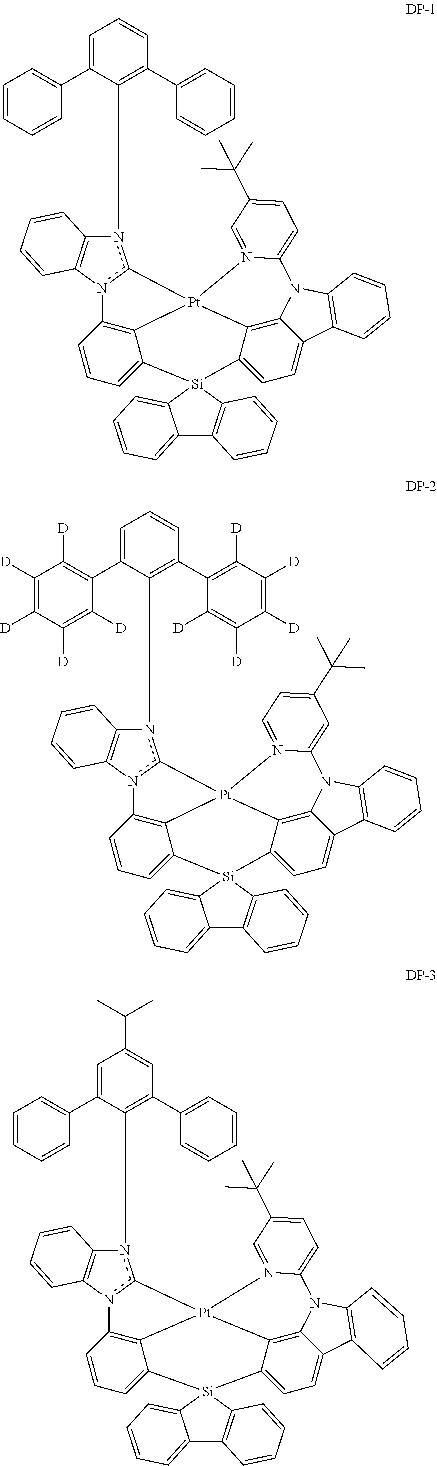

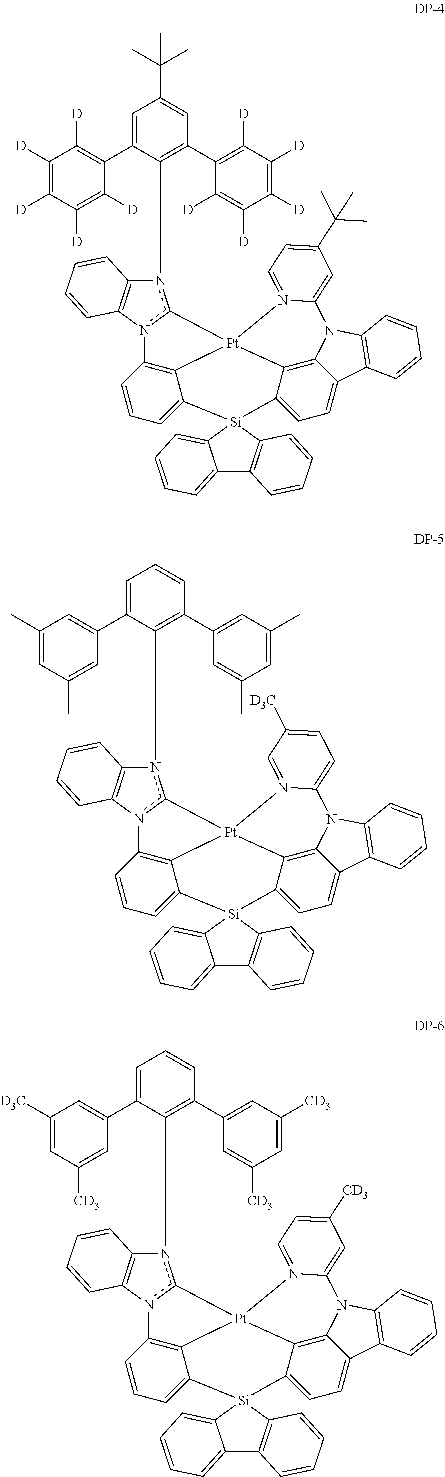

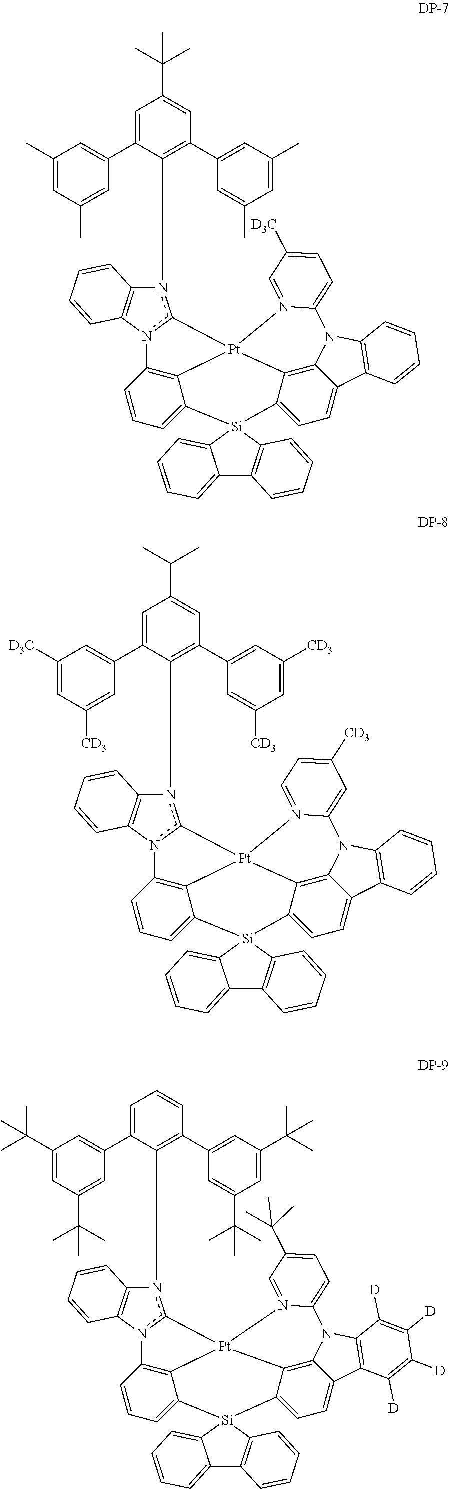

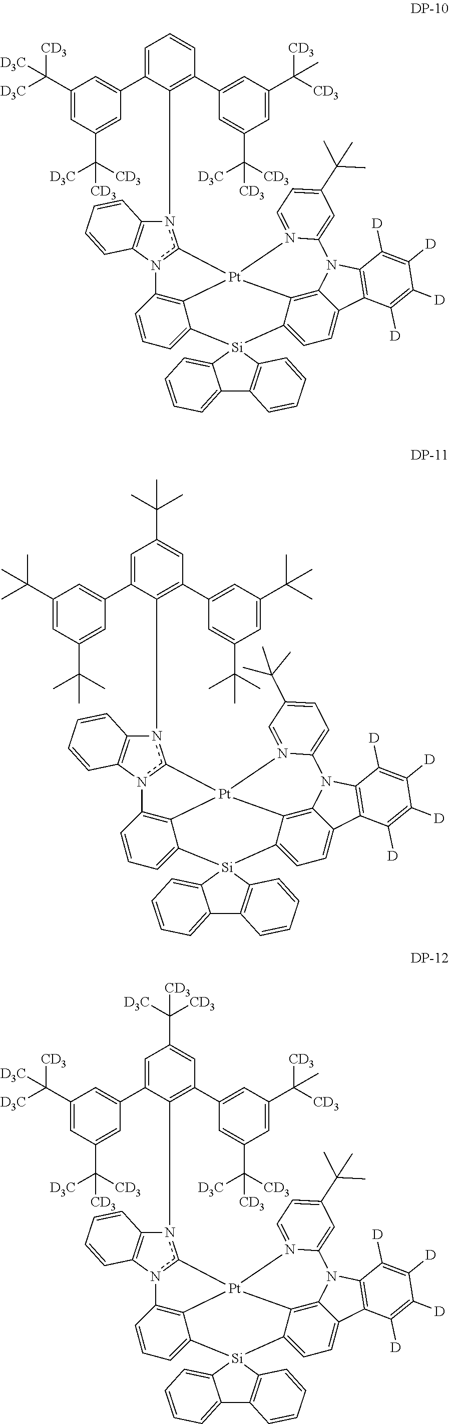

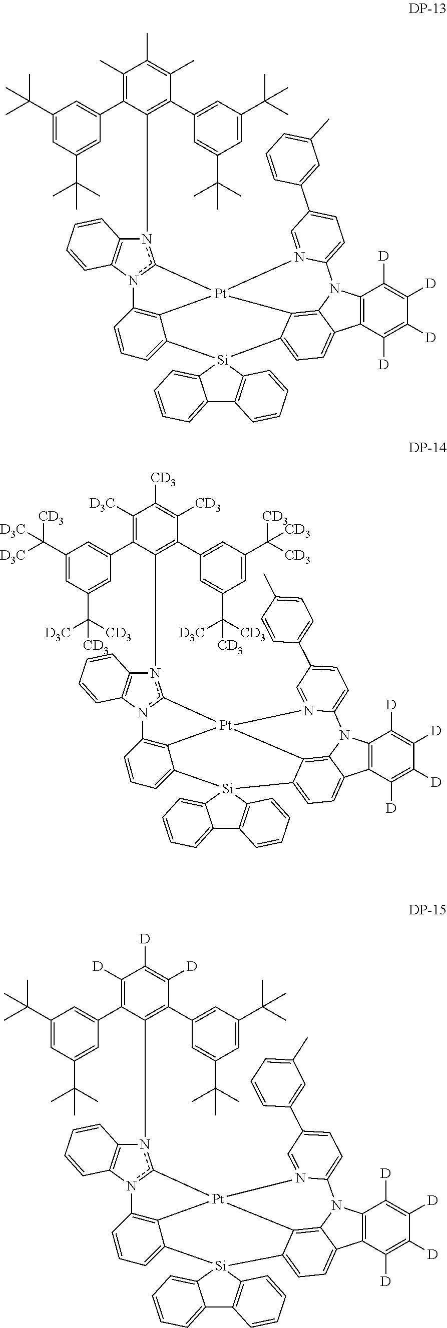

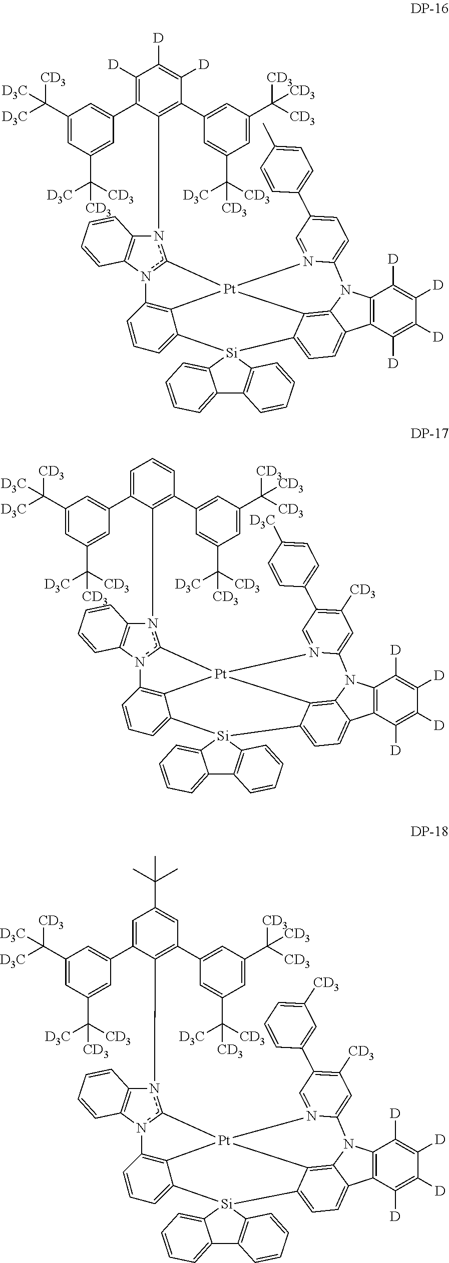

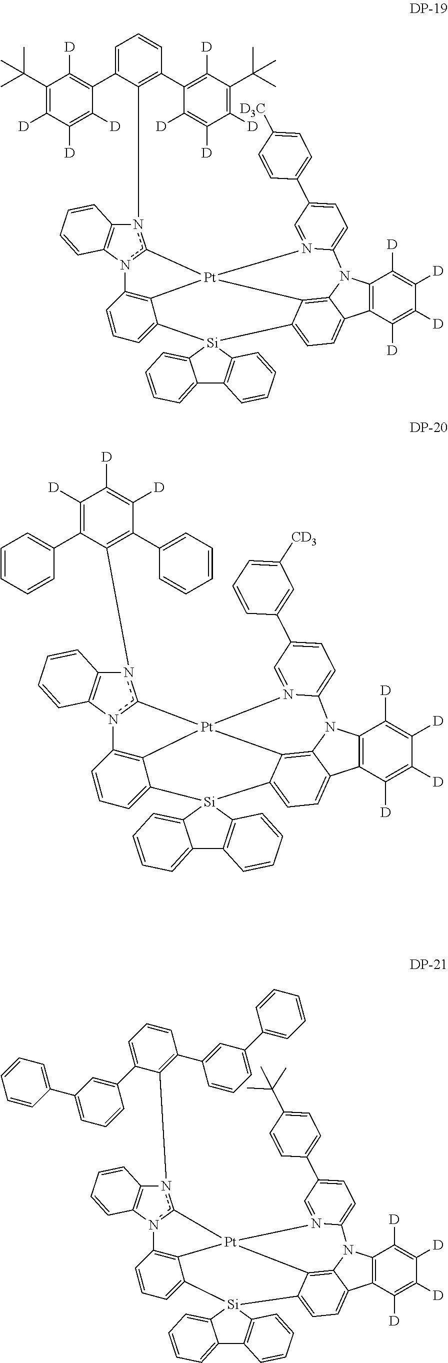

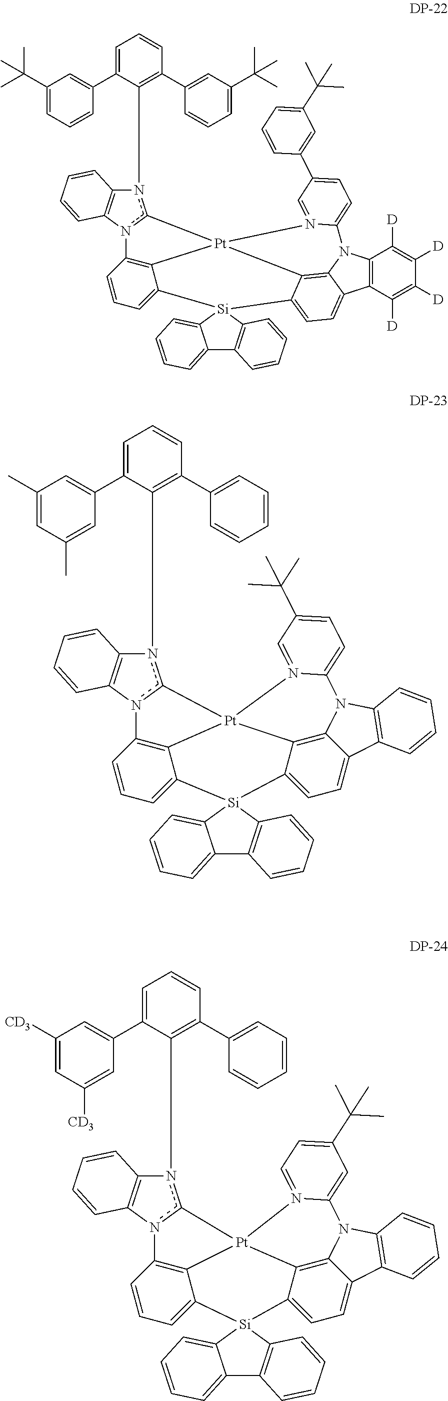

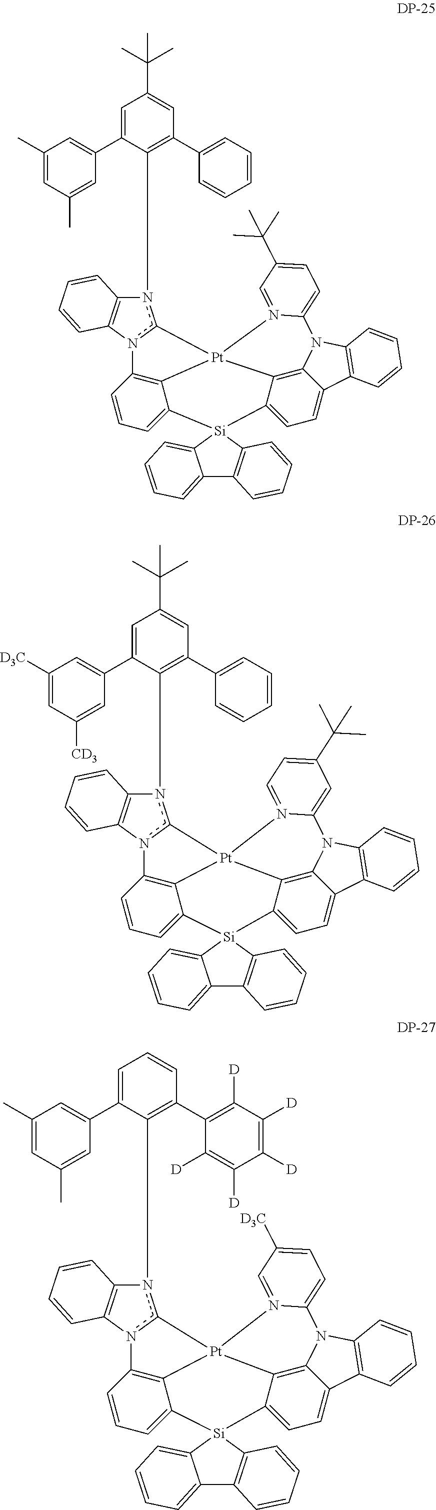

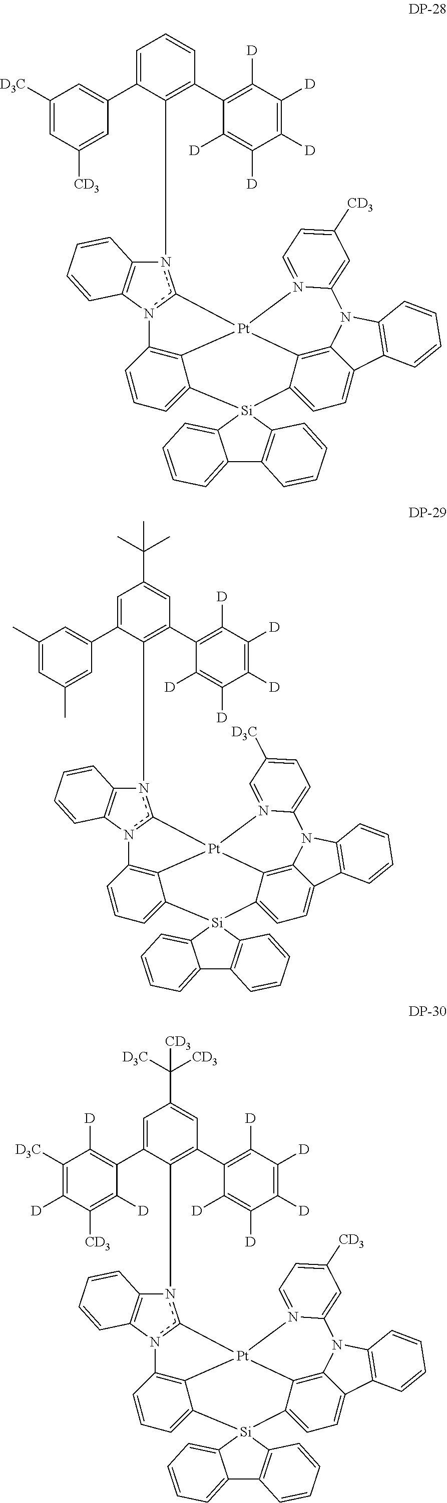

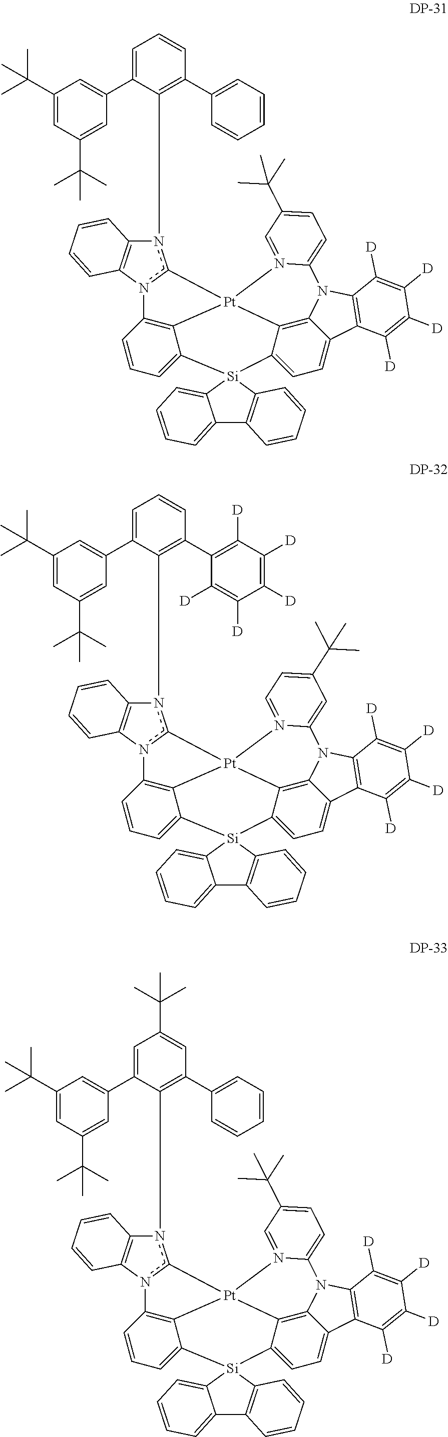

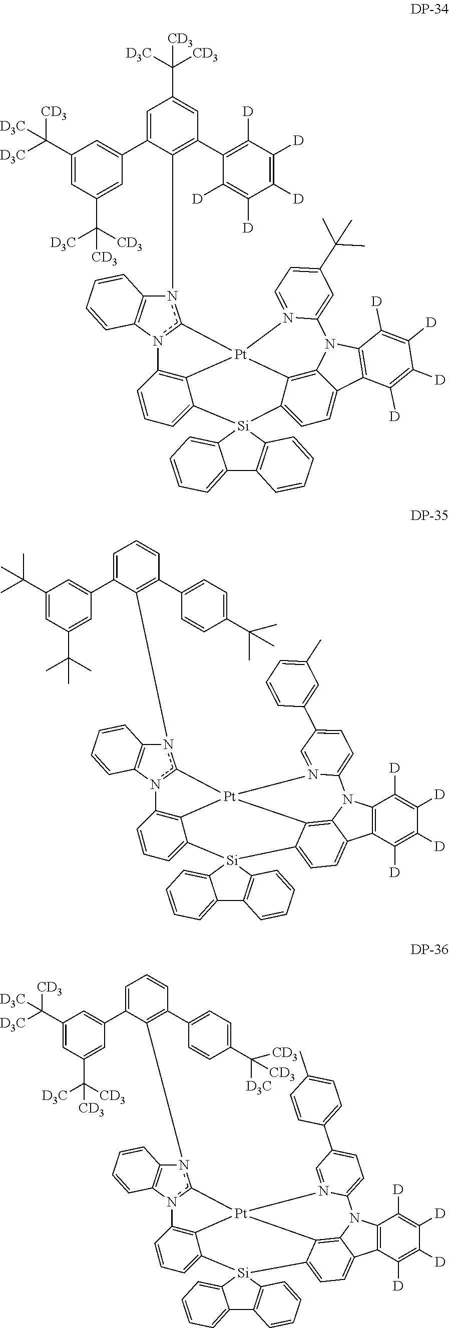

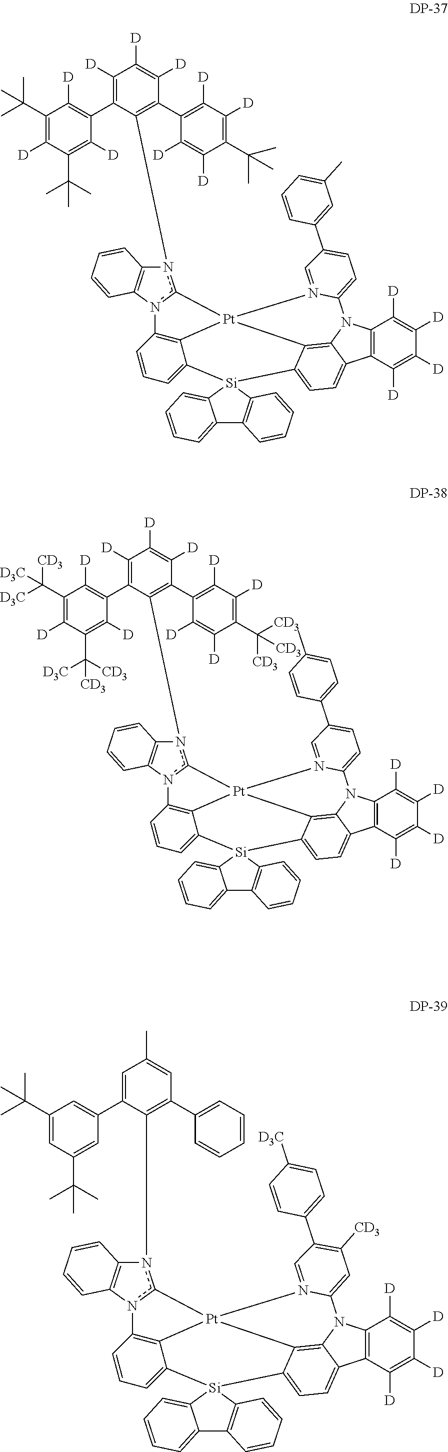

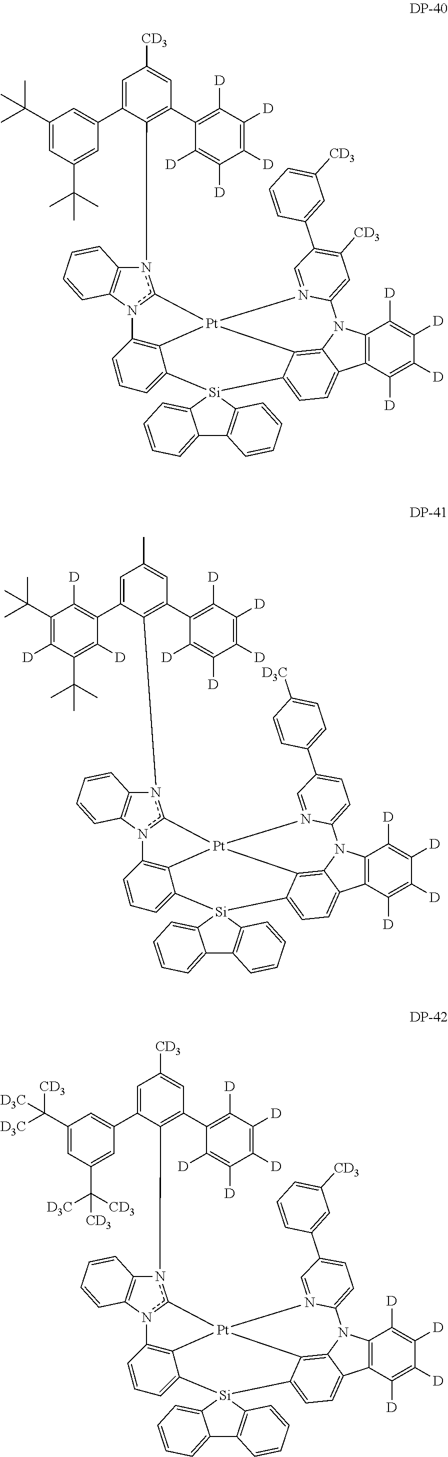

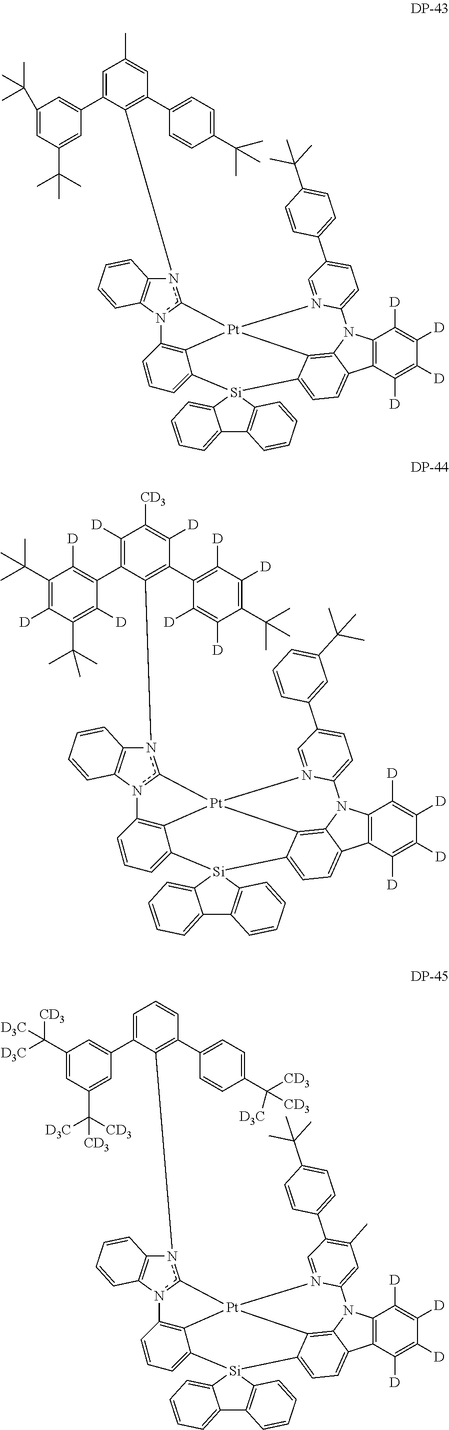

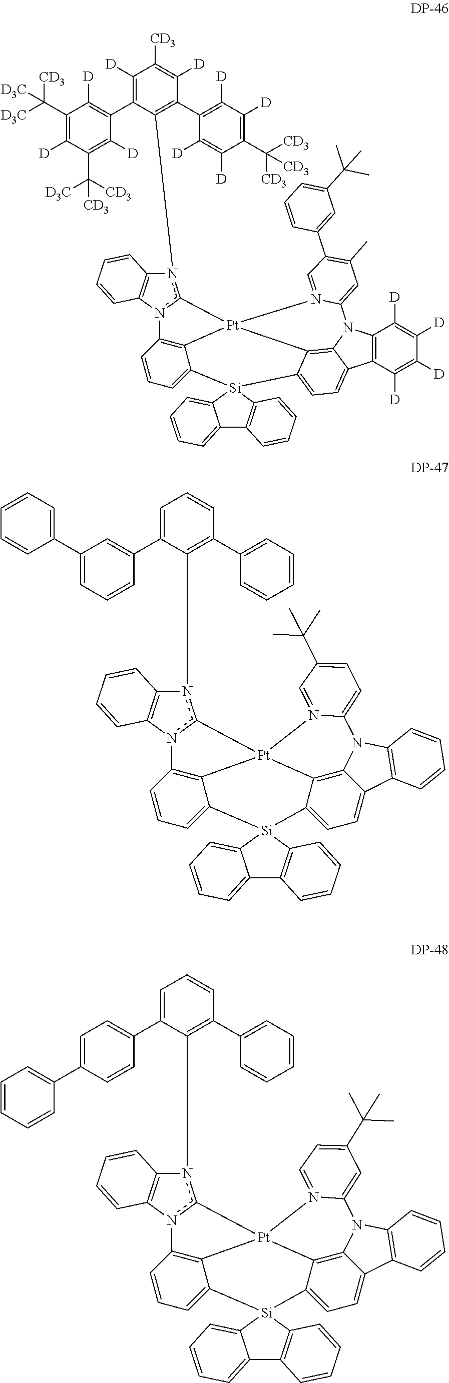

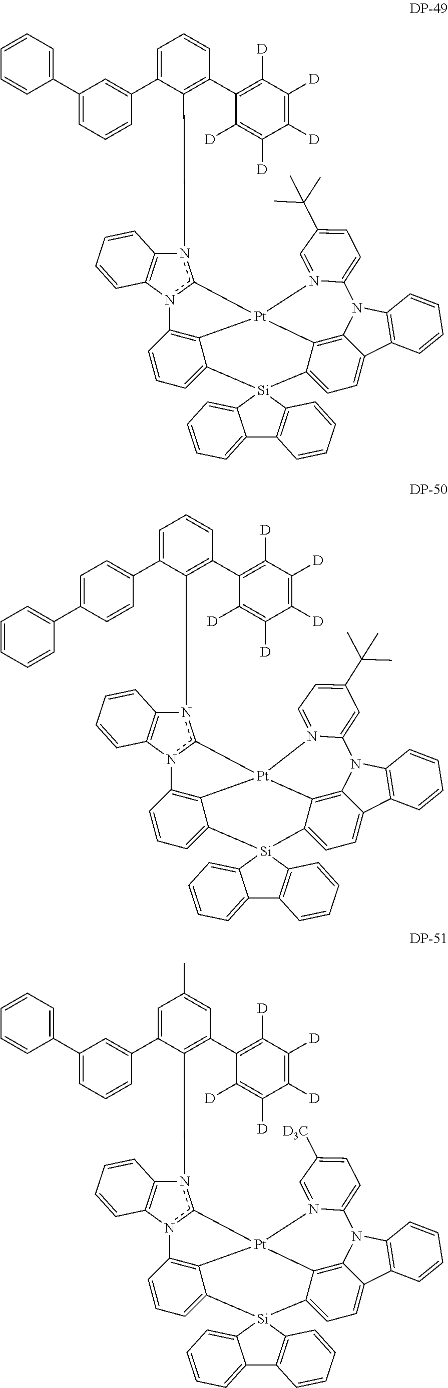

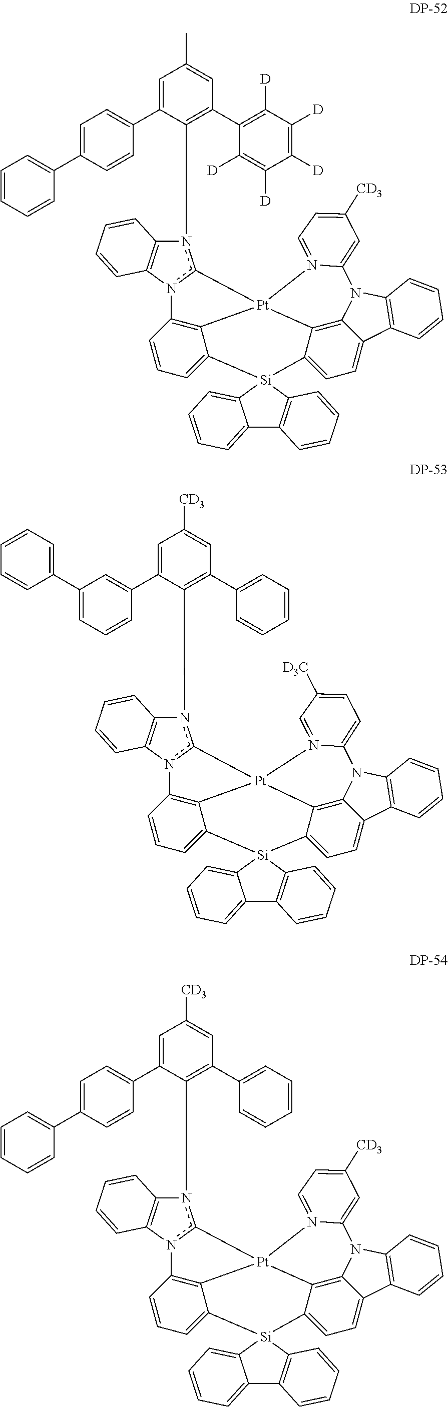

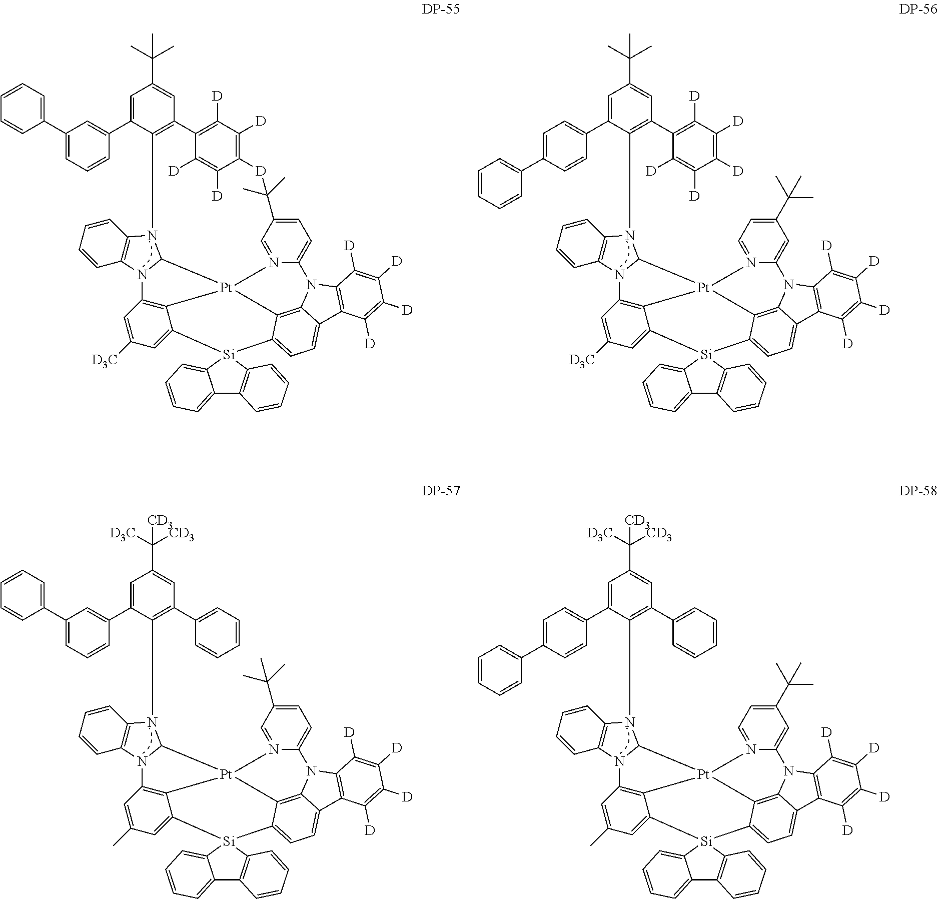

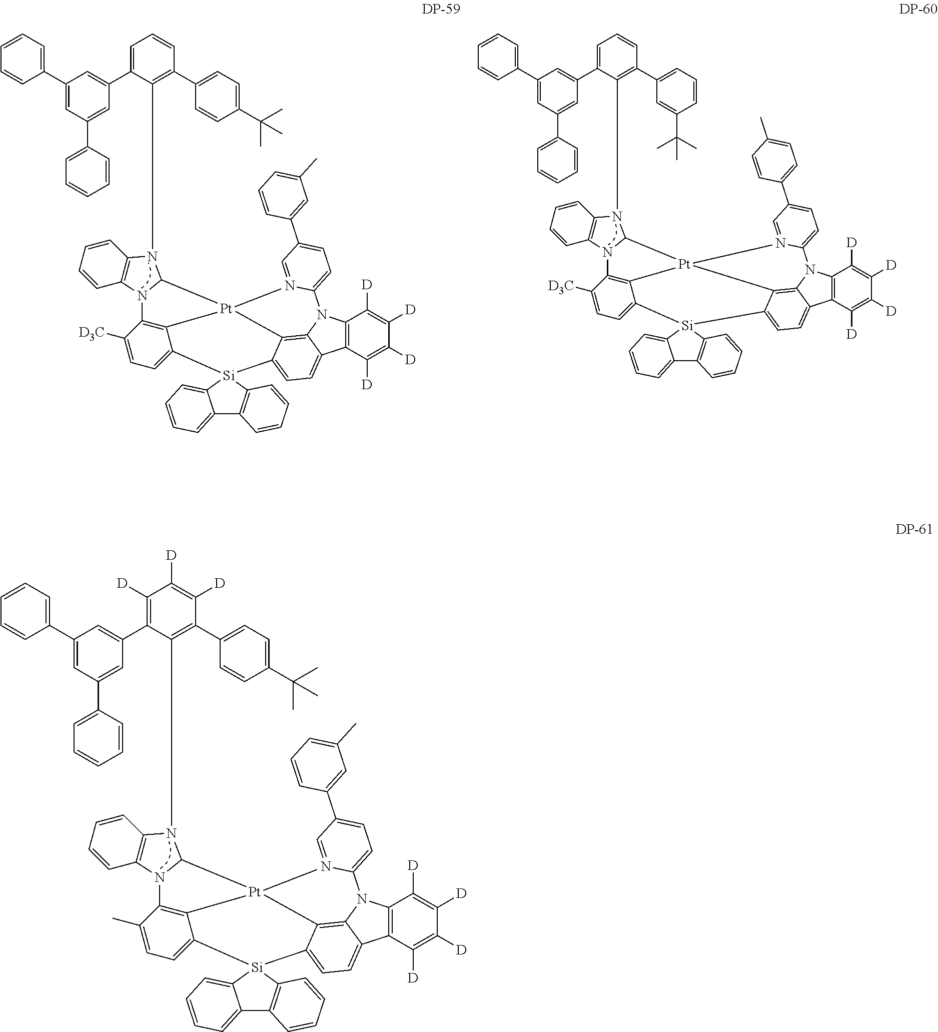

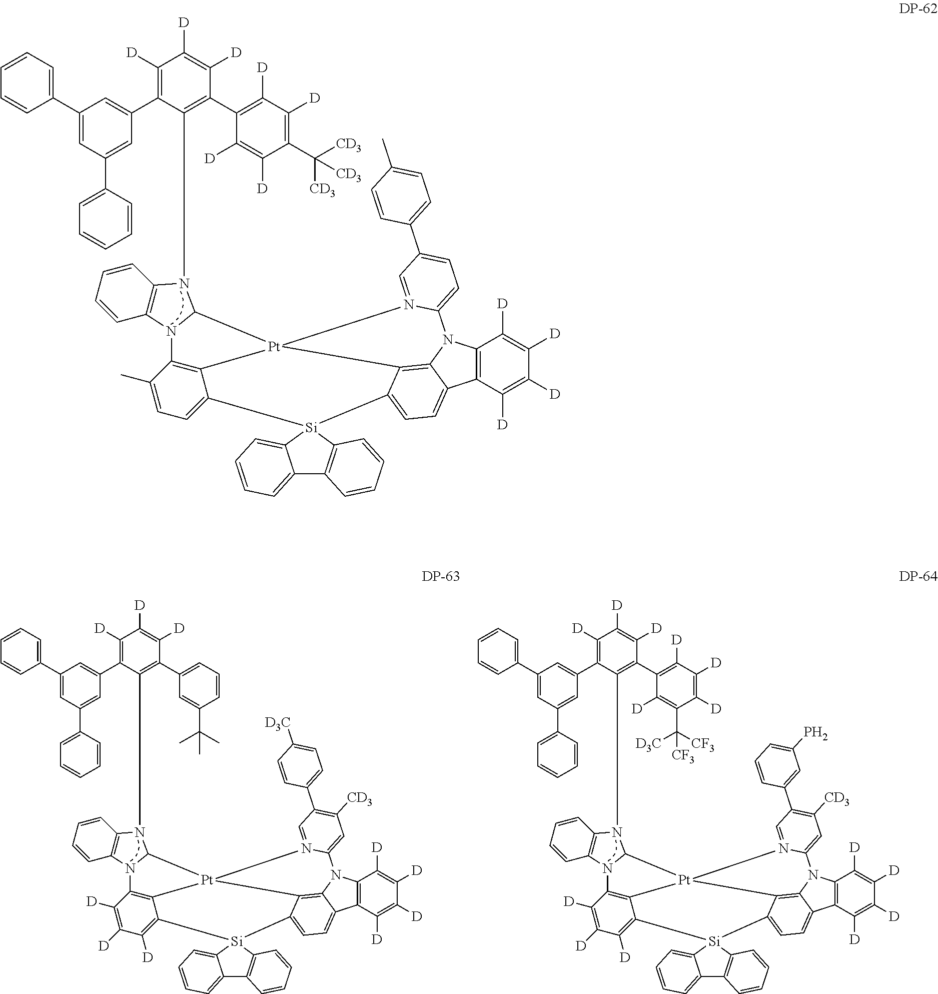

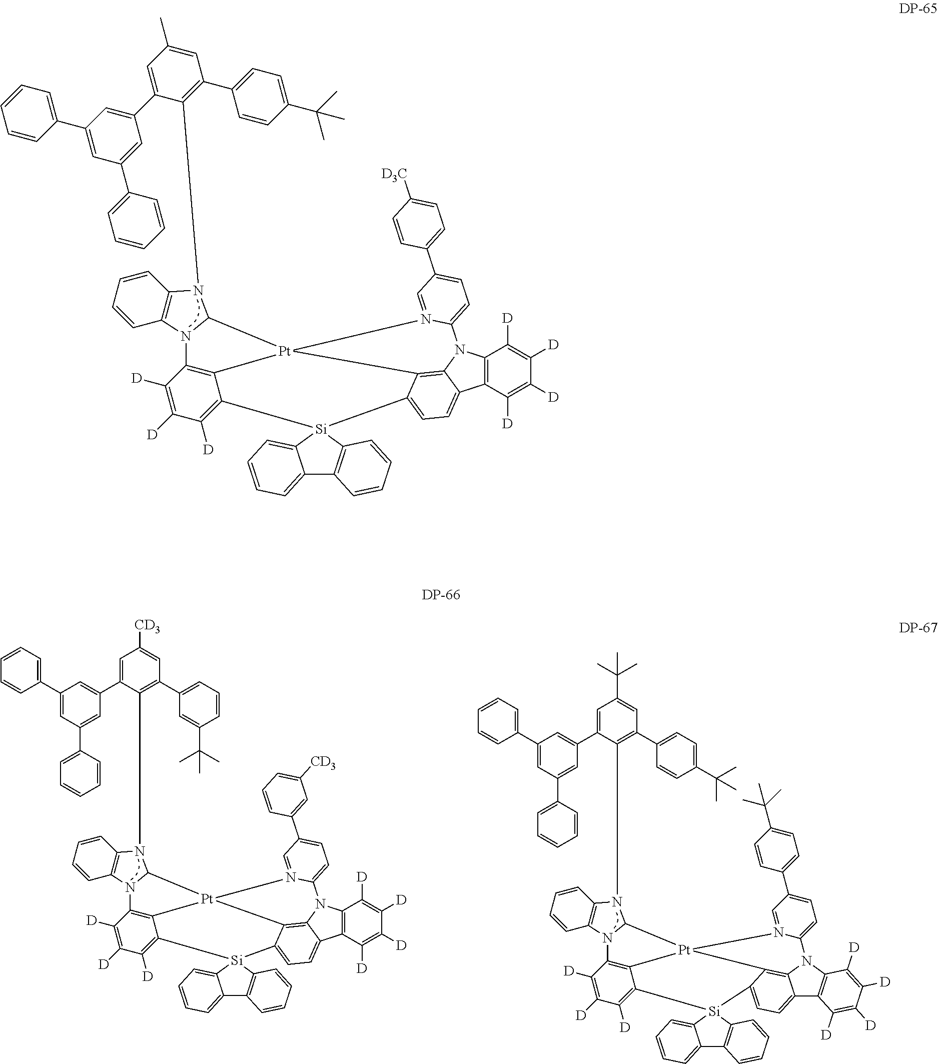

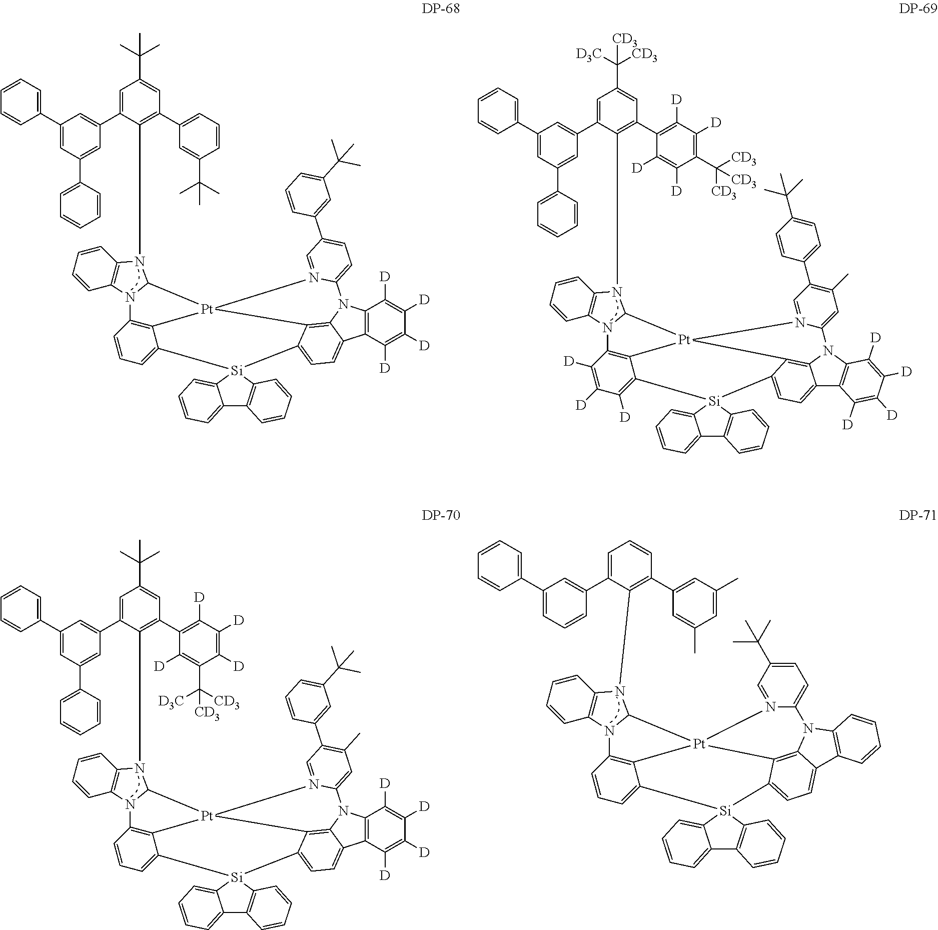

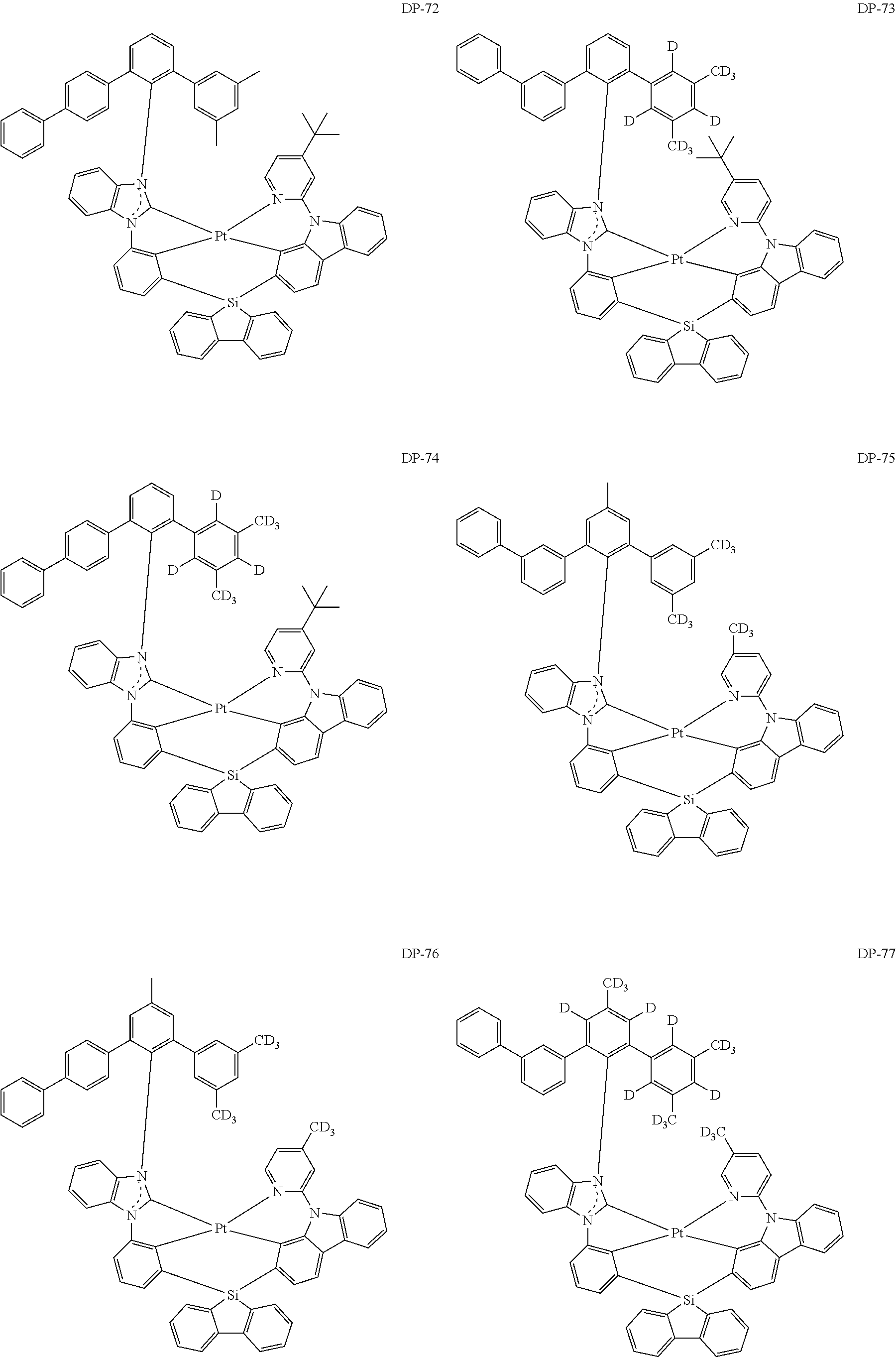

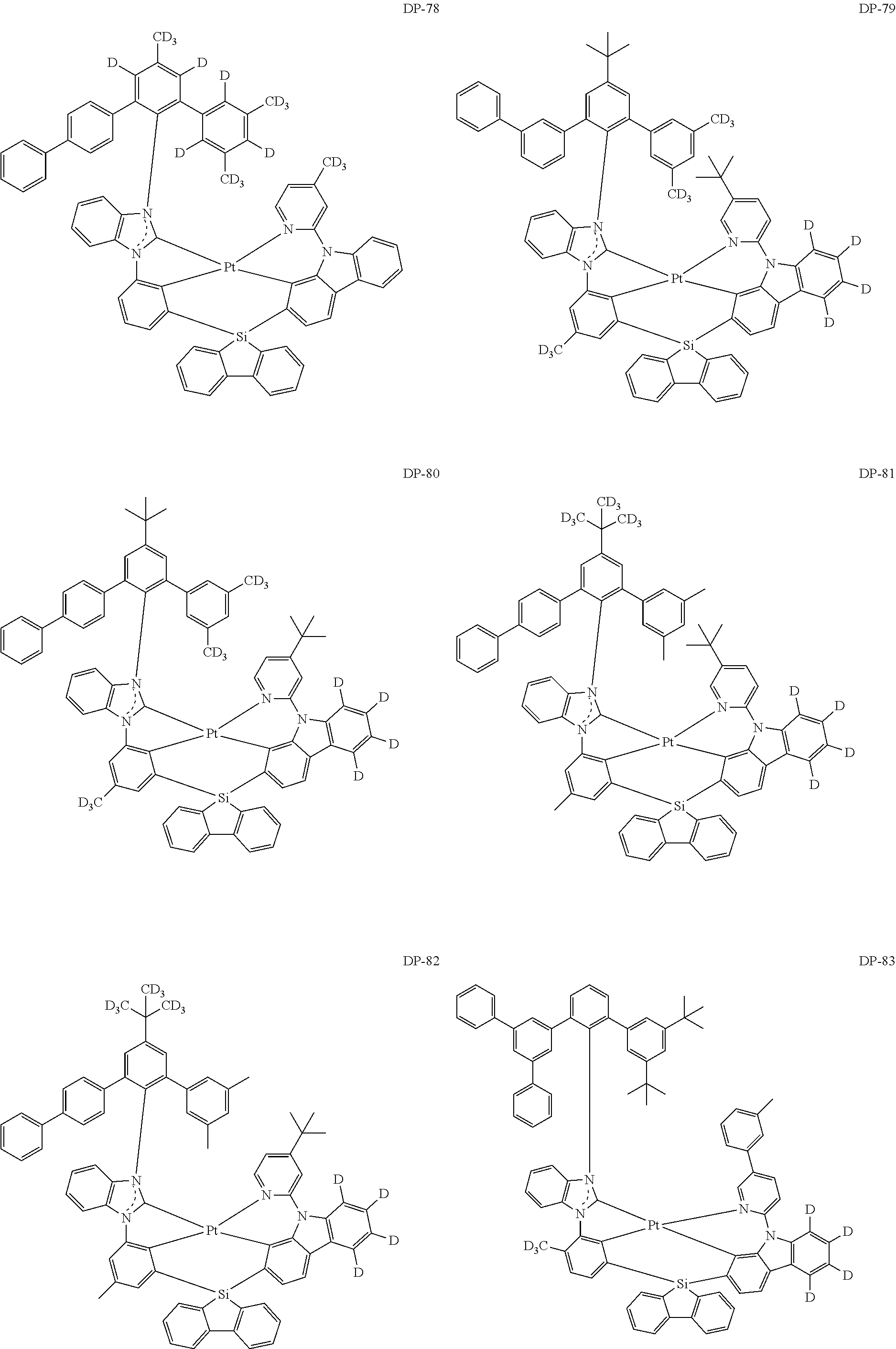

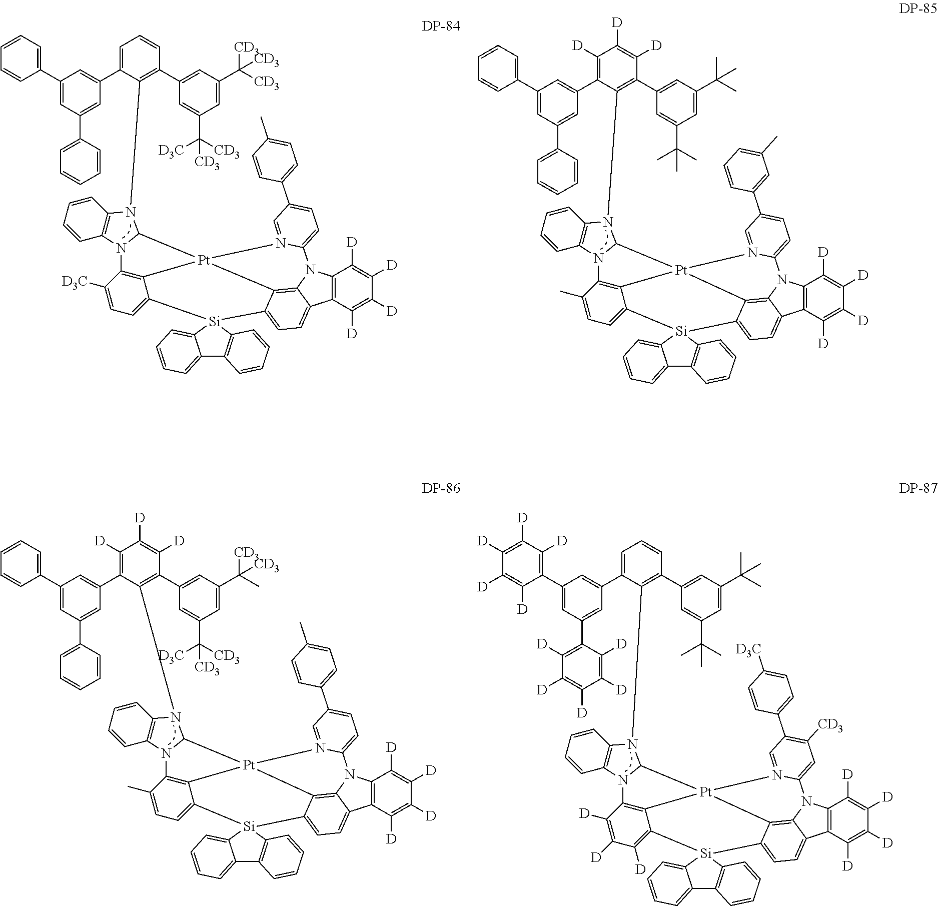

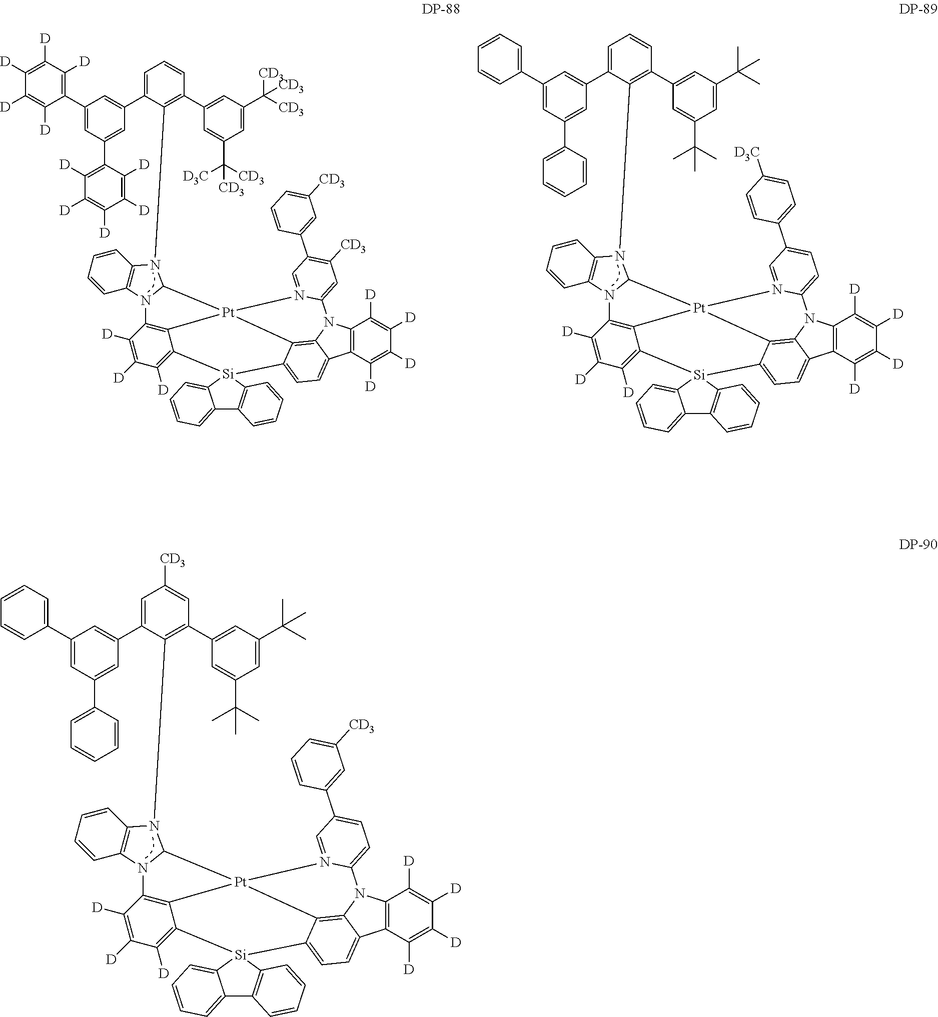

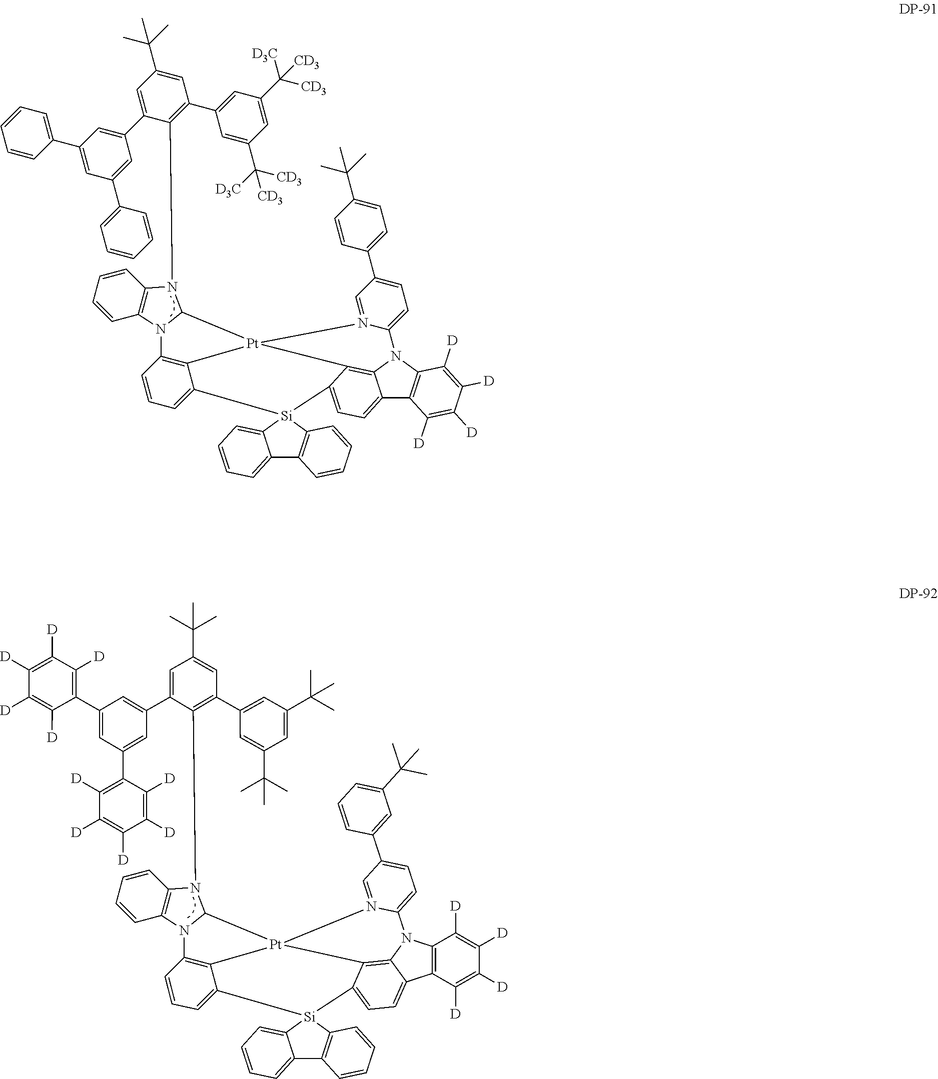

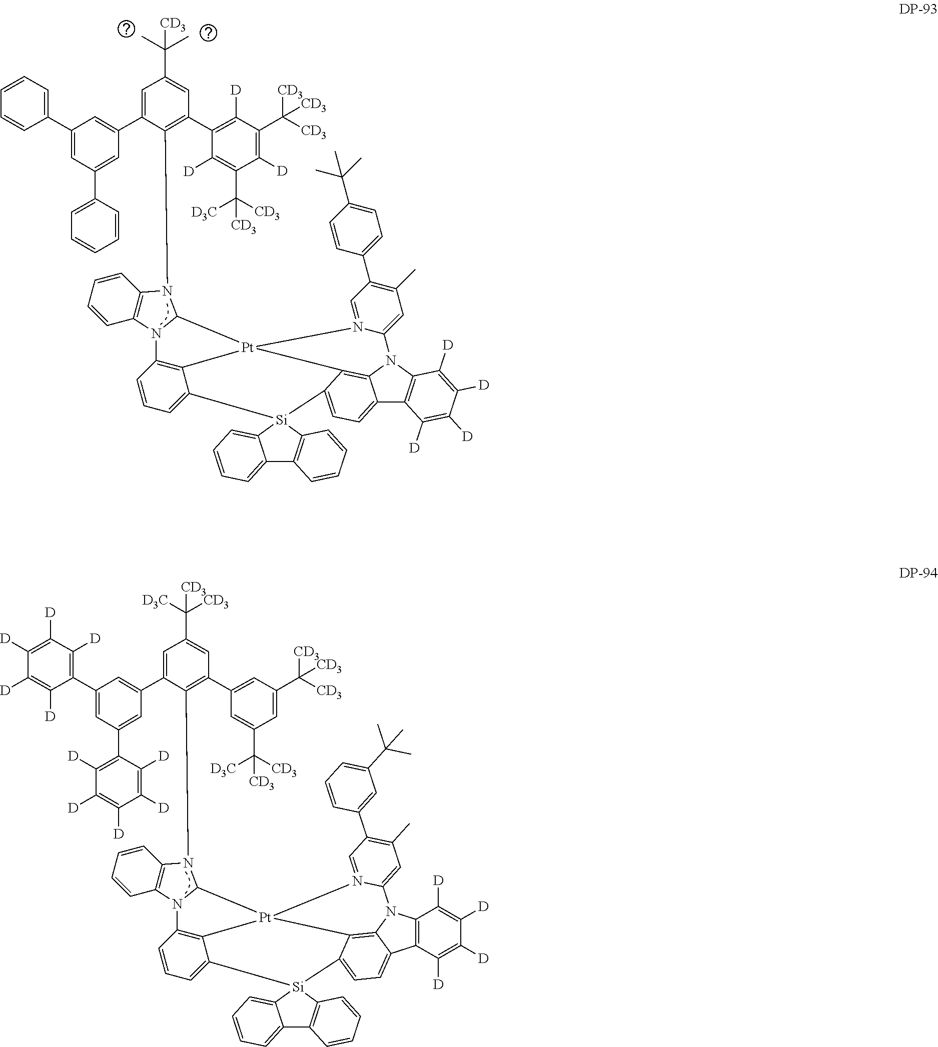

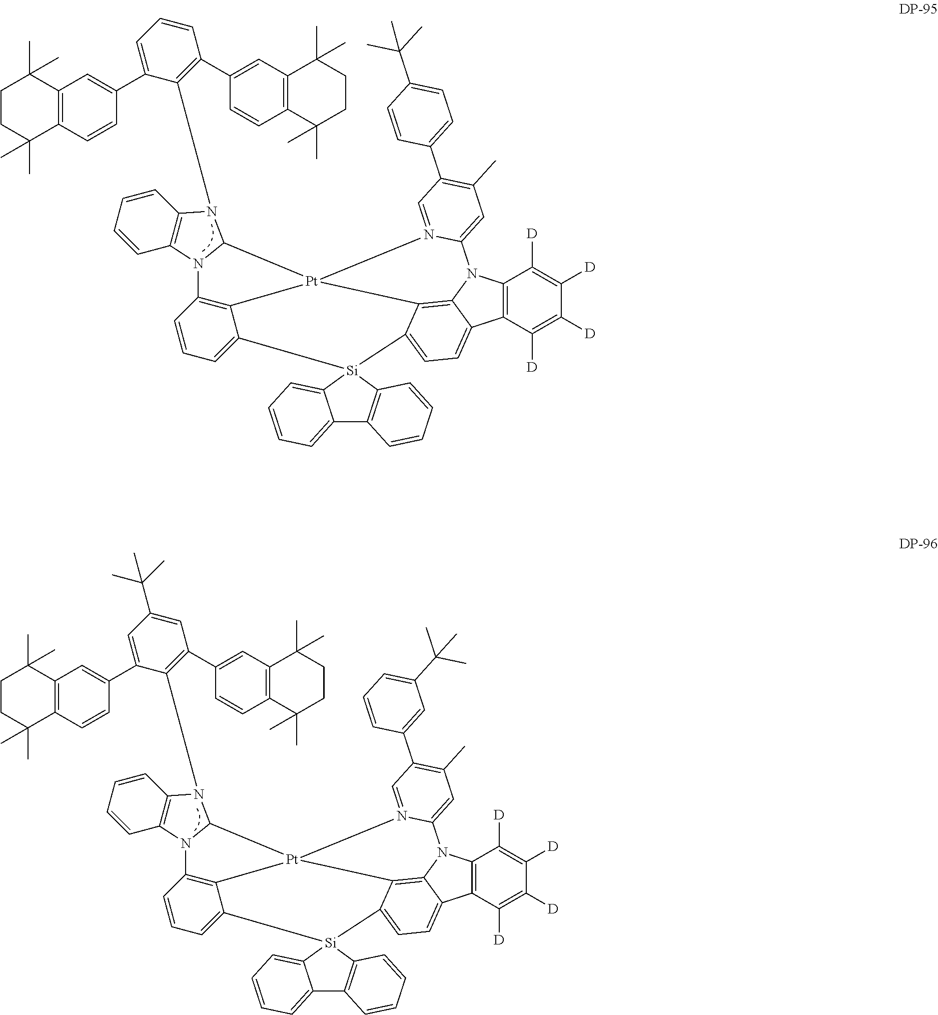

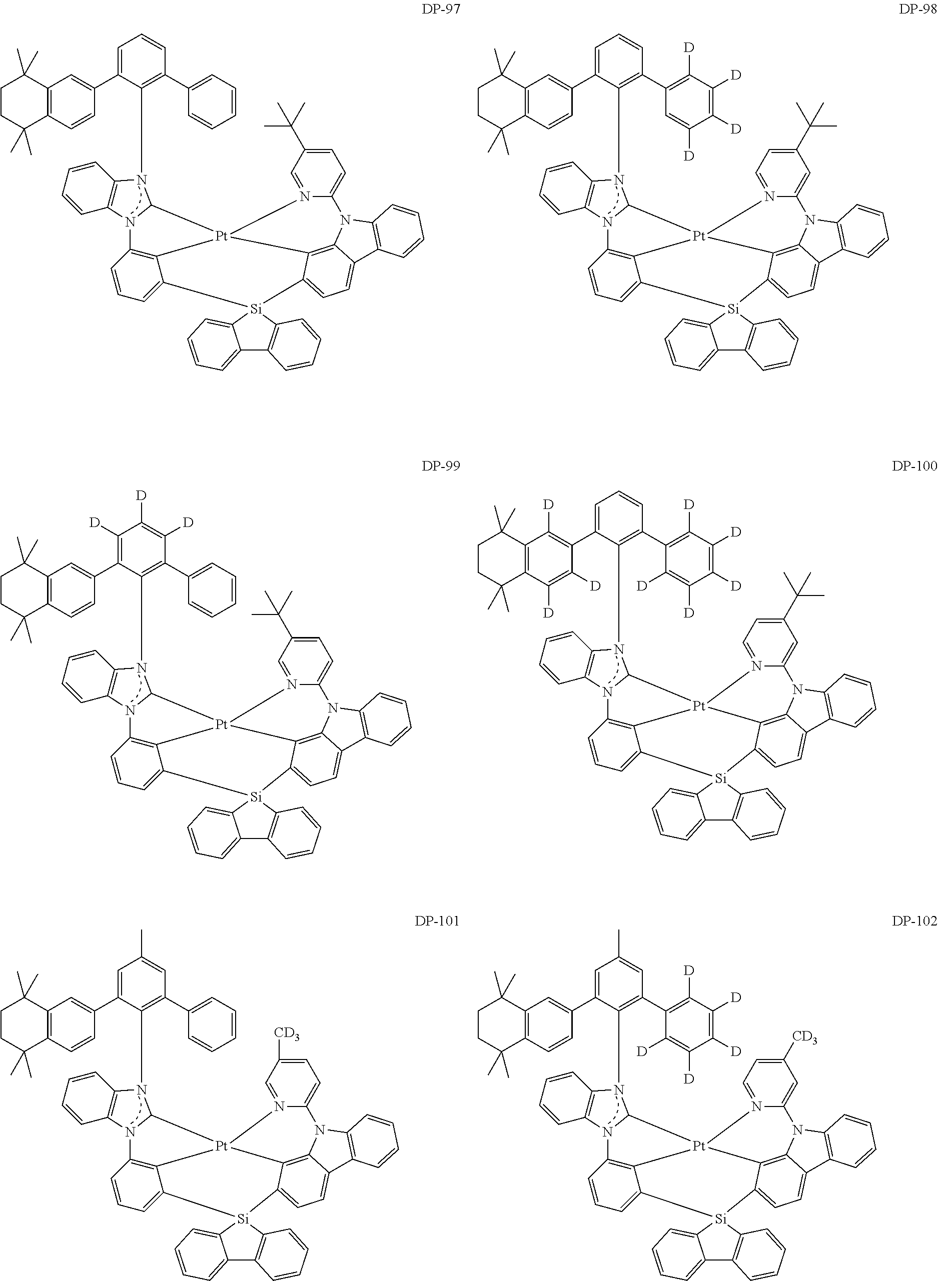

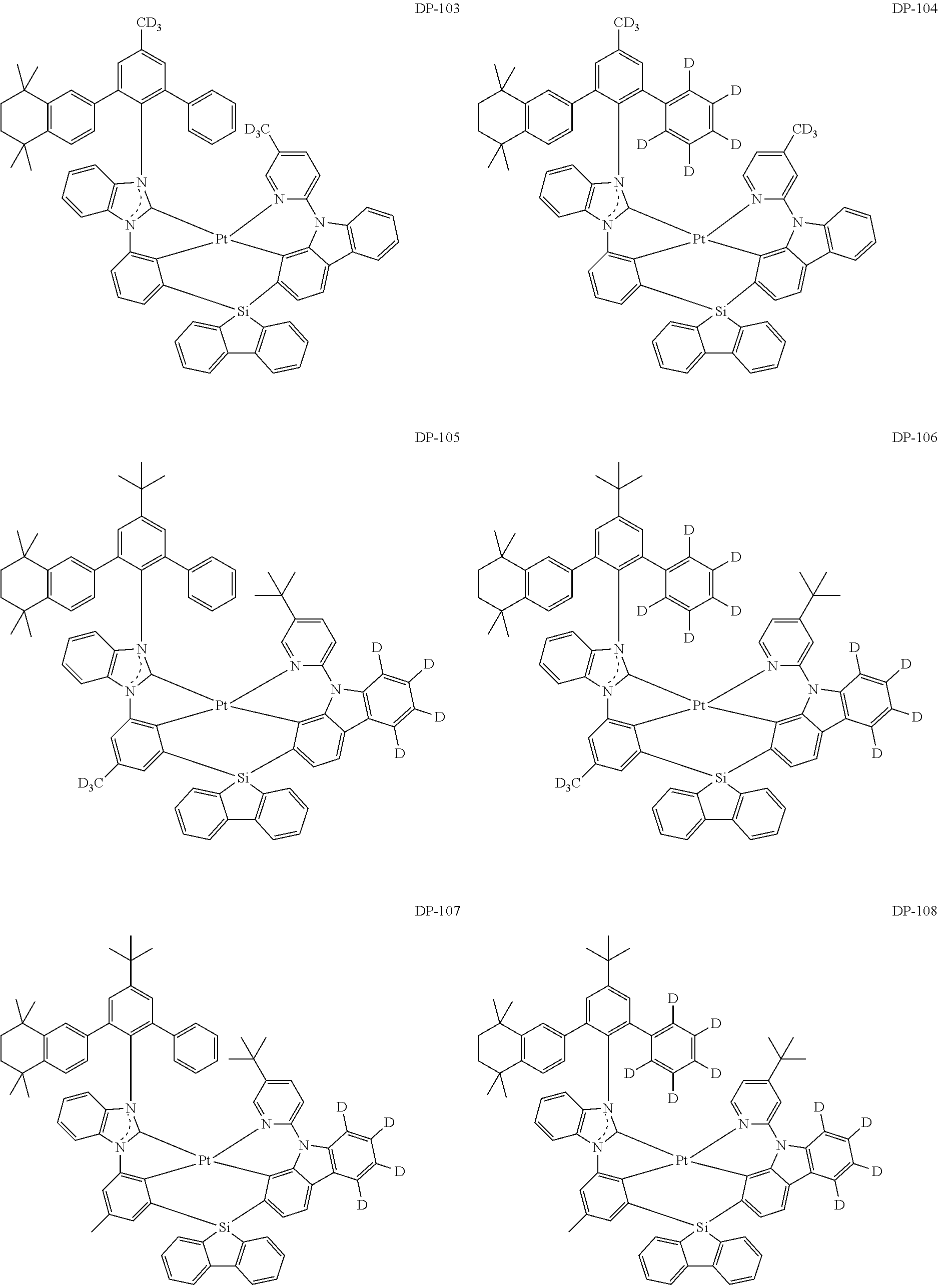

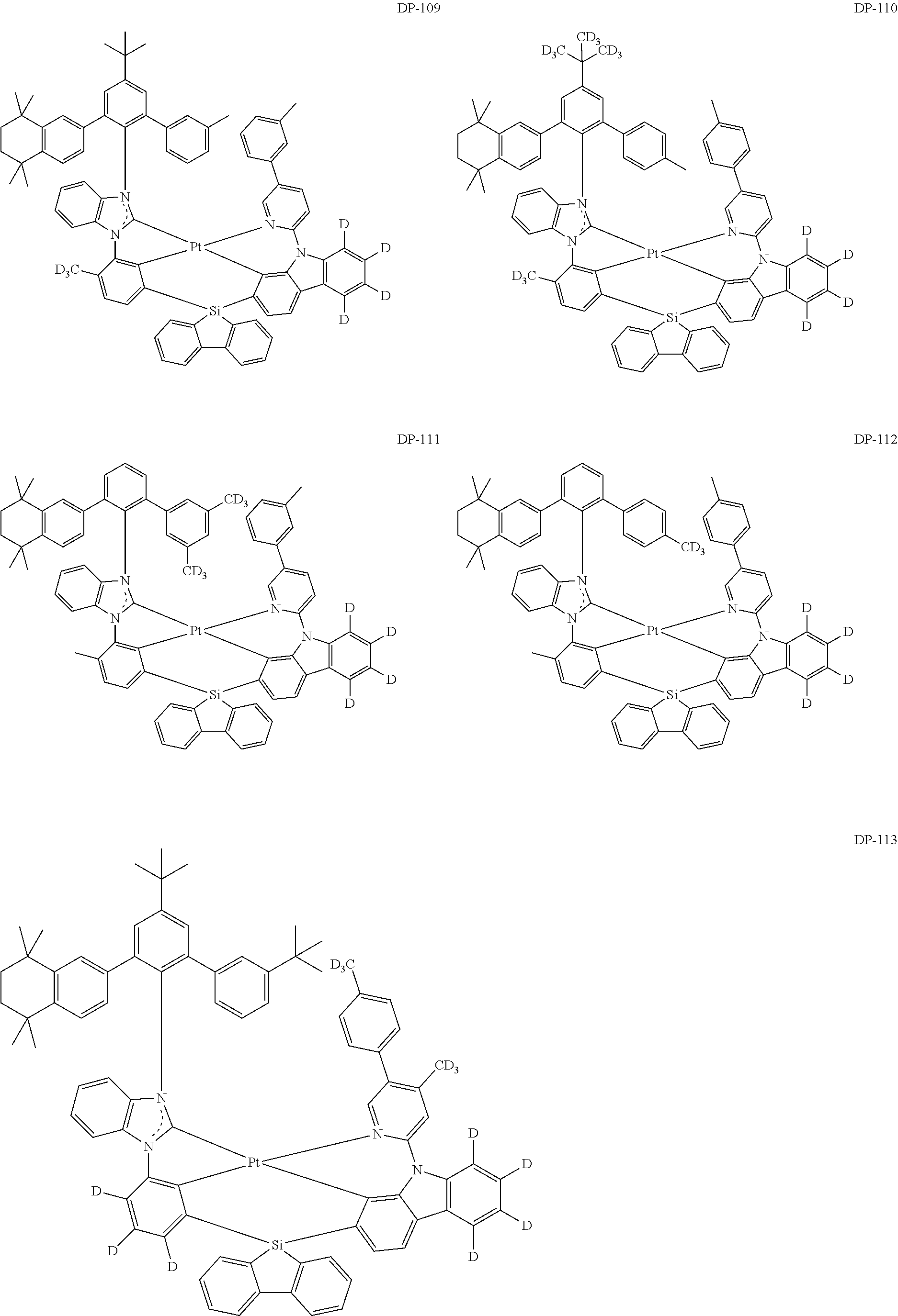

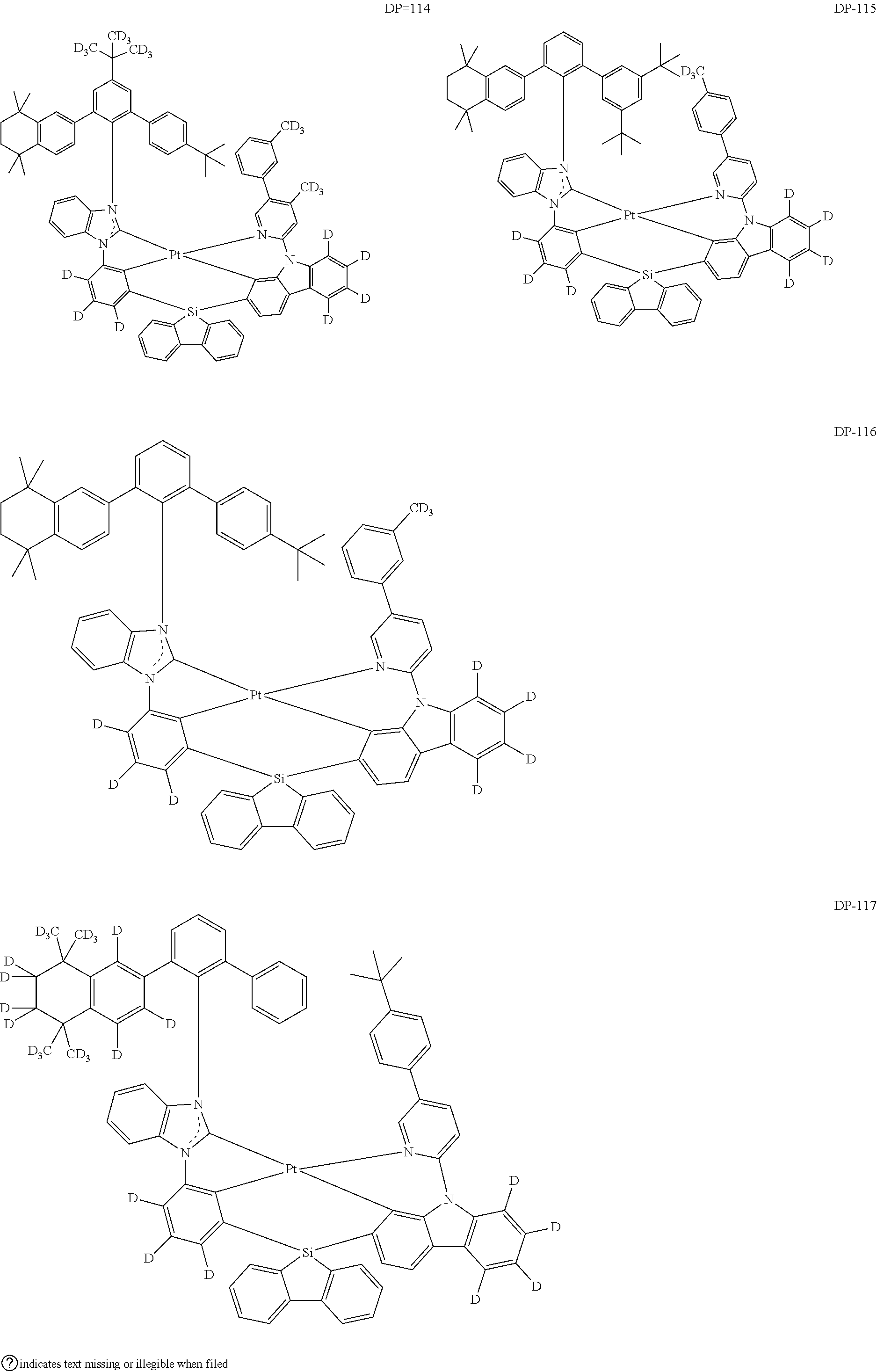

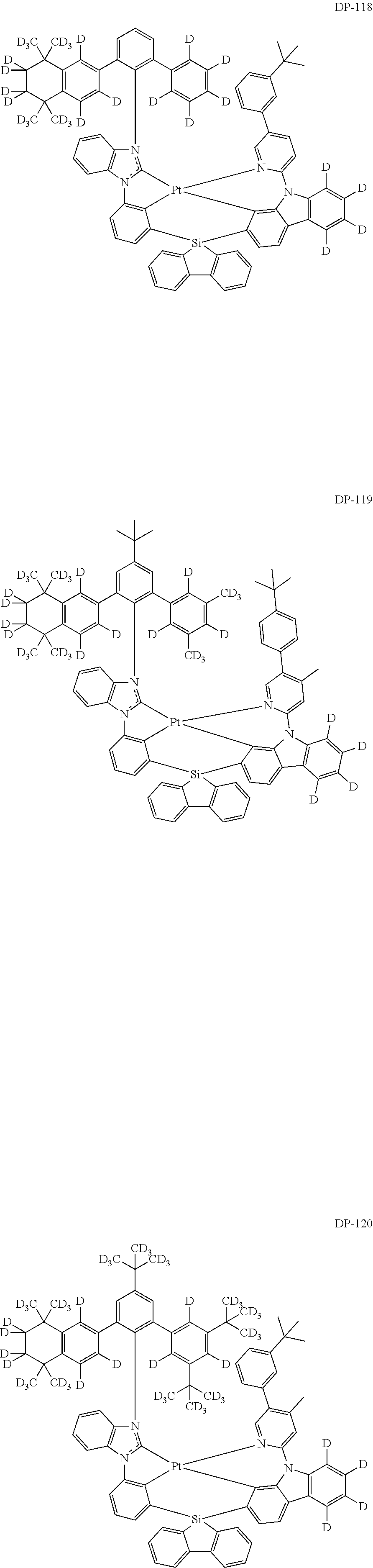

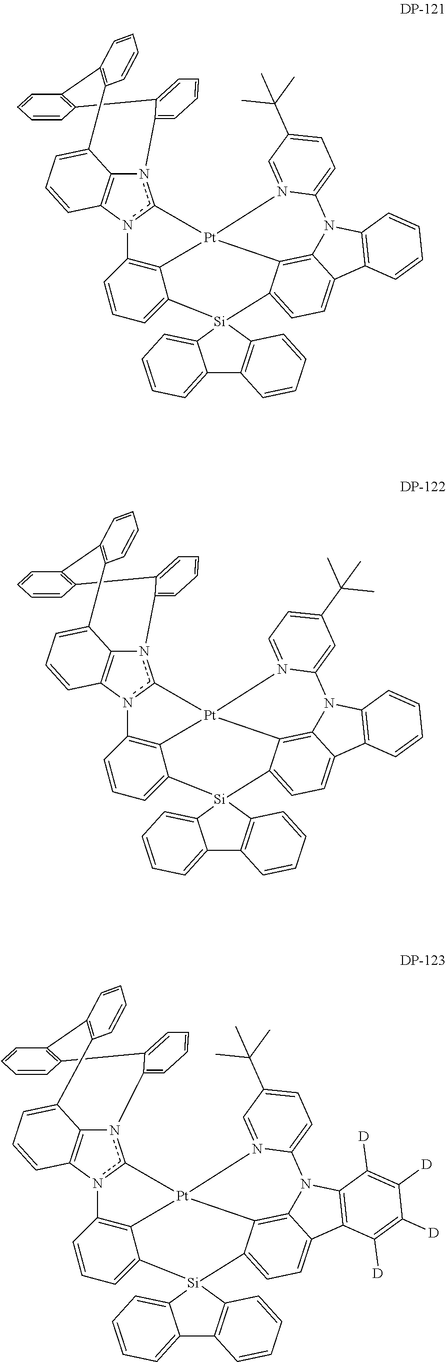

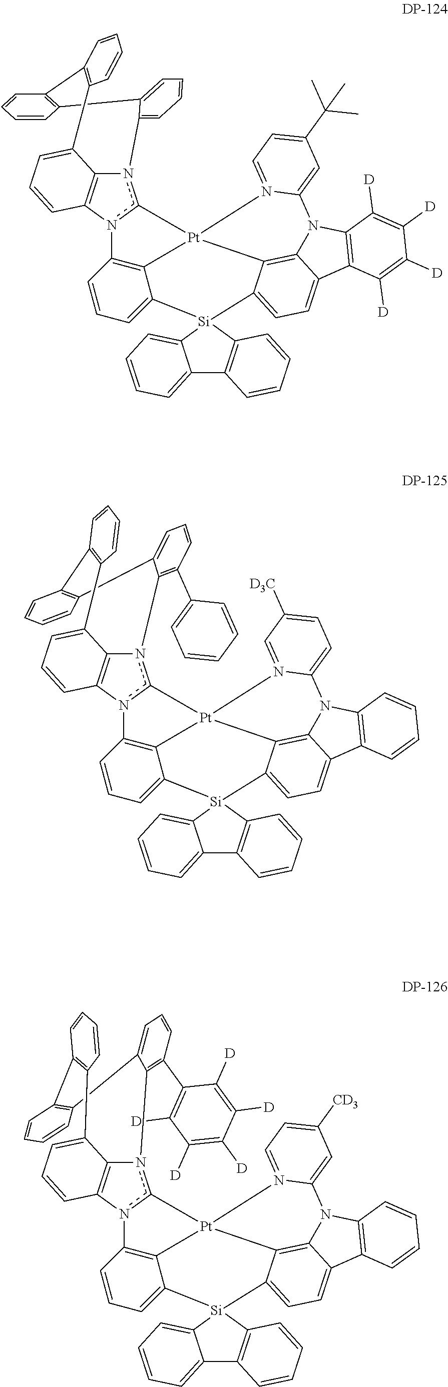

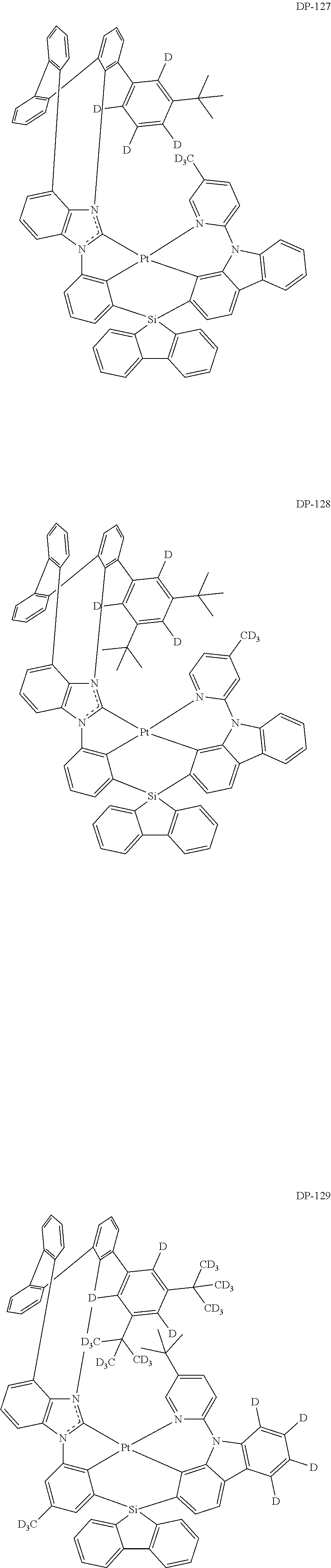

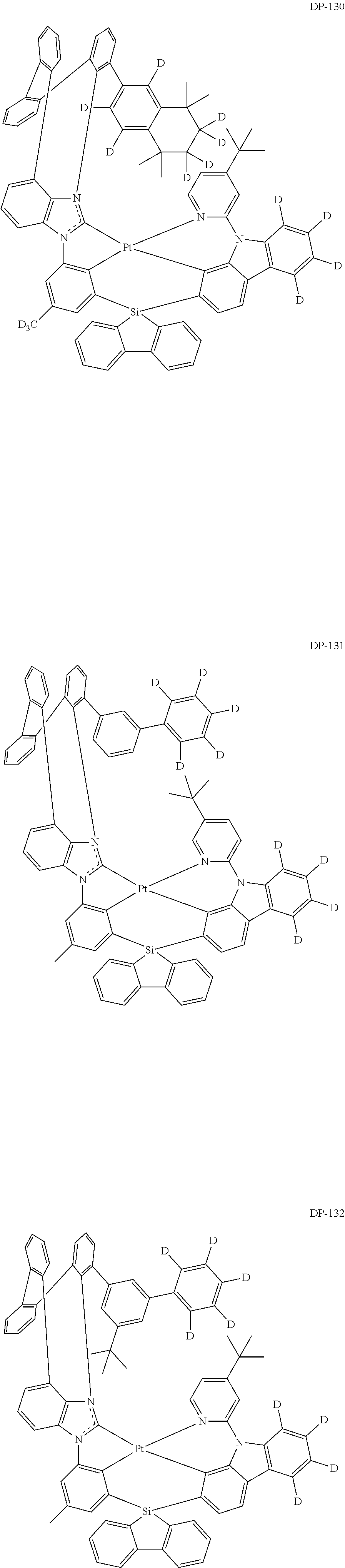

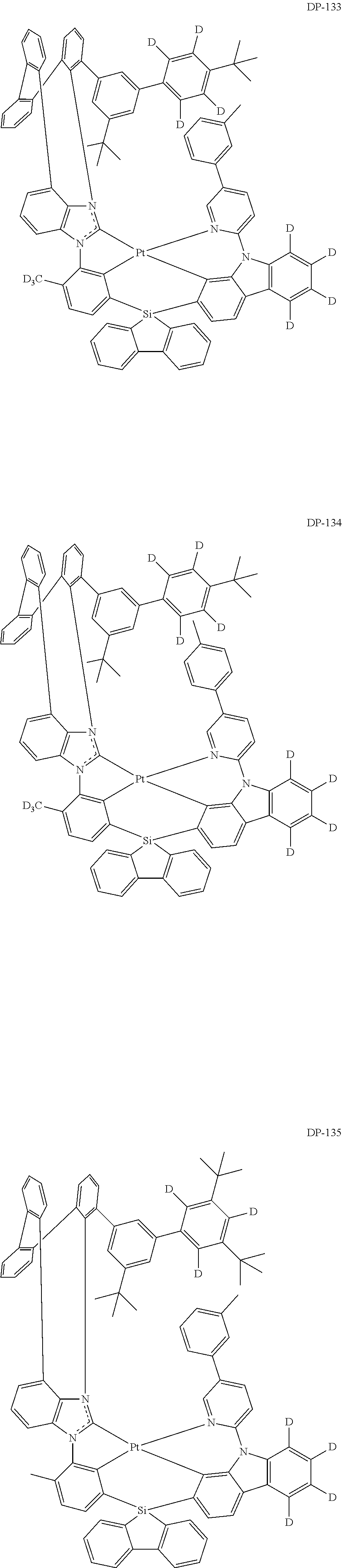

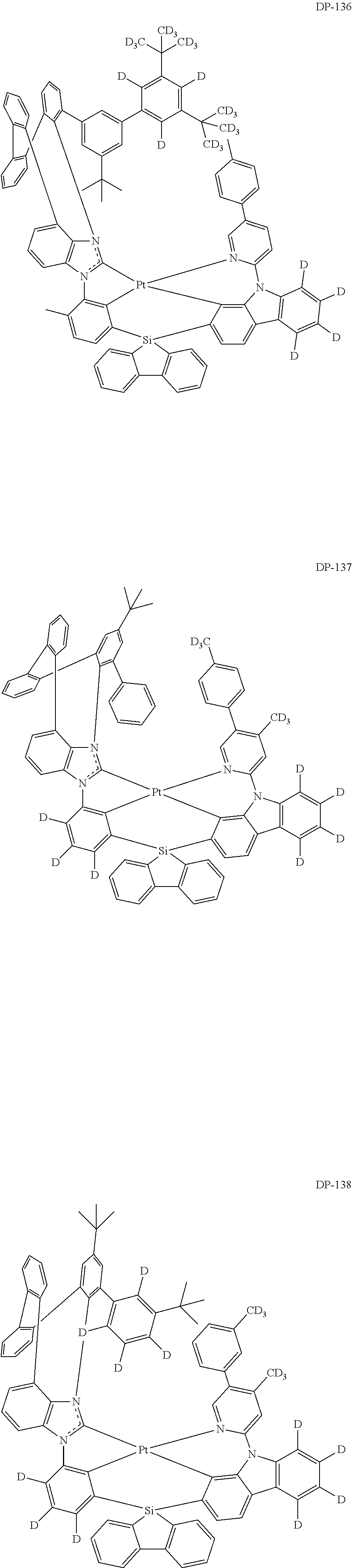

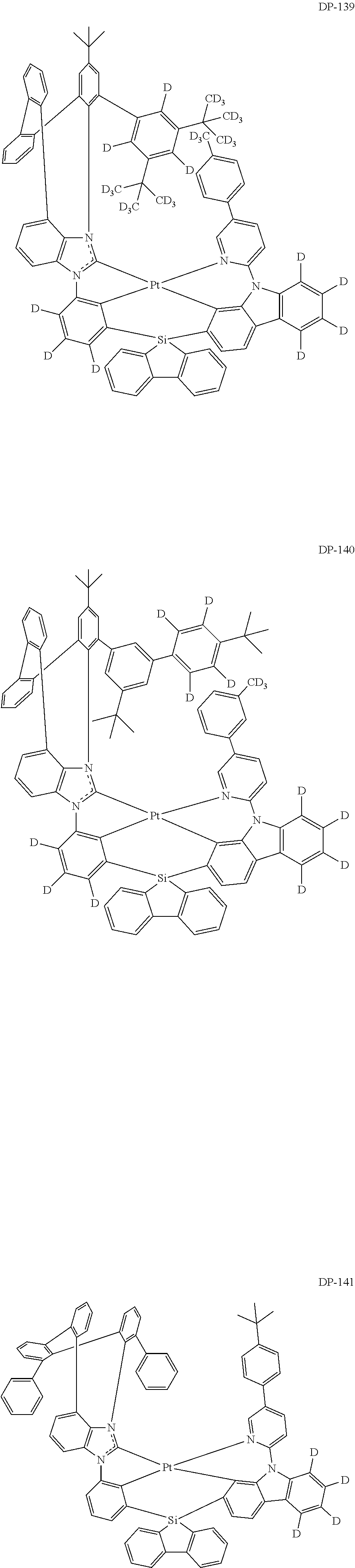

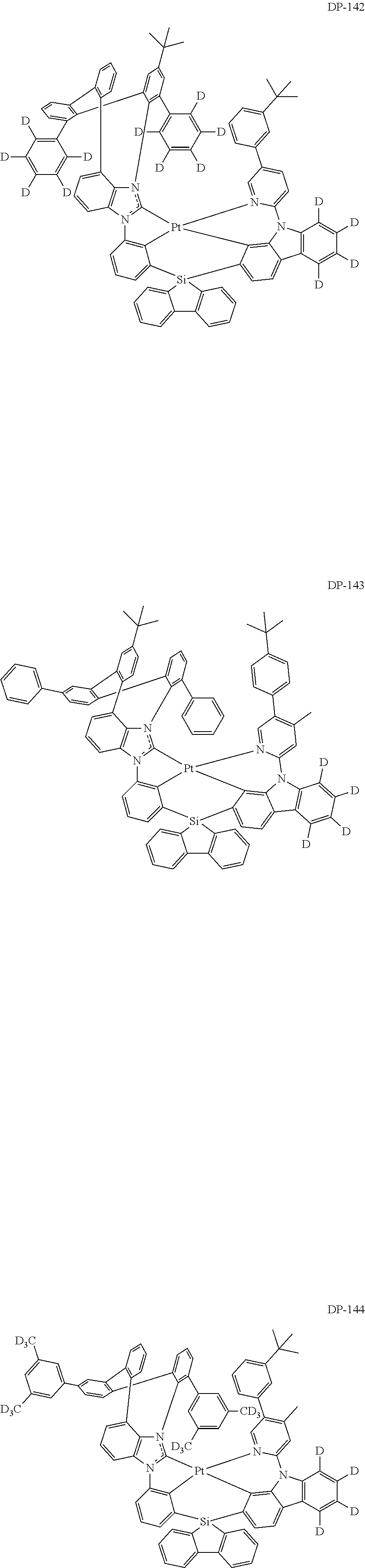

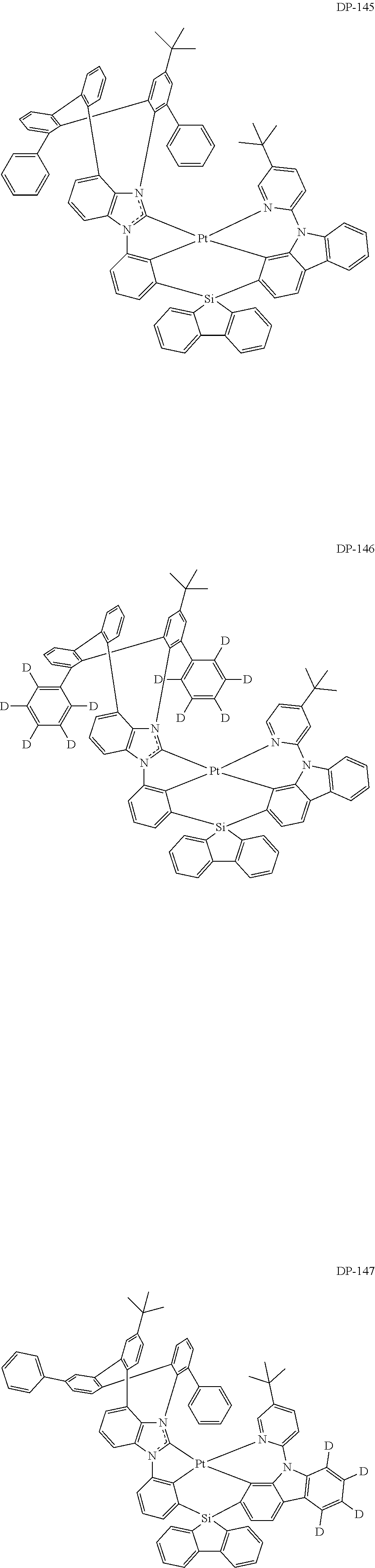

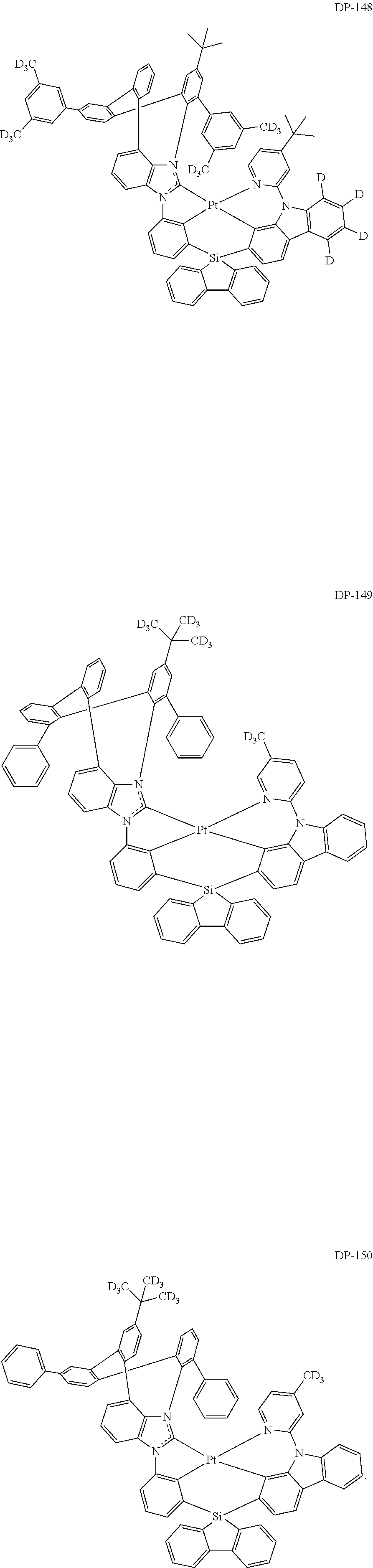

16. A light-emitting device, comprising:
a first electrode;
a second electrode; and
an intermediate layer between the first electrode and the second electrode, wherein
the intermediate layer comprises an emission layer, and
the emission layer includes an organometallic compound represented by Chemical Formula 1: 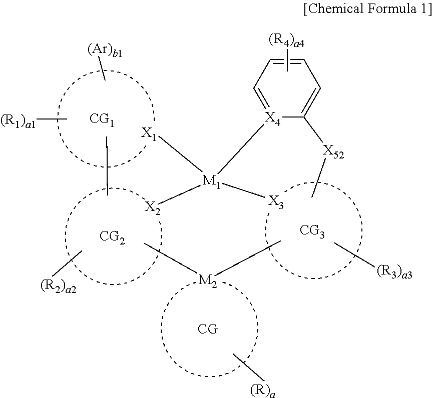
wherein in Chemical Formula 1,
M₁ is platinum (Pt), palladium (Pd), gold (Au), nickel (Ni), silver (Ag), or copper (Cu),
M₂ is carbon (C) or silicon (Si),
X₁ to X₄ are each independently be C or nitrogen (N),
CG, CG₁, CG₂, and CG₃ are each independently a C₃-C₆₀ carbocyclic group or a C₁-C₆₀ heterocyclic group, provided that a ring formed by X₁ and CG₁ is not a benzene group or a pyridine group,
X₅ is a direct linkage, *—N(R₅)—*′, *—B(R₅)—*′, *—P(R₅)—*′, *—C(R₅ₐ)(R_{5b})—*′, *—Si(R₅ₐ)(R_{5b})—*′, *—Ge(R₅ₐ)(R_{5b})—*′, *—S—*′, *—Se—*′, *—O—*′, *—C(═O)—*′, *—S(═O)—*′, *—S(═O)₂—*′, *—C(R₅)═*′, *═C(R₅)—*′, *—C(R₅ₐ)═C(R_{5b})—*′, *—C(═S)—*′ or *—C≡C—*′,
Ar is a substituted or unsubstituted C₆-C₆₀ aryl group, or a substituted or unsubstituted C₅-C₆₀ heteroaryl group,
R, R₂ to R₄, R₅, R₅ₐ, and R_{5b} are each independently hydrogen, deuterium, a halogen, a substituted or unsubstituted C₁-C₁₀ alkyl group, a substituted or unsubstituted C₂-C₁₀ alkenyl group, a substituted or unsubstituted C₂-C₁₀ alkynyl group, a substituted or unsubstituted C₆-C₃₀ aryl group, or a substituted or unsubstituted C₅-C₃₀ heteroaryl group,
R₁ is: hydrogen, deuterium, a halogen, a substituted or unsubstituted C₁-C₁₀ alkyl group, a substituted or unsubstituted C₂-C₁₀ alkenyl group, a substituted or unsubstituted C₂-C₁₀ alkynyl group, a substituted or unsubstituted C₆-C₃₀ aryl group, a substituted or unsubstituted C₅-C₃₀ heteroaryl group; a direct linkage bonded to Ar; or a substituted or unsubstituted C₁-C₁₀ alkylene group bonded to Ar,
a, a1, a2, a3, and a4 are each independently an integer from 0 to 20, and
b1 is 1 or 2.

17. The light-emitting device of claim 16, wherein
the emission layer includes a host and a dopant, and
the organometallic compound serves as a phosphorescent dopant or as a thermally activated delayed fluorescence (TADF) dopant.

18. The light-emitting device of claim 17, wherein the dopant includes a thermally activated delayed fluorescence material.

19. The light-emitting device of claim 17, wherein the host comprises:
a hole transporting host represented by Chemical Formula HT; and
an electron transporting host represented by Chemical Formula ET: 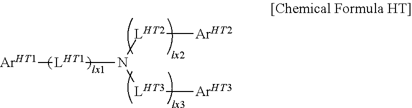
wherein in Chemical Formula HT,
L^{HT1}, L^{HT2}, and L^{HT3} are each independently a direct linkage, a substituted or unsubstituted C₆-C₃₀ arylene group, or a substituted or unsubstituted C₂-C₃₀ heteroarylene group,
lx1 to lx3 are each independently an integer from 0 to 10,
Ar^{HT1} and Ar^{HT2} are each independently a substituted or unsubstituted C₆-C₃₀ aryl group, or a substituted or unsubstituted C₂-C₃₀ heteroaryl group, and
Ar^{HT3} is a substituted or unsubstituted C₆-C₃₀ aryl group; 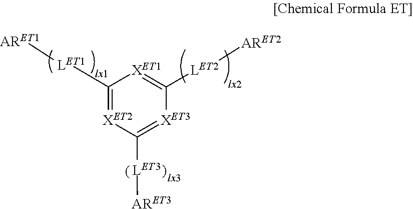
wherein in Chemical Formula ET,
at least one of X^{ET1} to X^{ET3} is N,
the remainder of X^{ET1} to X^{ET3} are each independently C(R^{ET})
R^{ET} is a hydrogen atom, a deuterium atom, a substituted or unsubstituted C₁-C₂₀ alkyl group, a substituted or unsubstituted C₆-C₆₀ aryl group, or a substituted or unsubstituted C₂-C₆₀ heteroaryl group,
lx1 to lx3 are each independently an integer from 0 to 10,
L^{ET1} to L^{ET3} are each independently a direct linkage, a substituted or unsubstituted C₆-C₃₀ arylene group, or a substituted or unsubstituted C₂-C₃₀ heteroarylene group, and
Ar^{ET1} to Ar^{ET3} are each independently a hydrogen atom, a deuterium atom, a substituted or unsubstituted C₁-C₂₀ alkyl group, a substituted or unsubstituted C₆-C₃₀ aryl group, or a substituted or unsubstituted C₂-C₃₀ heteroaryl group.

20. The light-emitting device of claim 16, wherein
the emission layer emits blue light, and
the blue light has a maximum emission wavelength in a range of about 440 nm to about 460 nm.

21. The light-emitting device of claim 16, wherein the organometallic compound is represented by Chemical Formula 1-2 or Chemical Formula 1-3: 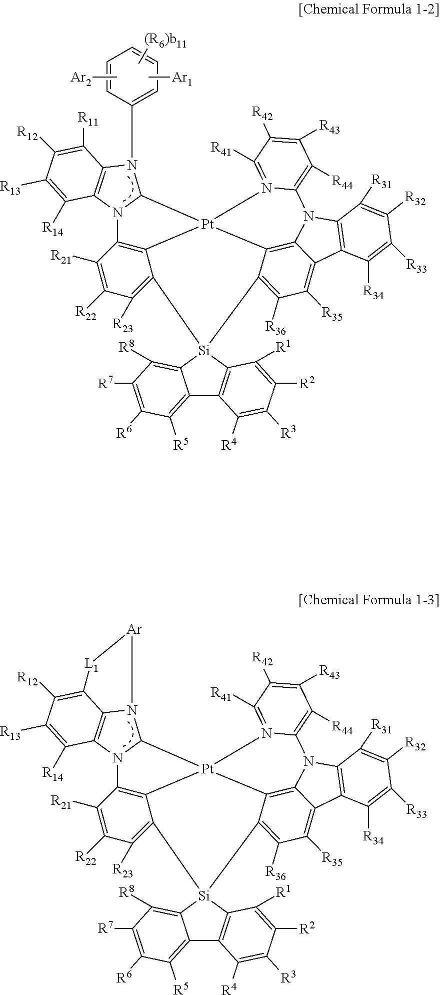
wherein in Chemical Formulae 1-2 and 1-3,
Ar, Ar₁, and Ar₂ are each independently a substituted or unsubstituted C₆-C₃₀ aryl group, or a substituted or unsubstituted C₅-C₃₀ heteroaryl group,
R₆ is each independently hydrogen, deuterium, a halogen, a substituted or unsubstituted C₁-C₁₀ alkyl group, a substituted or unsubstituted C₂-C₁₀ alkenyl group, or a substituted or unsubstituted C₂-C₁₀ alkynyl group,
b₁₁ is an integer from 0 to 3,
R¹ to R⁸, R₁₂ to R₁₄, R₂₁ to R₂₃, R₃₁ to R₃₆, and R₄₁ to R₄₄ are each independently hydrogen, deuterium, a halogen, a substituted or unsubstituted C₁-C₁₀ alkyl group, a substituted or unsubstituted C₂-C₁₀ alkenyl group, a substituted or unsubstituted C₂-C₁₀ alkynyl group, a substituted or unsubstituted C₆-C₃₀ aryl group, or a substituted or unsubstituted C₅-C₃₀ heteroaryl group, and
L₁ is a direct linkage or a substituted or unsubstituted C₁-C₁₀ alkylene group.

22. An electronic device comprising the light-emitting device of claim 16.

23. The electronic device of claim 22, further comprising:
a functional layer disposed on the light-emitting device, wherein
the functional layer comprises a sensor layer, a polarizing layer, a color conversion layer, a color filter layer, a window film, or a combination thereof.

24. The electronic device of claim 23, wherein
the functional layer comprises the color conversion layer, and
the color conversion layer includes quantum dots.
